(19) United States
(12) Patent Application Publication
(10) Pub. No.: US 2013/0136900 A1
(43) Pub. Date: May 30, 2013

(54) ACTINIC RAY-SENSITIVE OR RADIATION-SENSITIVE RESIN COMPOSITION, AND RESIST FILM, PATTERN FORMING METHOD, ELECTRONIC DEVICE MANUFACTURING METHOD, AND ELECTRONIC DEVICE, EACH USING THE COMPOSITION

(71) Applicant: FUJIFILM Corporation, Tokyo (JP)

(72) Inventors: Akinori SHIBUYA, Haibara-gun (JP); Kaoru IWATO, Haibara-gun (JP)

(73) Assignee: FUJIFILM CORPORATION, Tokyo (JP)

(21) Appl. No.: 13/687,897

(22) Filed: Nov. 28, 2012

(30) Foreign Application Priority Data
Nov. 29, 2011 (JP) 2011-260909

(51) Int. Cl. G03F 7/004

(52) U.S. Cl. CPC G03F 7/004
USPC 428/174; 430/270.1; 430/325

(57) ABSTRACT

Disclosed are an actinic ray-sensitive or radiation-sensitive resin composition including (A) a compound capable of generating an acid by irradiation of actinic rays or radiation, and (B) a resin of which solubility in an alkali developer is increased by being decomposed by the action of an acid, a resist film using the composition, a pattern forming method, an electronic device manufacturing method, and an electronic device, wherein the actinic ray-sensitive or radiation-sensitive resin composition contains a combination composed of the two types of specific compounds of (A-1) or a combination of the two types of specific compounds of (A-2) as the compound (A).

### BACKGROUND OF THE INVENTION

1. Field of the Invention

The present invention relates to an actinic ray-sensitive or radiation-sensitive resin composition which changes properties due to a reaction by irradiation of actinic rays or radiation, and a resist film, a pattern forming method, an electronic device manufacturing method, and an electronic device, each using the composition. In particular, the present invention relates to an actinic ray-sensitive or radiation-sensitive resin composition used for a manufacturing process of semiconductor such as an IC, a liquid crystal, a manufacturing process of circuit board such as thermal head, a photofabrication process in addition to these, a lithographic printing plate and an acid-curable composition, and, a resist film, a pattern forming method, an electronic device manufacturing method and an electronic device, each using the composition.

2. Description of the Related Art

A chemical amplification type resist composition is a pattern forming material which forms a pattern on a substrate by generating an acid in an exposed portion by irradiation of actinic rays such as far ultraviolet light or radiation, and changing solubility of irradiated portions and non-irradiated portions by actinic rays or radiation in a developer using a reaction which uses this acid as a catalyst.

When a KrF excimer laser is used as an exposure light source, high sensitivity and high resolution is obtained and favorable patterns may also be formed since the resin with poly(hydroxystyrene) usually having a small absorption in the region of 248 nm as a basic skeleton is used as a main component, therefore, this system is considered more favorable than a naphthoquinonediazide/novolak resin system in the related art.

Meanwhile, when a light source with a shorter wavelength, for example, an ArF excimer laser (193 nm) is used as an exposure light source, the chemical amplification system described above is not sufficient since a compound having an aromatic group essentially shows a large absorption in the region of 193 nm. As a result, resists for an ArF excimer laser containing a resin having an alicyclic hydrocarbon structure have been developed.

In addition, a variety of compounds for use as a photoacid generator which is a major component of a chemical amplification type resist composition (for example, see WO2011/093139A, WO2011/093280A and WO2011/104127A) have also been developed. For example, in WO2011/093139A, a sulfonium salt photoacid generator having an ether structure in the sulfonium cation is disclosed.

However, from the viewpoint of overall performances as a resist composition, it is extremely difficult to find a suitable combination of the resin used, a photoacid generator, a basic compound, an additive, a solvent and the like, and it remains not to be sufficient. For example, the development of an actinic ray-sensitive or radiation-sensitive resin composition in which depth of focus latitude (Depth of Focus) is large and the occurrence of particles is small over time has been required.

### SUMMARY OF THE INVENTION

The object of the present invention is, in view of the above, to provide an actinic ray-sensitive or radiation-sensitive resin composition having liquid properties such that depth of focus latitude (Depth of Focus) is large and the occurrence of particles is small over time, and a resist film using the composition, a pattern forming method, an electronic device manufacturing method, and an electronic device.

The inventors have completed the present invention as a result of intensive studies to solve the above problems. That is, the present invention is as follows.

[1] An actinic ray-sensitive or radiation-sensitive resin composition including (A) a compound capable of generating an acid by irradiation of actinic rays or radiation, and (B) a resin of which solubility in an alkali developer is increased by being decomposed by the action of an acid, wherein the actinic ray-sensitive or radiation-sensitive resin composition contains a combination of the following compounds of (A-1) or a combination of the following compounds of (A-2) as the compound (A).

(A-1) A combination of a compound represented by the following General Formula (I) and a compound represented by the following General Formulae (II) or (III)

(A-2) A combination of a compound represented by the following General Formula (IV) and a compound represented by the following General Formula (V)

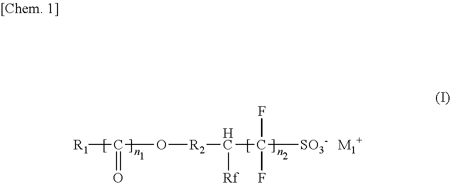

In General Formula (I), R₁ is a group having “a monovalent alicyclic hydrocarbon group having 5 or more carbon atoms” or a group having “an aryl group having 6 or more carbon atoms”. R₂ is a divalent linking group. Rf is a fluorine atom, or an alkyl group substituted with at least one fluorine atom. M₁⁺ is a monovalent cation. n₁ and n₂ each independently are 0 or 1.

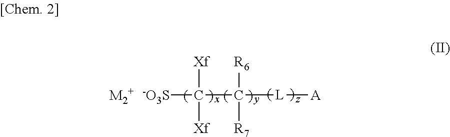

In General Formula (II), Xf and A each independently represent an alkyl group having 1 to 5 carbon atoms or a fluorine atom, and Xfs may be bonded to each other to form a ring. Xfs which are present in plural number may be the same as or different from each other.

R₆ and R₇ each independently represent a hydrogen atom, a fluorine atom or an alkyl group and R₆ and R₇ may be the same as or different from each other when present in plural number.

L represents a divalent linking group and Ls may be the same as or different from each other when present in plural number.

x represents an integer of 1 to 20, y represents an integer of 0 to 10, and z represents an integer of 0 to 10.

M₂⁺ represents a monovalent cation.

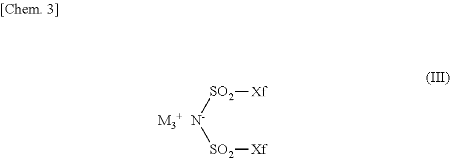

In General Formula (III), Xfs each independently are synonymous with Xfs in General Formula (II), Xfs may be the same as or different from each other, and may be bonded to each other to form a ring. M₃⁺ represents a monovalent cation.

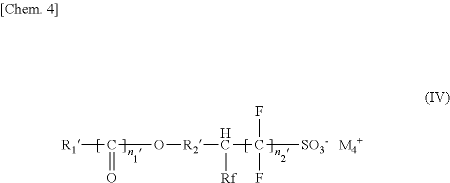

In General Formula (IV), R₁′ is an alkyl group having 1 to 5 carbon atoms. R₂′ is a divalent linking group. Rf′ is a fluorine atom, or an alkyl group substituted with at least one fluorine atom. M₄⁺ is a monovalent cation. n₁′ and n₂′ each independently are 0 or 1.

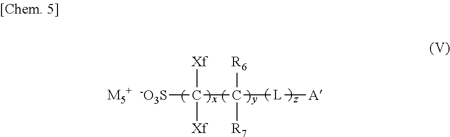

In General Formula (V), Xf, R₆, R₇, L, x, y, and z are synonymous with Xf, R₆, R₇, L, x, y, and z in General Formula (II).

A′ represents a monovalent alicyclic hydrocarbon group having 5 or more carbon atoms or an aryl group having 6 or more carbon atoms.

M₅⁺ represents a monovalent cation.

[2] The actinic ray-sensitive or radiation-sensitive resin composition according to [1], wherein the resin (B) is a resin having a repeating unit represented by the following General Formula (AIII).

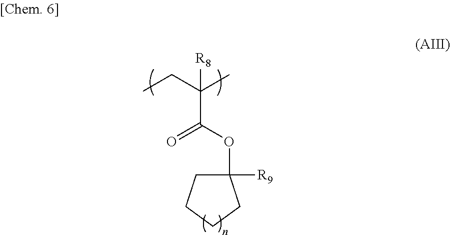

R₈ represents a hydrogen atom or an alkyl group. R₉ represents an alkyl group. n represents an integer of 1 to 6.

[3] The actinic ray-sensitive or radiation-sensitive resin composition according to [1] or

[2], further including a low molecular compound containing a nitrogen atom and a group capable of being detached by the action of an acid.

[4] The actinic ray-sensitive or radiation-sensitive resin composition according any one of [1] to [3], wherein the resin (B) is a resin containing a repeating unit having a lactone structure or a sultone structure represented by the following General Formula (VI).

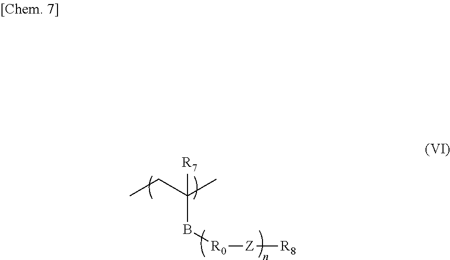

In General Formula (VI), B represents an ester bond or an amide bond.

R₀ represents an alkylene group, a cycloalkylene group or a combination thereof, and when R₀ is present in plural number, the plural R₀s may be the same as or different from each other.

Z represents a single bond, an ether bond, an ester bond, an amide bond, a urethane bond or a urea bond. When Z is present in plural number, the plural Zs may be the same as or different from each other.

R₈ represents a monovalent organic group having a lactone structure or a sultone structure.

n is the number of repetitions of the structure represented by —R₀—Z—, and represents an integer of 0 to 2.

R₇ represents a hydrogen atom, a halogen atom or an alkyl group.

[5] The actinic ray-sensitive or radiation-sensitive resin composition according to [4], wherein n is 1 or 2 in General Formula (VI).

[6] A resist film which is formed using the actinic ray-sensitive or radiation-sensitive resin composition according any one of [1] to [5].

[7] A pattern forming method including exposing and developing the resist film according to [6].

[8] The pattern forming method according to [7], wherein the exposure is an immersion exposure.

[9] An electronic device manufacturing method including the pattern forming method according to [7] or [8].

[10] An electronic device which is manufactured using the electronic device manufacturing method according to [9].

According to the present invention, an actinic ray-sensitive or radiation-sensitive resin composition having liquid properties such that depth of focus latitude (Depth of Focus) is large and the occurrence of particles is small over time, and a resist film using the composition, a pattern forming method, an electronic device manufacturing method, and an electronic device, may be provided.

### DESCRIPTION OF THE PREFERRED EMBODIMENTS

In the notation of a group (an atomic group) in the present specification, a notation in which substituted and unsubstituted are not specified includes not only a group (an atomic group) having no substituents, but also a group (an atomic group) having a substituent. For example, an “alkyl group” includes not only an alkyl group having no substituents (an unsubstituted alkyl group), but also an alkyl group having a substituent (a substituted alkyl group).

“Actinic rays” or “radiation” in the present specification means, for example, a bright line spectrum of a mercury lamp, far ultraviolet rays represented by an excimer laser, extreme ultraviolet rays (EUV light), X-rays, an electron beam (EB) and the like. In addition, in the present invention, “light” means actinic rays or radiation.

In addition, “exposure” in the present specification includes, unless otherwise specified, not only an exposure by a mercury lamp, far ultraviolet rays represented by an excimer laser, X-rays, EUV light and the like, but also a drawing by particle rays such as an electron beam or an ion beam.

An actinic ray-sensitive or radiation-sensitive resin composition of the present invention includes (A) a compound capable of generating an acid by irradiation of actinic rays or radiation and (B) a resin of which solubility in an alkali developer is increased by being decomposed by the action of an acid, and the actinic ray-sensitive or radiation-sensitive resin composition contains a combination of the following compounds of (A-1) or a combination of the following compounds of (A-2) as the compound (A).

(A-1) A combination of a compound represented by the following General Formula (I) and a compound represented by the following General Formulae (II) or (III)

(A-2) A combination of a compound represented by the following General Formula (IV) and a compound represented by the following General Formula (V)

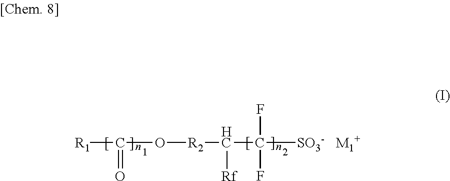

In General Formula (I), R₁ is a group having “a monovalent alicyclic hydrocarbon group having 5 or more carbon atoms” or a group having “an aryl group having 6 or more carbon atoms”. R₂ is a divalent linking group. Rf is a fluorine atom, or an alkyl group substituted with at least one fluorine atom. M₁⁺ is a monovalent cation. n₁ and n₂ each independently are 0 or 1.

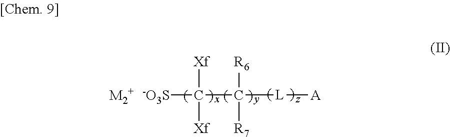

In General Formula (II), Xf and A each independently represent an alkyl group having 1 to 5 carbon atoms or a fluorine atom, and Xfs may be bonded to each other to form a ring. Xfs which are present in plural number may be the same as or different from each other.

R₆ and R₇ each independently represent a hydrogen atom, a fluorine atom or an alkyl group and R₆ and R₇ may be the same as or different from each other when present in plural number.

L represents a divalent linking group and Ls may be the same as or different from each other when present in plural number.

x represents an integer of 1 to 20, y represents an integer of 0 to 10, and z represents an integer of 0 to 10.

M₂⁺ represents a monovalent cation.

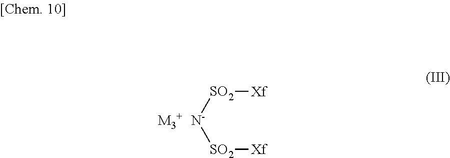

In General Formula (III), Xfs each independently are synonymous with Xfs in General Formula (II), Xfs may be the same as or different from each other, and may be bonded to each other to form a ring. M₃⁺ represents a monovalent cation.

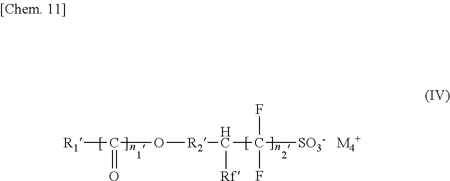

In General Formula (IV), R₁′ is an alkyl group having 1 to 5 carbon atoms. R₂′ is a divalent linking group. Rf′ is a fluorine atom, or an alkyl group substituted with at least one fluorine atom. M₄⁺ is a monovalent cation. n₁′ and n₂′ each independently are 0 or 1.

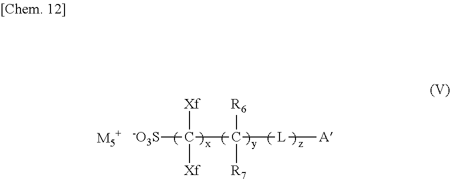

In General Formula (V), Xf, R₆, R₇, L, x, y, and z are synonymous with Xf, R₆, R₇, L, x, y, and z in General Formula (II).

A′ represents a monovalent alicyclic hydrocarbon group having 5 or more carbon atoms or an aryl group having 6 or more carbon atoms.

M₅⁺ represents a monovalent cation.

The actinic ray-sensitive or radiation-sensitive resin composition of the present invention contains a combination of the compound of (A-1) or a combination of the compound of (A-2) as the compound (A) (an acid generator) as described above.

Here, in the compound represented by General Formula (I) in the combination of the compounds of (A-1), R₁ is a group having “a monovalent alicyclic hydrocarbon group having 5 or more carbon atoms” or a group having “an aryl group having 6 or more carbon atoms”, and is a cyclic group with a relatively large number of carbon atoms. Therefore, the length of acid diffusion of the acid generated from the compound represented by General Formula (I) in the exposed portion becomes relatively small.

Meanwhile, in the compound represented by General Formula (II) or (III) in the combination of the compound of (A-1), particularly, A is an alkyl group having 1 to 5 carbon atoms in General Formula (II), and Xf is an alkyl group having 1 to 5 carbon atoms or a fluorine atom in General Formula (III). Therefore, the length of acid diffusion of the acid generated from the compound represented by General Formula (II) or (III) in the exposed portion becomes relatively large since both A in General Formulae (II) and Xf in General Formula (III) do not correspond to cyclic groups, and the number of carbon atoms is also suppressed.

In addition, in the compound represented by General Formula (IV) in the combination of the compounds of (A-2), R₁′ is an alkyl group having 1 to 5 carbon atoms (in more detail, a chain alkyl group having 1 to 5 carbon atoms, and the chain alkyl group may be any of a straight chain alkyl group and a branched chain alkyl group, a straight chain alkyl group being preferable), does not correspond to a cyclic group, and the number of carbon atoms is also suppressed. Therefore, the length of acid diffusion of the acid generated from the compound represented by General Formula (IV) in the exposed portion becomes relatively large.

Furthermore, in the compound represented by General Formula (V) in the combination of the compound of (A-2), A′ is a monovalent alicyclic hydrocarbon group having 5 or more carbon atoms or an aryl group having 6 or more carbon atoms, and is a cyclic group with a relatively large number of carbon atoms. Therefore, the length of acid diffusion of the acid generated from the compound represented by General Formula (V) in the exposed portion becomes relatively small.

That is, in both the combination of the compounds of (A-1), and the combination of the compounds of (A-2), an acid generator in which the length of acid diffusion of the acid generated becomes small since a terminal portion of the anion (the terminal portion which is on the opposite side to a sulfonate anion portion) is bulky, and an acid generator in which the length of acid diffusion of the acid generated becomes large since a terminal portion of the anion is not bulky are combined.

As described above, it is postulated that, by combining a plurality of types of acid generators generating acids having different lengths of acid diffusion due to structural differences of an anion, acid distribution of the thickness direction of a resist film after a heating step which is carried out after exposure becomes uniformized, and therefore, latitude for depth of focus changes is improved.

In addition, the compound represented by General Formula (I) used in the combination of the compounds of (A-1), and the compound represented by General Formula (IV) used in the combination of the compounds of (A-2), include a structure of —CHRf— and —CHRf′—, respectively, and when n₂ and n₂′ in adjacent positions of sulfonate anions are 0, the number of fluorine atoms bonded to carbon atoms corresponding to an α-position, and when n₂ and n₂′ are 1, the number of fluorine atoms bonded to carbon atoms corresponding to a β-position, are small, respectively. Therefore, it is considered that the response of the reaction with the resin (B) and the acid with respect to depth of focus changes becoming slow due to the strength of the sulfonic acid generated from this acid generator being weak also contributes to the expansion of depth of focus latitude.

In addition, it is postulated that, in the combination of the compounds of (A-1) and the combination of the compounds of (A-2), two or more types of acid generators are used in combination and as a result, compatibility of an actinic ray-sensitive or radiation-sensitive resin composition as liquid is increased, and the occurrence of particles over time is suppressed.

The actinic ray-sensitive or radiation-sensitive resin composition of the present invention is, for example, a positive-tone composition, and is typically a positive-tone resist composition. Hereinafter, each component of the composition will be described.

[1] (A) Compound Capable of Generating Acid by Irradiation of Actinic Rays or Radiation

The actinic ray-sensitive or radiation-sensitive resin composition of the present invention is a compound capable of generating an acid by irradiation of actinic rays or radiation as described above (hereinafter, simply referred to as an acid generator), and contains the combination of the compounds of (A-1) or the combination of the compounds of (A-2).

Hereinafter, the compounds represented by General Formulae (I) to (V) in the combination of the compounds of (A-1) or the combination of the compounds of (A-2) will be described.

First, the compound represented by General Formula (I) will be described.

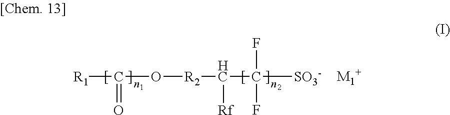

In General Formula (I), R₁ is a group having “a monovalent alicyclic hydrocarbon group having 5 or more carbon atoms” or a group having “an aryl group having 6 or more carbon atoms”. R₂ is a divalent linking group. Rf is a fluorine atom, or an alkyl group substituted with at least one fluorine atom. M₁⁺ is a monovalent cation. n₁ and n₂ each independently are 0 or 1.

In the present invention, in the alicyclic hydrocarbon group, the ring of the alicyclic hydrocarbon group having a heteroatom such as a nitrogen atom, an oxygen atom and a sulfur atom as a ring member is included, and the ring having a carbonyl carbon as a ring member is also included. In addition, the bonds constituting the ring of the alicyclic hydrocarbon group may be unsaturated bonds.

In addition, in the aryl group, the aromatic ring of the aryl group having a heteroatom such as a nitrogen atom, an oxygen atom and a sulfur atom as a ring member is also included.

The “monovalent alicyclic hydrocarbon group having 5 or more carbon atoms” in the group having “a monovalent alicyclic hydrocarbon group having 5 or more carbon atoms” of R₁ is preferably a group having 20 or less carbon atoms, and more preferably a group having 15 or less carbon atoms. The group having “a monovalent alicyclic hydrocarbon group having 5 or more carbon atoms” may be a group having a monocyclic alicyclic hydrocarbon group or a group having a polycyclic alicyclic hydrocarbon group. In addition, the group having “a monovalent alicyclic hydrocarbon group having 5 or more carbon atoms” may have a plurality of monocyclic or polycyclic alicyclic hydrocarbon groups. The group having “a monovalent alicyclic hydrocarbon group having 5 or more carbon atoms” may suitably include a monocyclic or polycyclic alicyclic hydrocarbon group itself or an alkyl group having “a monocyclic or polycyclic alicyclic hydrocarbon group having 5 or more carbon atoms”.

The total number of carbon atoms of the alkyl group having “a monocyclic or polycyclic alicyclic hydrocarbon group having 5 or more carbon atoms” is preferably 20 or less.

As the monocyclic alicyclic hydrocarbon group, a group having 5 to 12 carbon atoms is preferable, and a cyclopentyl group, a cyclohexyl group, a cycloheptyl group, a cyclooctyl group, a cyclododecanyl group, a cyclopentenyl group, a cyclohexenyl group, a cyclooctadienyl group, a piperidine ring group or the like, and particularly, a cyclopentyl group, a cyclohexyl group or a cyclooctyl group is preferable.

As the polycyclic alicyclic hydrocarbon group, a group having 10 to 20 carbon atoms is preferable, and a bicyclo[4.3.0]nonanyl group, a decahydronaphthalenyl group, a 1,2,3,4-tetrahydronaphthalenyl group, a tricyclo[5.2.1.0^{2,6}]decanyl group, a tetracyclodecanyl group, a tetracyclododecanyl group, a bornyl group, an isobornyl group, a norbornyl group, an adamantyl group, a noradamantyl group, a 1,7,7-trimethyltricyclo[2.2.1.0^{2,6}]heptanyl group, a 3,7,7-trimethylbicyclo[4.1.0]heptanyl group, a decahydro isoquinoline ring group or the like may be included, and a norbornyl group, an adamantyl group or a noradamantyl group is preferable.

The “aryl group having 6 or more carbon atoms” in the group having “an aryl group having 6 or more carbon atoms” of R₁ is preferably a group having 20 or less carbon atoms, and more preferably a group having 15 or less carbon atoms. The group having “an aryl group having 6 or more carbon atoms” may be a group having a monocyclic aryl group or a group having a polycyclic aryl group. In addition, the group having “an aryl group having 6 or more carbon atoms” may have a plurality of monocyclic or polycyclic aryl groups. The group having “an aryl group having 6 or more carbon atoms” may suitably include a monocyclic or polycyclic aryl group itself or an alkyl group having “a monocyclic or polycyclic aryl group having 6 or more carbon atoms”.

The total number of carbon atoms of the alkyl group having “a monocyclic or polycyclic aryl group having 6 or more carbon atoms” is preferably 20 or less.

The monocyclic aryl group may include a phenyl group or the like.

The polycyclic aryl group may include a naphthyl group, an anthracenyl group or the like.

R₁ is particularly preferably a cyclohexyl group or an adamantyl group.

The group having “a monovalent alicyclic hydrocarbon group having 5 or more carbon atoms” and “an aryl group having 6 or more carbon atoms” as R₁ may further have a substituent and the further substituent may include a hydroxyl group, a halogen atom (a fluorine atom, a chlorine atom, a bromine atom, an iodine atom or the like), a nitro group, a cyano group, an amide group, a sulfonamide group, an alkyl group such as a methyl group, an ethyl group, a propyl group, an n-butyl group, a sec-butyl group, a hexyl group, a 2-ethylhexyl group or an octyl group, an alkoxy group such as a methoxy group, an ethoxy group, a hydroxyethoxy group, a propoxy group, a hydroxypropoxy group or a butoxy group, an alkoxycarbonyl group such as a methoxycarbonyl group or an ethoxycarbonyl group, an acyl group such as a formyl group, an acetyl group or a benzoyl group, an acyloxy group such as an acetoxy group or a butyryloxy group, or a carboxyl group.

The divalent linking group of R₂ is not particularly limited, but may include —COO—, —OCO—, —CO—, —O—, —S—, —SO—, —SO₂—, an alkylene group, a cycloalkylene group, an alkenylene group, and a group in which two or more of these are combined. Among these, an alkylene group (preferably an alkylene group having 1 to 5 carbon atoms) is preferable. The alkylene group, the alkenylene group and the cycloalkylene group may further have a substituent, and specific examples of the substituent are the same substituents which may be further included in the group having “a monovalent alicyclic hydrocarbon group having 5 or more carbon atoms” and “an aryl group having 6 or more carbon atoms” as R₁ described above.

Rf is a fluorine atom, or an alkyl group substituted with at least one fluorine atom. The number of carbon atoms of this alkyl group is preferably 1 to 30, more preferably 1 to 10, and even more preferably 1 to 4. In addition, the alkyl group substituted with at least one fluorine atom is preferably a perfluoroalkyl group.

Rf is preferably a fluorine atom or a perfluoroalkyl group having 1 to 4 carbon atoms. More specifically, Rf is preferably a fluorine atom, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, or CH₂CH₂C₄F₉, and more preferably a fluorine atom or CF₃. In particular, it is preferable that both Xfs be fluorine atoms.

n₂ is preferably 1.

Examples of the monovalent cation represented by M₁⁺ include a cation represented by the following General Formula (ZI) or (ZII).

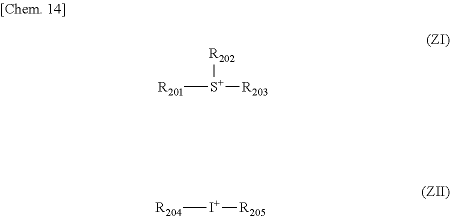

First, General Formula (ZI) will be described.

In General Formulae (ZI), R₂₀₁, R₂₀₂, and R₂₀₃ each independently represent an organic group.

The number of carbon atoms of the organic group as R₂₀₁, R₂₀₂ and R₂₀₃ is generally 1 to 30, and preferably 1 to 20.

In addition, two of R₂₀₁ to R₂₀₃ may be bonded to each other to form a ring structure, and the ring structure may include an oxygen atom, a sulfur atom, an ester bond, an amide bond or a carbonyl group within the ring. Examples of the group formed by two of R₂₀₁ to R₂₀₃ being bonded may include an alkylene group (for example, a butylene group or a pentylene group).

Examples of the organic group represented by R₂₀₁, R₂₀₂, and R₂₀₃ include corresponding groups in cations (ZI-1), (ZI-2), (ZI-3) and (ZI-4) described later.

The cation (ZI-1) is an aryl sulfonium cation in which at least one of R₂₀₁ to R₂₀₃ of General Formula (ZI) is an aryl group.

In the aryl sulfonium cation, all of R₂₀₁ to R₂₀₃ may be aryl groups, or a part of R₂₀₁ to R₂₀₃ may be aryl groups with the remaining ones being alkyl groups or cycloalkyl groups.

Examples of the aryl sulfonium cation include a triarylsulfonium cation, a diaryl alkyl sulfonium cation, an aryl dialkyl sulfonium cation, a diaryl cycloalkyl sulfonium cation or an aryl dicycloalkyl sulfonium cation.

The aryl group in the aryl sulfonium cation is preferably a phenyl group or a naphthyl group, and more preferably a phenyl group. The aryl group may be an aryl group having a heterocyclic structure containing an oxygen atom, a nitrogen atom, a sulfur atom or the like. The heterocyclic structure may include a pyrrole residue, a furan residue, a thiophene residue, an indole residue, a benzofuran residue, a benzothiophene residue, or the like. When the aryl sulfonium compound has two or more aryl groups, these two or more aryl groups may be the same as or different from each other.

The alkyl group or the cycloalkyl group which is present as necessary in the aryl sulfonium cation is preferably a linear or branched alkyl group having 1 to 15 carbon atoms and a cycloalkyl group having 3 to 15 carbon atoms, and includes, for example, a methyl group, an ethyl group, a propyl group, an n-butyl group, a sec-butyl group, a t-butyl group, a cyclopropyl group, a cyclobutyl group, a cyclohexyl group or the like.

The aryl group, the alkyl group, and the cycloalkyl group of R₂₀₁ to R₂₀₃ may have an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a halogen atom, a hydroxyl group or a phenylthio group as a substituent. The substituent is preferably a linear or branched alkyl group having 1 to 12 carbon atoms, a cycloalkyl group having 3 to 12 carbon atoms, or a linear, branched or cyclic alkoxy group having 1 to 12 carbon atoms, and more preferably an alkyl group having 1 to 4 carbon atoms or an alkoxy group having 1 to 4 carbon atoms. The substituent may be substituted on any one of three R₂₀₁ to R₂₀₃, or may be substituted on all three. In addition, when R₂₀₁ to R₂₀₃ are aryl groups, the substituents are preferably substituted on p-positions of the aryl groups.

Next, a cation (ZI-2) will be described.

The cation (ZI-2) is a compound in which R₂₀₁ to R₂₀₃ in Formula (ZI) each independently represent an organic group which does not have an aromatic ring. Here, the aromatic ring also includes an aromatic ring containing a heteroatom.

The organic group which does not contain an aromatic ring as R₂₀₁ to R₂₀₃ generally has 1 to 30 carbon atoms, and preferably 1 to 20 carbon atoms.

R₂₀₁ to R₂₀₃ each independently are preferably an alkyl group, a cycloalkyl group, an allyl group or a vinyl group, more preferably a linear or branched 2-oxoalkyl group, a 2-oxocycloalkyl group, an alkoxycarbonyl methyl group, and particularly preferably a linear or branched 2-oxoalkyl group.

Preferable examples of the alkyl group and the cycloalkyl group of R₂₀₁ to R₂₀₃ may include a linear or branched alkyl group having 1 to 10 carbon atoms (for example, a methyl group, an ethyl group, a propyl group, a butyl group or a pentyl group), a cycloalkyl group having 3 to 10 carbon atoms (a cyclopentyl group, a cyclohexyl group or a norbornyl group). More preferable examples of the alkyl group may include a 2-oxoalkyl group or an alkoxycarbonyl methyl group. More preferable examples of the cycloalkyl group may include a 2-oxocycloalkyl group.

The 2-oxoalkyl group may be either linear or branched and preferably include a group having >C═O at 2-position of the above alkyl group.

The 2-oxocycloalkyl group may preferably include a group having >C═O at 2-position of the above cycloalkyl group.

The alkoxy group in the alkoxycarbonyl methyl group may preferably include an alkoxy group having 1 to 5 carbon atoms (a methoxy group, an ethoxy group, a propoxy group, a butoxy group or a pentoxy group).

R₂₀₁ to R₂₀₃ may be further substituted with a halogen atom, an alkoxy group (for example, having 1 to 5 carbon atoms), a hydroxyl group, a cyano group or a nitro group.

Next, a cation (ZI-3) will be described.

The cation (ZI-3) is a cation represented by the following General Formula (ZI-3) below, and is a cation having a phenacylsulfonium structure.

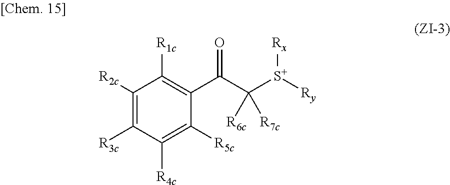

In General Formula (ZI-3), R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group or an arylthio group.

R_{6c} and R_{7c} each independently represent a hydrogen atom, an alkyl group, a cycloalkyl group, a halogen atom, a cyano group or an aryl group.

Rₓ and R_{y} each independently represent an alkyl group, a cycloalkyl group, a 2-oxoalkyl group, a 2-oxocycloalkyl group, an alkoxycarbonyl alkyl group, an allyl group or a vinyl group.

Any two or more of R_{1c} to R_{5c}, R_{5c} and R_{6c}, R_{6c} and R_{7c}, R_{5c} and Rₓ, and Rₓ and R_{y}, may be bonded to each other to form a ring structure, and this ring structure may include an oxygen atom, a sulfur atom, a ketone group, an ester bond or an amide bond.

The ring structure may include an aromatic or non-aromatic hydrocarbon ring, an aromatic or non-aromatic heterocyclic ring, or a polycyclic condensed ring formed by two or more of these rings being combined. As the ring structure, 3- to 10-membered rings may be included, 4- to 8-membered rings are preferable, and 5- or 6-membered rings are more preferable.

The group formed by any two or more of R_{1c} to R_{5c}, R_{6c} and R_{7c}, and Rₓ and R_{y} being bonded may include a butylene group, pentylene group or the like.

The group formed by R_{5c} and R_{6c}, and R_{5c} and Rₓ being bonded is preferably a single bond or an alkylene group, and as the alkylene group, a methylene group, an ethylene group or the like may be included.

The alkyl group as R_{1c} to R_{7c} may be either linear or branched, and includes, for example, an alkyl group having 1 to 20 carbon atoms, preferably a linear or branched alkyl group having 1 to 12 carbon atoms (for example, a methyl group, an ethyl group, a linear or branched propyl group, a linear or branched butyl group, or a linear or branched pentyl group), and the cycloalkyl group includes, for example, a cycloalkyl group having 3 to 10 carbon atoms (for example, a cyclopentyl group or a cyclohexyl group).

The aryl group as R_{1c} to R_{7c} preferably has 5 to 15 carbon atoms, and includes, for example, a phenyl group or a naphthyl group.

The alkoxy group as R_{1c} to R_{5c} may be any of linear, branched and cyclic, and includes, for example, an alkoxy group having 1 to 10 carbon atoms, preferably, a linear and branched alkoxy group having 1 to 5 carbon atoms (for example, a methoxy group, an ethoxy group, a linear or branched propoxy group, a linear or branched butoxy group, or a linear or branched pentoxy group), and a cyclic alkoxy group having 3 to 10 carbon atoms (for example, a cyclopentyloxy group or a cyclohexyloxy group).

Specific examples of the alkoxy group in the alkoxycarbonyl group as R_{1c} to R_{5c} are the same as specific examples of the alkoxy group as R_{1c} to R_{5c} described above.

Specific examples of the alkyl group in the alkylcarbonyloxy group and the alkylthio group as R_{1c} to R_{5c} are the same as specific examples of the alkyl group as R_{1c} to R_{5c} described above.

Specific examples of the cycloalkyl group in the cycloalkyl carbonyloxy group as R_{1c} to R_{5c} are the same as specific examples of the cycloalkyl group of R_{1c} to R_{5c} described above.

Specific examples of the aryl group in the aryloxy group and the arylthio group as R_{1c} to R_{5c} are the same as specific examples of the aryl group R_{1c} to R_{5c} described above.

Preferably, any of R_{1c} to R_{5c} is a linear or branched alkyl group, a cycloalkyl group, or a linear, branched or cyclic alkoxy group, and more preferably, the total number of carbon atoms in R_{1c} to R_{5c} is 2 to 15. As a result, solubility in a solvent is further improved and the generation of particles is suppressed during storage.

The ring structure which may be formed by any two or more of R_{1c} to R_{5c} being bonded to each other may preferably include a 5-membered or 6-membered ring, and particularly preferably include a 6-membered ring (for example, a phenyl ring).

The ring structure which may be formed by R_{5c} and R_{6c} being bonded to each other may include a 4- or higher membered (particularly preferably a 5- to 6-membered ring) formed together with a carbonyl carbon atom and a carbon atom in General Formula (ZI-3) by R_{5c} and R_{6c} being bonded to each other and constituting a single bond or an alkylene group (a methylene group, an ethylene group, or the like).

As an embodiment of R_{6c} and R_{7c}, it is preferable that both of them be an alkyl group. In particular, it is preferable that each of R_{6c} and R_{7c} be a linear or branched alkyl group having 1 to 4 carbon atoms, and particularly, it is preferable that both be a methyl group.

In addition, when R_{6c} and R_{7c} are bonded to each other to form a ring, the group formed by R_{6c} and R_{7c} being bonded is preferably an alkylene group having 2 to 10 carbon atoms, and includes, for example, an ethylene group, a propylene group, a butylene group, a pentylene group, a hexylene group, or the like. Furthermore, the ring formed by R_{6c} and R_{7c} being bonded may have a heteroatom such as an oxygen atom within the ring.

The alkyl group and the cycloalkyl group as Rₓ and R_{y} may include the same alkyl group and the cycloalkyl group as R_{1c} to R_{7c}.

The 2-oxoalkyl group and the 2-oxocycloalkyl group as Rₓ and R_{y} may include the group having >C═O at 2-position of the alkyl group and the cycloalkyl group as R_{1c} to R_{7c}.

The alkoxy group in the alkoxycarbonyl alkyl group as Rₓ and R_{y} may include the same alkoxy group as R_{1c} to R_{5c}, and the alkyl groups include, for example, an alkyl group having 1 to 12 carbon atoms, and preferably include a linear alkyl group having 1 to 5 carbon atoms (for example, a methyl group or an ethyl group).

The allyl group as Rₓ and R_{y} is not particularly limited, but is preferably an unsubstituted allyl group, or an allyl group substituted with a monocyclic or polycyclic cycloalkyl group (preferably a cycloalkyl group having 3 to 10 carbon atoms).

The vinyl group as Rₓ and R_{y} is not particularly limited, but is preferably an unsubstituted vinyl group, or a vinyl group substituted with a monocyclic or polycyclic cycloalkyl group (preferably a cycloalkyl group having 3 to 10 carbon atoms).

The ring structure which may be formed by R_{5c} and Rₓ being bonded to each other may include a 5- or higher membered ring (particularly preferably a 5-membered ring) formed together with a sulfur atom and a carbonyl carbon atom in General Formula (I) by R_{5c} and Rₓ being bonded to each other and constituting a single bond or an alkylene group (a methylene group, an ethylene group, or the like).

The ring structure which may be formed by Rₓ and R_{y} being bonded to each other may include a 5-membered or 6-membered ring, particularly preferably a 5-membered ring (that is, a tetrahydrothiophene ring) formed by divalent Rₓ and R_{y} (for example, a methylene group, an ethylene group, a propylene group or the like) together with a sulfur atom in General Formula (ZI-3).

Rₓ and R_{y} are preferably an alkyl group or a cycloalkyl group having 4 or more carbon atoms, more preferably an alkyl group or a cycloalkyl group having 6 or more carbon atoms, even more preferably an alkyl group or a cycloalkyl group having 8 or more carbon atoms.

R_{1c} to R_{7c}, Rₓ, and R_{y} may further have a substituent and the substituent may include a halogen atom (for example, a fluorine atom), a hydroxyl group, a carboxyl group, a cyano group, a nitro group, an alkyl group, a cycloalkyl group, an aryl group, an alkoxy group, an aryloxy group, an acyl group, an arylcarbonyl group, an alkoxyalkyl group, an aryloxyalkyl group, an alkoxycarbonyl group, an aryloxycarbonyl group, an alkoxycarbonyloxy group, an aryloxycarbonyloxy group, or the like.

Examples of the alkyl group include a linear or branched alkyl group having 1 to 12 carbon atoms such as a methyl group, an ethyl group, an n-propyl group, an i-propyl group, an n-butyl group, a 2-methylpropyl group, a 1-methylpropyl group or a t-butyl group.

Examples of the cycloalkyl group include a cycloalkyl group having 3 to 10 carbon atoms such as a cyclopentyl group or a cyclohexyl group.

Examples of the aryl group include an aryl group having 6 to 15 carbon atoms such as a phenyl group or a naphthyl group.

Examples of the alkoxy group include a linear, branched or cyclic alkoxy group having 1 to 20 carbon atoms such as a methoxy group, an ethoxy group, an n-propoxy group, an i-propoxy group, an n-butoxy group, a 2-methylpropoxy group, a 1-methylpropoxy group, a t-butoxy group, a cyclopentyloxy group or a cyclohexyloxy group.

Examples of the aryloxy group include an aryloxy group having 6 to 10 carbon atoms such as a phenyloxy group or a naphthyloxy group.

Examples of the acyl group include a linear or branched acyl group having 2 to 12 carbon atoms such as an acetyl group, a propionyl group, an n-butanoyl group, an i-butanoyl group, an n-heptanoyl group, a 2-methylbutanoyl group, a 1-methylbutanoyl group or a t-heptanoyl group.

Examples of the arylcarbonyl group include an aryloxy group having 6 to 10 carbon atoms such as a phenylcarbonyl group or a naphthylcarbonyl group.

Examples of the alkoxyalkyl group include a linear, branched or cyclic alkoxyalkyl group having 2 to 21 carbon atoms such as a methoxymethyl group, an ethoxymethyl group, a 1-methoxyethyl group, a 2-methoxyethyl group, a 1-ethoxyethyl group or a 2-ethoxyethyl group.

Examples of the aryloxyalkyl group may include an aryloxy group having 7 to 12 carbon atoms such as a phenyloxymethyl group, a phenyloxyethyl group, a naphthyloxymethyl group or a naphthyloxyethyl group.

Examples of the alkoxycarbonyl group include a linear, branched or cyclic alkoxycarbonyl group having 2 to 21 carbon atoms such as a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, a cyclopentyloxycarbonyl group or a cyclohexyloxycarbonyl group.

Examples of the aryloxycarbonyl group include an aryloxycarbonyl group having 7 to 11 carbon atoms such as a phenyloxycarbonyl group or a naphthyloxycarbonyl group.

Examples of the alkoxycarbonyloxy group include a linear, branched or cyclic alkoxycarbonyloxy group having 2 to 21 carbon atoms such as a methoxycarbonyloxy group, an ethoxycarbonyloxy group, an n-propoxycarbonyloxy group, an i-propoxycarbonyloxy group, an n-butoxycarbonyloxy group, a t-butoxycarbonyloxy group, a cyclopentyloxycarbonyloxy group or a cyclohexyloxycarbonyloxy group.

Examples of the aryloxycarbonyloxy group include an aryloxycarbonyloxy group having 7 to 11 carbon atoms such as a phenyloxycarbonyloxy group or a naphthyloxycarbonyloxy group.

In General Formula (ZI-3), it is more preferable that R_{1c}, R_{2c}, R_{4c}, and R_{5c} each independently represent a hydrogen atom, and R₃ represent a group other than a hydrogen atom, that is, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group or an arylthio group.

As the cation (ZI-2) or (ZI-3) in the present invention, specific examples below may be included.

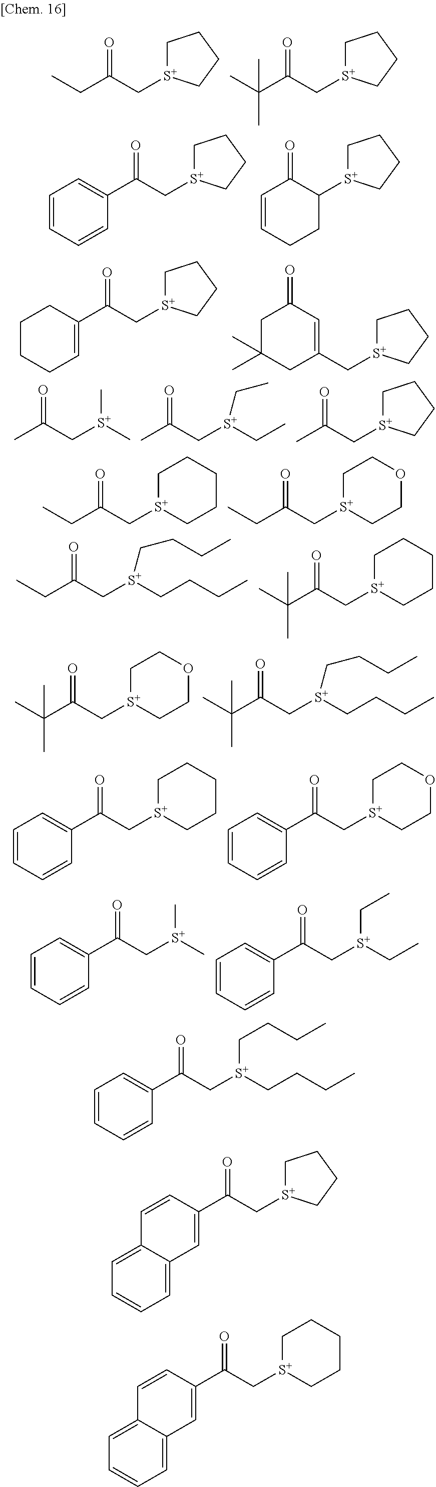

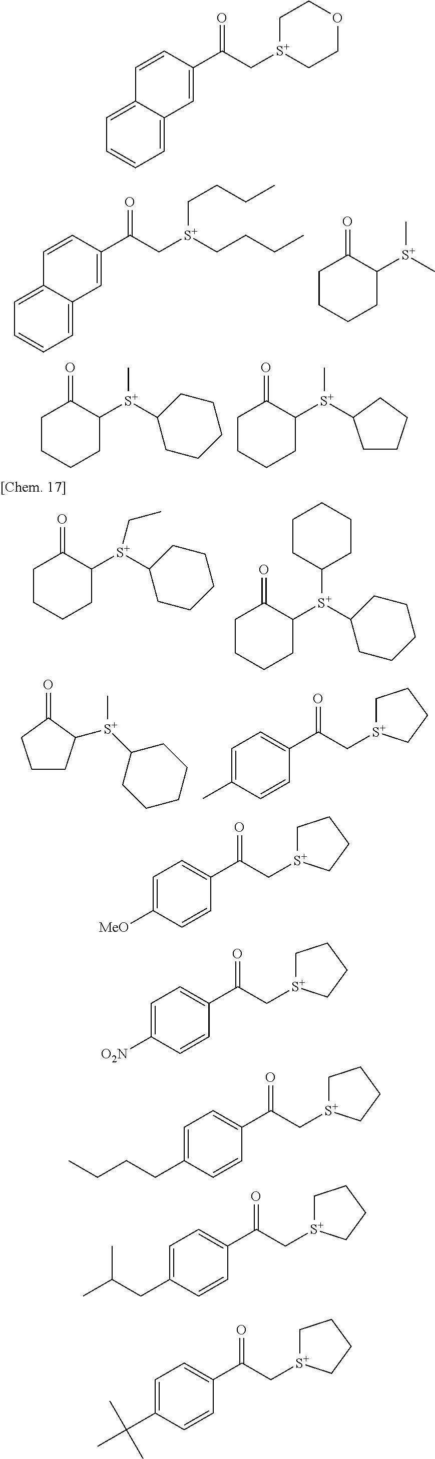

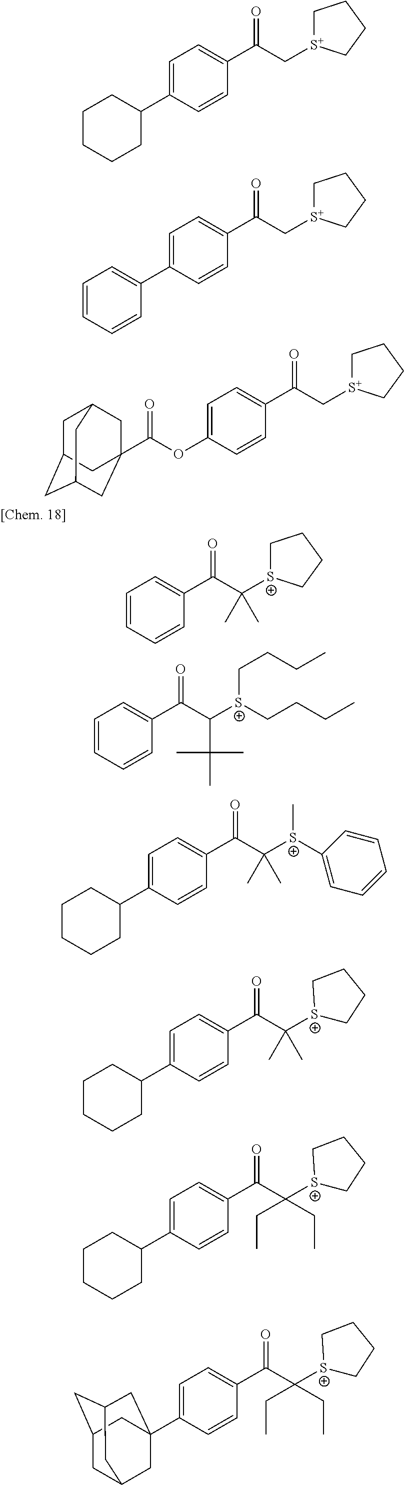

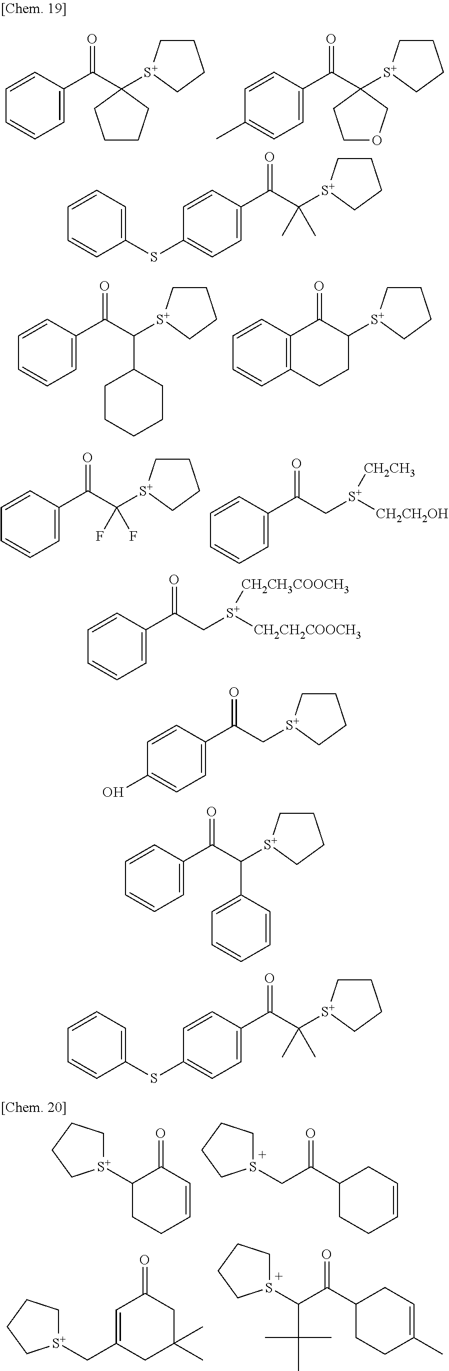

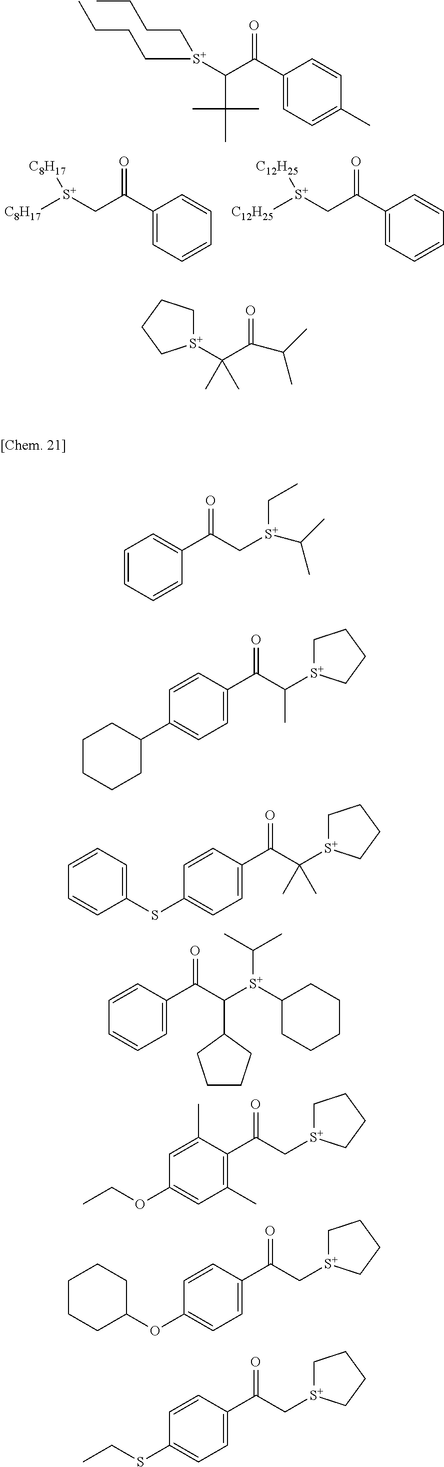

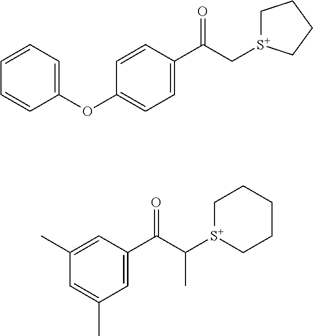 [SMILES: O=C(C[S+]1CCCC1)c1ccc(Oc2ccccc2)cc1 ; Cc1cc(C)cc(C(=O)C(C)[S+]2CCCCC2)c1]

Next, a cation (ZI-4) will be described.

The cation (ZI-4) is represented by the following General Formula (ZI-4).

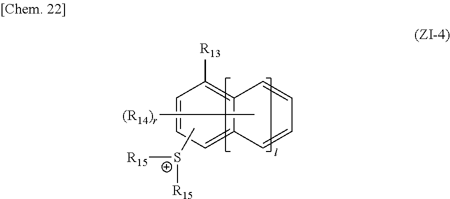

In General Formula (ZI-4), R₁₃ represents a hydrogen atom, a fluorine atom, a hydroxyl group, an alkyl group, a cycloalkyl group, an alkoxy group, an alkoxycarbonyl group, or a group having a cycloalkyl group. These groups may have a substituent.

R₁₄s, when present in plural number, each independently represent a hydroxyl group, an alkyl group, a cycloalkyl group, an alkoxy group, an alkoxycarbonyl group, an alkylcarbonyl group, an alkylsulfonyl group or a cycloalkylsulfonyl group or a group having a cycloalkyl group. These groups may have a substituent.

R₁₅s each independently represent an alkyl group, a cycloalkyl group or a naphthyl group. Two R₁₅s may be bonded to each other to form a ring. These groups may have a substituent.

1 represents an integer of 0 to 2.

r represents an integer of 0 to 8.

In General Formula (ZI-4), the alkyl group of R₁₃, R₁₄, and R₁₅ is linear or branched, and preferably has 1 to 10 carbon atoms, and may include a methyl group, an ethyl group, an n-propyl group, an i-propyl group, an n-butyl group, a 2-methylpropyl group, a 1-methylpropyl group, a t-butyl group, an n-pentyl group, a neopentyl group, an n-hexyl group, an n-heptyl group, an n-octyl group, a 2-ethylhexyl group, an n-nonyl group, an n-decyl group or the like. Among these alkyl groups, a methyl group, an ethyl group, an n-butyl group, a t-butyl group or the like is preferable.

The cycloalkyl group of R₁₃, R₁₄, and R₁₅ may include a monocyclic or polycyclic cycloalkyl group (preferably a cycloalkyl group having 3 to 20 carbon atoms) including a cycloalkenyl group. Specifically cyclopropyl, cyclobutyl, cyclopentyl, cyclohexyl, cycloheptyl, cyclooctyl, cyclododecanyl, cyclopentenyl, cyclohexenyl, cyclooctadienyl, norbornyl, tricyclodecanyl, tetracyclododecanyl or adamantyl may be included, and particularly, cyclopropyl, cyclopentyl, cyclohexyl, cycloheptyl or cyclooctyl is preferable.

The alkoxy group of R₁₃ and R₁₄ is linear or branched, and preferably has 1 to 10 carbon atoms, and includes, for example, a methoxy group, an ethoxy group, an n-propoxy group, an i-propoxy group, an n-butoxy group, a 2-methylpropoxy group, a 1-methylpropoxy group, a t-butoxy group, an n-pentyloxy group, a neopentyloxy group, an n-hexyloxy group, an n-heptyloxy group, an n-octyloxy group, a 2-ethylhexyloxy group, an n-nonyloxy group, an n-decyloxy group, or the like. Among these alkoxy groups, a methoxy group, an ethoxy group, an n-propoxy group or an n-butoxy group is preferable.

The alkoxycarbonyl group of R₁₃ and R₁₄ is linear or branched, and preferably has 2 to 11 carbon atoms, and includes, for example, a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, an n-pentyloxycarbonyl group, a neopentyloxycarbonyl group, an n-hexyloxy carbonyl group, an n-heptyloxycarbonyl group, an n-octyloxycarbonyl group, a 2-ethylhexyloxycarbonyl group, an n-nonyloxycarbonyl, group, n-decyloxycarbonyl group, or the like. Among these alkoxycarbonyl groups, a methoxycarbonyl group, an ethoxycarbonyl group, an n-butoxycarbonyl group or the like is preferable.

The group having a cycloalkyl group of R₁₃ and R₁₄, may include a monocyclic or polycyclic cycloalkyl group (preferably a cycloalkyl group having 3 to 20 carbon atoms), and includes, for example, a monocyclic or polycyclic cycloalkyloxy group, or an alkoxy group having a monocyclic or polycyclic cycloalkyl group. These groups may further have a substituent.

As the monocyclic or polycyclic cycloalkyloxy group of R₁₃ and R₁₄, the total number of carbon atoms is preferably 7 or more, the total number of carbon atoms is more preferably greater than or equal to 7 and less than or equal to 15, and, furthermore, having a monocyclic cycloalkyl group is preferable. The monocyclic cycloalkyloxy group having a total of 7 or more carbon atoms is a monocyclic cycloalkyloxy group in which a cycloalkyloxy group such as a cyclopropyloxy group, a cyclobutyloxy group, a cyclopentyloxy group, a cyclohexyloxy group, a cycloheptyloxy group, a cyclooctyloxy group, or a cyclododecanyloxy group has an arbitrary substituent such as an alkyl group such as a methyl group, an ethyl group, a propyl group, a butyl group, a pentyl group, a hexyl group, a heptyl group, an octyl group, a dodecyl group, a 2-ethylhexyl group, an isopropyl group, a sec-butyl group, a t-butyl group or an iso-amyl group, a hydroxyl group, a halogen atom (a fluorine atom, a chlorine atom, a bromine atom, an iodine atom), a nitro group, a cyano group, an amide group, a sulfonamide group, an alkoxy group such as a methoxy group, an ethoxy group, a hydroxyethoxy group, a propoxy group, a hydroxypropoxy group or a butoxy group, an alkoxycarbonyl group such as a methoxycarbonyl group or an ethoxycarbonyl group, an acyl group such as a formyl group, an acetyl group or a benzoyl group, an acyloxy group such as an acetoxy group or a butyryloxy group, a carboxyl group, or the like, and represents a monocyclic cycloalkyloxy group in which the total number of carbon atoms combined with an arbitrary substituent on the cycloalkyl group is 7 or more.

In addition, the polycyclic cycloalkyloxy group having a total of 7 or more carbon atoms may include a norbornyloxy group, a tricyclodecanyloxy group, a tetracyclodecanyloxy group, an adamantyloxy group, or the like.

As the alkoxy group having a monocyclic or polycyclic cycloalkyl group of R₁₃ and R₁₄, the total number of carbon atoms is preferably 7 or more, the total number of carbon atoms is more preferably greater than or equal to 7 and less than or equal to 15, and, furthermore, an alkoxy group having a monocyclic cycloalkyl group is preferable. The alkoxy group having a monocyclic cycloalkyl group having a total of 7 or more carbon atoms is a group in which the monocyclic cycloalkyl group which may have a substituent described above is substituted on the alkoxy group such as a methoxy group, an ethoxy group, a propoxy group, a butoxy group, a pentyloxy group, a hexyloxy group, a heptoxy group, an octyloxy group, a dodecyloxy group, a 2-ethylhexyloxy group, an isopropoxy group, a sec-butoxy group, a t-butoxy group or an iso-amyloxy group, and represents a group in which the total number of carbon atoms including the substituent is 7 or more. For example, a cyclohexylmethoxy group, a cyclopentylethoxy group, a cyclohexylethoxy group or the like may be included, and a cyclohexylmethoxy group is preferable.

In addition, the alkoxy group having a polycyclic cycloalkyl group having a total of 7 or more carbon atoms may include a norbornylmethoxy group, a norbornylethoxy group, a tricyclodecanylmethoxy group, a tricyclodecanylethoxy group, a tetracyclodecanylmethoxy group, a tetracyclodecanylethoxy group, an adamantylmethoxy group, an adamantylethoxy group or the like, and is preferably a norbornylmethoxy group, a norbornylethoxy group or the like.

As the alkyl group of the alkylcarbonyl group of R₁₄, the same specific examples as R₁₃ to R₁₅ described above may be included.

The alkylsulfonyl group and the cycloalkylsulfonyl group of R₁₄ may be linear, branched or cyclic, and preferably have 1 to 10 carbon atoms, and include, for example, a methanesulfonyl group, an ethanesulfonyl group, an n-propanesulfonyl group, an n-butanesulfonyl group, a tert-butanesulfonyl group, an n-pentanesulfonyl group, a neopentanesulfonyl group, an n-hexanesulfonyl group, an n-heptanesulfonyl group, an n-octanesulfonyl group, a 2-ethylhexanesulfonyl group, an n-nonanesulfonyl group, an n-decanesulfonyl group, a cyclopentanesulfonyl group, a cyclohexanesulfonyl group, or the like. Among these alkylsulfonyl groups and the cycloalkylsulfonyl groups, a methanesulfonyl group, an ethanesulfonyl group, an n-propanesulfonyl group, an n-butanesulfonyl group, a cyclopentanesulfonyl group, a cyclohexanesulfonyl group or the like is preferable.

The substituent each of the above groups may have includes a halogen atom (for example, a fluorine atom), a hydroxyl group, a carboxyl group, a cyano group, a nitro group, an alkoxy group, an alkoxyalkyl group, an alkoxycarbonyl group, an alkoxycarbonyloxy group, or the like.

The alkoxy group includes a linear, branched or cyclic alkoxy group having 1 to 20 carbon atoms such as, for example, a methoxy group, an ethoxy group, an n-propoxy group, an i-propoxy group, an n-butoxy group, a 2-methylpropoxy group, a 1-methylpropoxy group, a t-butoxy group, a cyclopentyloxy group a cyclohexyloxy group, or the like.

The alkoxyalkyl group includes a linear, branched or cyclic alkoxyalkyl group having 2 to 21 carbon atoms such as, for example, a methoxymethyl group, an ethoxymethyl group, a 1-methoxyethyl group, a 2-methoxyethyl group, a 1-ethoxyethyl group or a 2-ethoxyethyl group, or the like.

The alkoxycarbonyl group includes a linear, branched or cyclic alkoxycarbonyl group having 2 to 21 carbon atoms such as, for example, a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, a cyclopentyloxycarbonyl group or a cyclohexyloxycarbonyl group, or the like.

The alkoxycarbonyloxy group includes a linear, branched or cyclic alkoxycarbonyloxy group having 2 to 21 carbon atoms such as, for example, a methoxycarbonyloxy group, an ethoxycarbonyloxy group, an n-propoxycarbonyloxy group, an i-propoxycarbonyloxy group, an n-butoxycarbonyloxy group, a t-butoxycarbonyloxy group, cyclopentyloxycarbonyloxy group or a cyclohexyloxycarbonyloxy group, or the like.

The ring structure which may be formed by two R₁₅s being bonded to each other may include a 5-membered or 6-membered ring, particularly preferably a 5-membered ring (that is, a tetrahydrothiophene ring) formed by two divalent R₁₅s together with a sulfur atom in General Formula (ZI-4), and may be ring condensed with an aryl group or cycloalkyl group. This divalent R₁₅ may have a substituent, and includes, for example, a hydroxyl group, a carboxyl group, a cyano group, a nitro group, an alkyl group, a cycloalkyl group, an alkoxy group, an alkoxyalkyl group, an alkoxycarbonyl group, an alkoxycarbonyloxy group, or the like. As for the substituent on the ring structure, a plurality or substituents may be present and these may be bonded to each other to form a ring (an aromatic or non-aromatic hydrocarbon ring, an aromatic or non-aromatic heterocyclic ring, a polycyclic condensed ring formed by combining two or more of these rings, or the like).

In General Formula (ZI-4), R₁₅ is preferably a methyl group, an ethyl group, a naphthyl group, a divalent group in which two R₁₅s are bonded to each other to form a tetrahydrothiophene ring structure together with a sulfur atom, or the like.

The substituent which R₁₃ and R₁₄ may have is preferably a hydroxyl group, an alkoxy group an alkoxycarbonyl group, or a halogen atom (particularly a fluorine atom).

l is preferably 0 or 1, and more preferably 1.

r is preferably 0 to 2.

As the cation represented by General Formula (ZI-4) of the present invention, specific examples below may be included.

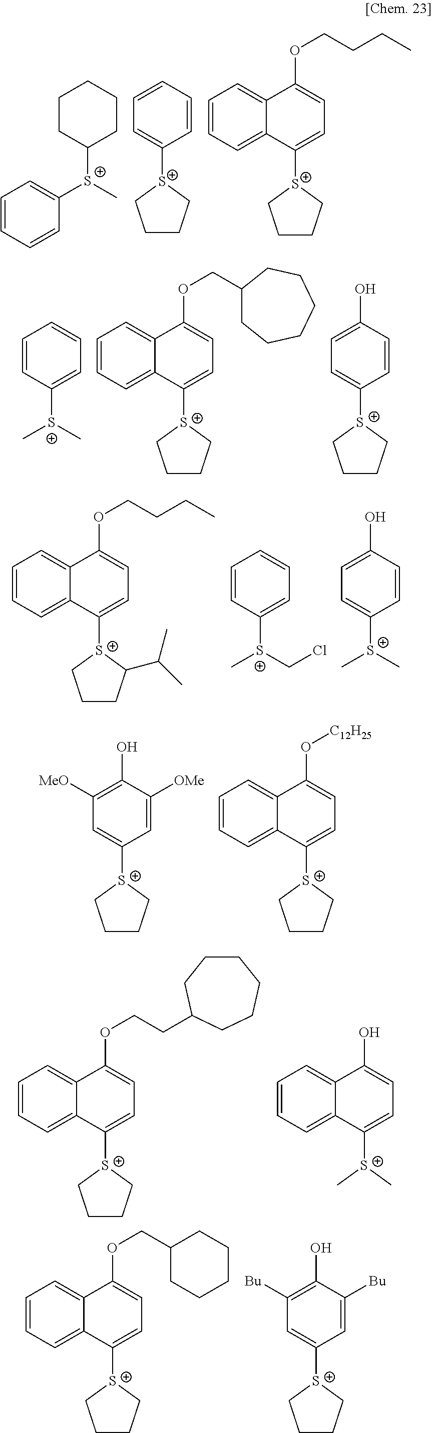

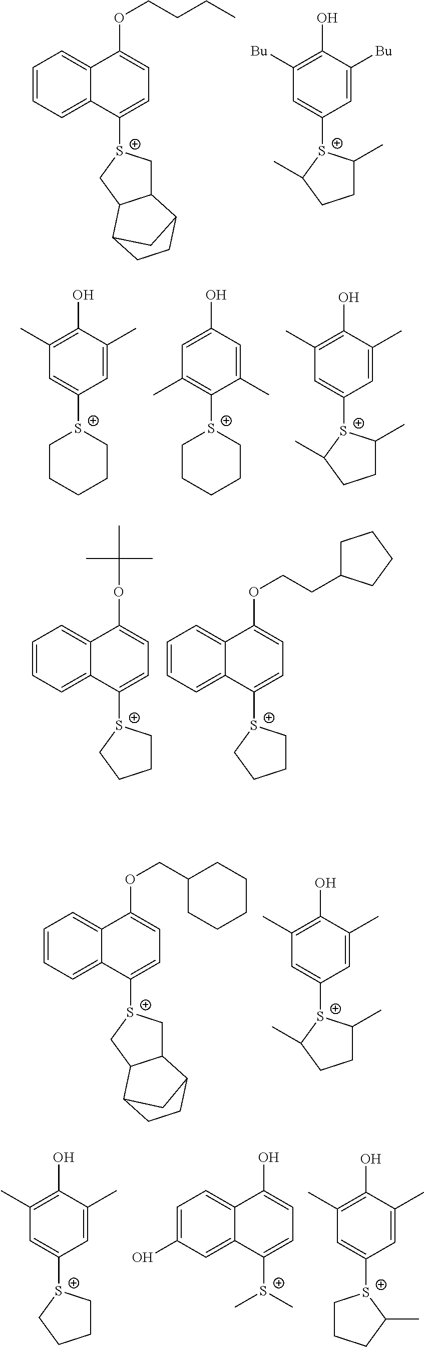

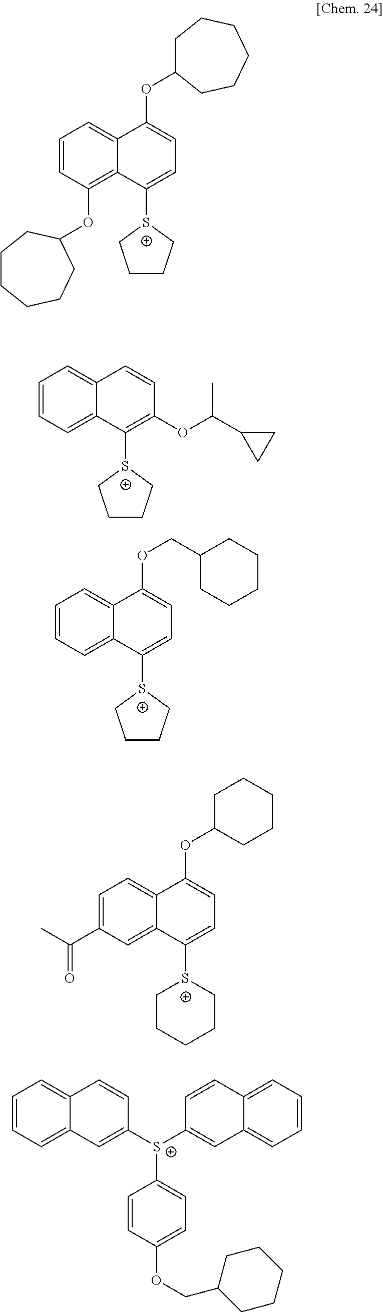

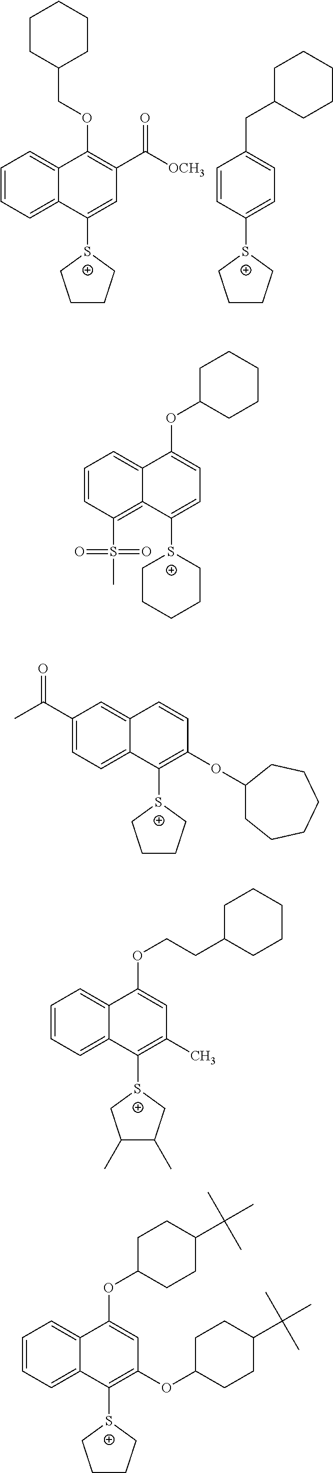

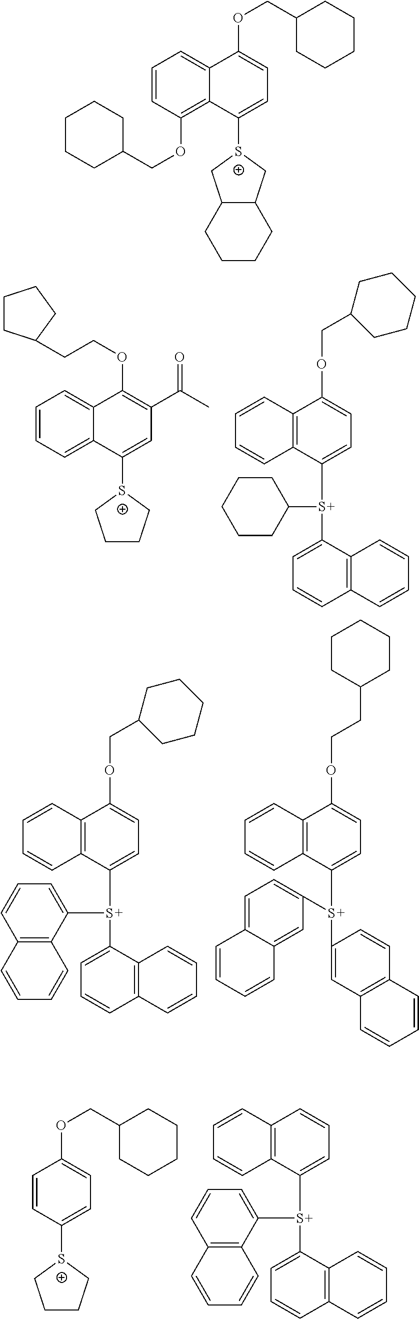

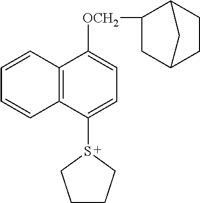

Next, General Formula (ZII) will be described.

In General Formula (ZII), R₂₀₄ and R₂₀₅ each independently represent an aryl group, an alkyl group, or a cycloalkyl group.

The aryl group of R₂₀₄ and R₂₀₅ is preferably a phenyl group or a naphthyl group, and more preferably a phenyl group. The aryl group of R₂₀₄ and R₂₀₅ may also be an aryl group having a heterocyclic structure containing an oxygen atom, a nitrogen atom, a sulfur atom or the like. The skeleton of the aryl group having a heterocyclic structure includes, for example, pyrrole, furan, thiophene, indole, benzofuran, benzothiophene, or the like.

The alkyl group and the cycloalkyl group of R₂₀₄ and R₂₀₅ may preferably include a linear or branched alkyl group having 1 to 10 carbon atoms (for example, a methyl group, an ethyl group, a propyl group, a butyl group or a pentyl group), and a cycloalkyl group having 3 to 10 carbon atoms (a cyclopentyl group, a cyclohexyl group or a norbornyl group).

The aryl group, the alkyl group, and the cycloalkyl group of R₂₀₄ and R₂₀₅ may have a substituent. The substituent the aryl group, the alkyl group, and the cycloalkyl group of R₂₀₄ and R₂₀₅ may have includes, for example, an alkyl group (for example, having 1 to 15 carbon atoms), a cycloalkyl group (for example, having 3 to 15 carbon atoms), an aryl group (for example, having 6 to 15 carbon atoms), an alkoxy group (for example, having 1 to 15 carbon atoms), a halogen atom, a hydroxyl group, a phenylthio group, or the like.

Specific examples of the cation represented by General Formula (ZII) are shown below.

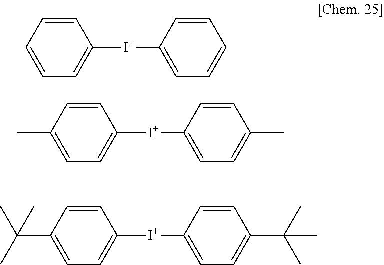

Next, a compound represented by General Formula (II) will be described.

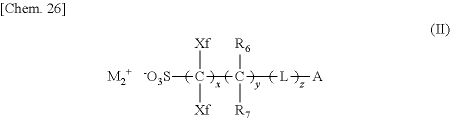

In General Formula (II), Xf and A each independently represent an alkyl group having 1 to 5 carbon atoms or a fluorine atom, and Xfs may be bonded to each other to form a ring. Xfs which are present in plural number may be the same as or different from each other.

R₆ and R₇ each independently represent a hydrogen atom, a fluorine atom or an alkyl group, and R₆ and R₇ may be the same as or different from each other when present in plural number.

L represents a divalent linking group and Ls may be the same as or different from each other when present in plural number.

x represents an integer of 1 to 20, y represents an integer of 0 to 10, and z represents an integer of 0 to 10.

M₂⁺ represents a monovalent cation.

The alkyl group having 1 to 5 carbon atoms as Xf and A is preferably an alkyl group having 1 to 4 carbon atom, and may include a methyl group, an ethyl group, an n-propyl group, an isopropyl group, or the like.

In addition, the alkyl group as Xf and A may have a substituent (preferably a fluorine atom), and the alkyl group having a substituent is preferably an alkyl group having 1 to 5 carbon atoms substituted with at least one fluorine atom, and more preferably a perfluoroalkyl group having 1 to 5 carbon atoms.

Specific examples of the alkyl group having 1 to 5 carbon atoms substituted with at least one fluorine atom as Xf and A include CF₃, C₂F₅, C₃F₇, C₄F₉, C₅F₁₁, CH₂CF₃, CH₂CH₂CF₃, CH₂C₂F₅, CH₂CH₂C₂F₅, CH₂C₃F₇, CH₂CH₂C₃F₇ or CH₂C₄F₉.

Xf and A are preferably a fluorine atom or an alkyl group having 1 to 5 carbon atoms substituted with at least one fluorine atom, more preferably a fluorine atom or a perfluoroalkyl group having 1 to 4 carbon atoms, and particularly preferably a fluorine atom or CF₃. It is particularly preferable that all Xfs be fluorine atoms.

R₆ and R₇ each dependently represent a hydrogen atom, a fluorine atom or an alkyl group, and the alkyl group may have a substituent (preferably a fluorine atom) and is preferably an alkyl group having 1 to 4 carbon atoms. More preferably, this alkyl group is a perfluoroalkyl group having 1 to 4 carbon atoms. Specific examples of the alkyl group having a substituent as R₆ and R₇ include CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, or CH₂CH₂C₄F₉, and among these, CF₃ is preferable.

L represents a divalent linking group, and may include —COO—, —OCO—, —CO—, —O—, —S—, —SO—, —SO₂—, —N(Ri)— (in the formula, Ri represents a hydrogen atom or an alkyl group), an alkylene group (preferably having 1 to 6 carbon atoms), a cycloalkylene group (preferably having 3 to 10 carbon atoms), an alkenylene group (preferably having 2 to 6 carbon atoms). -(L)_{z}- is preferably —COO—, —COO—, —CO—, —SO₂—, —CON(Ri)—, SO₂N(Ri)—, —CON(Ri)-alkylene group-, —N(Ri)CO-alkylene group-, —COO-alkylene group- or —OCO-alkylene group- is preferable, and —COO—, —COO—, —SO₂—, —CON(Ri)— or SO₂N(Ri)— is more preferable. Ls may be the same as or different from each other when present in plural number.

Specific examples and preferable examples of the alkyl group for Ri include the same specific examples and preferable examples of the alkyl group for A described above.

x is preferably 1 to 8, more preferably 1 to 4, and particularly preferably 1. y is preferably 0 to 4, more preferably 0 or 1, and even more preferably 0. z is preferably 0 to 8, more preferably 0 to 4, and even more preferably 1.

M₂⁺ represents a monovalent cation, and preferable ranges and specific examples thereof and the like are the same as those described for the monovalent cation of M₁⁺ in General Formula (I).

Next, a compound represented by General Formula (III) will be described.

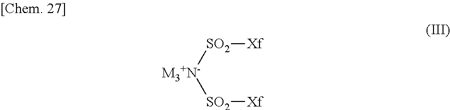

In General Formula (III), Xfs each independently are synonymous with Xfs in General Formula (II), Xfs may be the same as or different from each other, and may be bonded to each other to form a ring. M₃⁺ represents a monovalent cation.

Preferable ranges and specific examples of Xf in General Formula (III) are the same as those described for Xf in General Formula (II). In particular, Xf in General Formula (III) is preferably a trifluoromethyl group or a pentafluoroethyl group. In addition, it is also preferable that Xfs be bonded to each other and form a hexafluoropropylene group.

M₃⁺ represents a monovalent cation, and preferable ranges and specific examples thereof and the like are the same as those described for the monovalent cation M₁⁺ in General Formula (I).

Next, a compound represented by General Formula (IV) will be described.

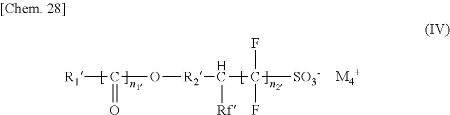

In General Formula (IV), R₁′ is an alkyl group having 1 to 5 carbon atoms. R₂′ is a divalent linking group. Rf′ is a fluorine atom, or an alkyl group substituted with at least one fluorine atom. M₄⁺ is a monovalent cation. n₁′ and n₂′ each independently are 0 or 1.

The alkyl group having 1 to 5 carbon atom as R₁′ is preferably an alkyl group having 1 to 4 carbon atom, and may include a methyl group, an ethyl group, an n-propyl group, an isopropyl group, or the like.

In addition, the alkyl group as R₁′ may have a substituent (preferably a fluorine atom), and the alkyl group having a substituent is preferably an alkyl group having 1 to 5 carbon atoms substituted with at least one fluorine atom, and more preferably a perfluoroalkyl group having 1 to 5 carbon atoms.

R₁′ is preferably a methyl group, an ethyl group or a trifluoromethyl group.

In General Formula (IV), preferable ranges, specific examples and the like of R₂′ and Rf′ are the same as those described for R₂ and Rf in General Formula (I).

M₄⁺ represents a monovalent cation, and preferable ranges and specific examples thereof and the like are the same as those described for the monovalent cation M₁⁺ in General Formula (I).

n₂ is preferably 1.

Next, a compound represented by General Formula (V) will be described.

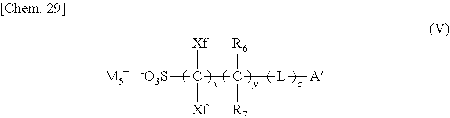

In General Formula (V), Xf, R₆, R₇, L, x, y, and z are synonymous with Xf, R₆, R₇, L, x, y, and z in General Formula (II).

A′ represents a monovalent alicyclic hydrocarbon group having 5 or more carbon atoms or an aryl group having 6 or more carbon atoms.

M₅⁺ represents a monovalent cation.

Preferable ranges, specific examples and the like of Xf, R₆, R₇, and L, and preferable ranges of x, y, and z are the same as those described for Xf, R₆, R₇, L, x, y, and z in General Formula (II).

Preferable ranges, specific examples and the like of the monovalent alicyclic hydrocarbon group having 5 or more carbon atoms of A′ are the same as those described for “the monovalent alicyclic hydrocarbon group having 5 or more carbon atoms” in the group having “a monovalent alicyclic hydrocarbon group having 5 or more carbon atoms” as R₁ in General Formula (I).

Preferable ranges, specific examples and the like of the aryl group having 6 or more carbon atoms of A′ are the same as those described for “the aryl group having 6 or more carbon atoms” in the group having “an aryl group having 6 or more carbon atoms” as R₁ in General Formula (I).

A′ may include a monocyclic cycloalkyl group such as a cyclopentyl group, a cyclohexyl group or a cyclooctyl group, a polycyclic cycloalkyl group such as a norbornyl group, a tricyclodecanyl group, a tetracyclodecanyl group, a tetracyclododecanyl group or an adamantyl group, or an alicyclic hydrocarbon group having a heteroatom as a ring member such as a piperidine ring group or a decahydro isoquinoline ring group, and is preferably a polycyclic cycloalkyl group or an alicyclic hydrocarbon group having a nitrogen atom.

M₅⁺ represents a monovalent cation, and preferable ranges and specific examples thereof and the like are the same as those described for the monovalent cation M₁⁺ in General Formula (I).

Preferable specific examples of the anion structure in the compounds represented by General Formulae (I) to (V) are shown below, however, the present invention is not limited to these. In addition, the following specific examples of the anion structure in the compounds represented by General Formula (I) also correspond to General Formula (V), and the following specific examples of the anion structure in the compounds represented by General Formula (IV) also correspond to General Formula (II).

### [Anion Structure in Compounds Represented by General Formula (I)]

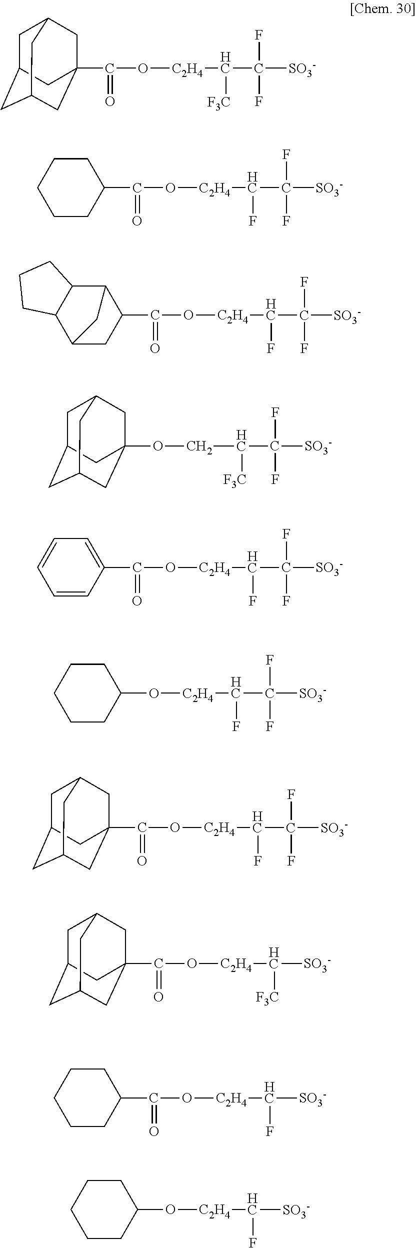

[Anion Structure in Compounds Represented by General Formula (II)]

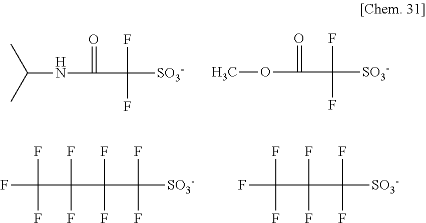

[Anion Structure in Compounds Represented by General Formula (III)]

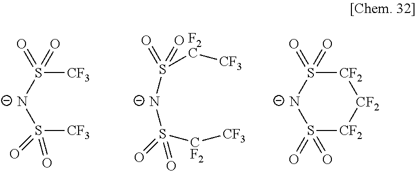

[Anion Structure in Compounds Represented by General Formula (IV)]

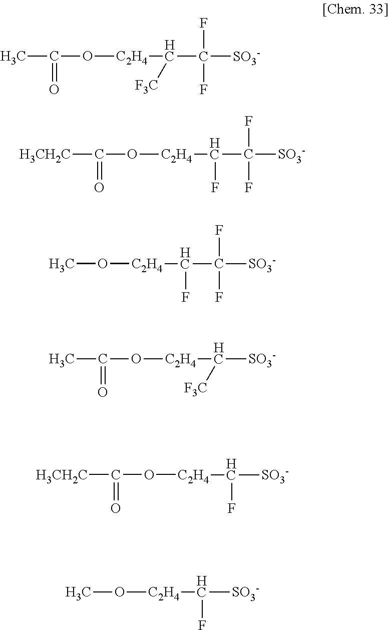

[Anion Structure in Compounds Represented by General Formula (V)]

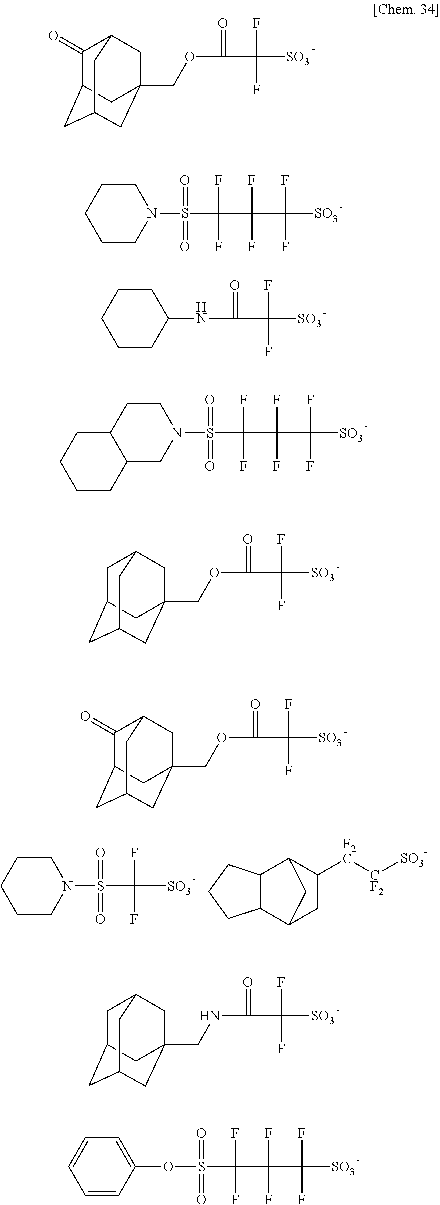

In addition, preferable specific examples of the anion structure in the compounds represented by General Formulae (I) to (V) are shown below, however, the present invention is not limited to these.

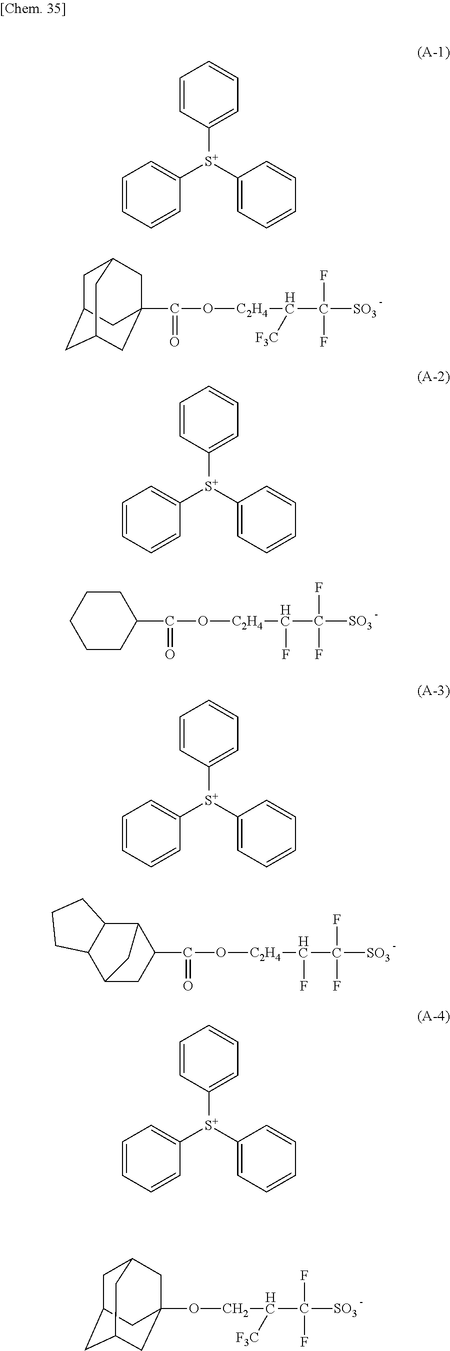

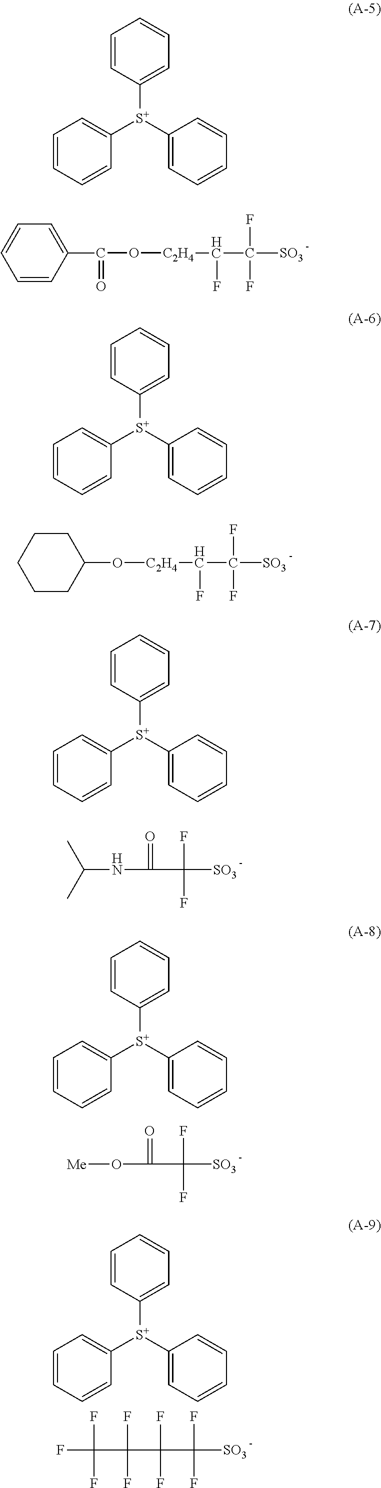

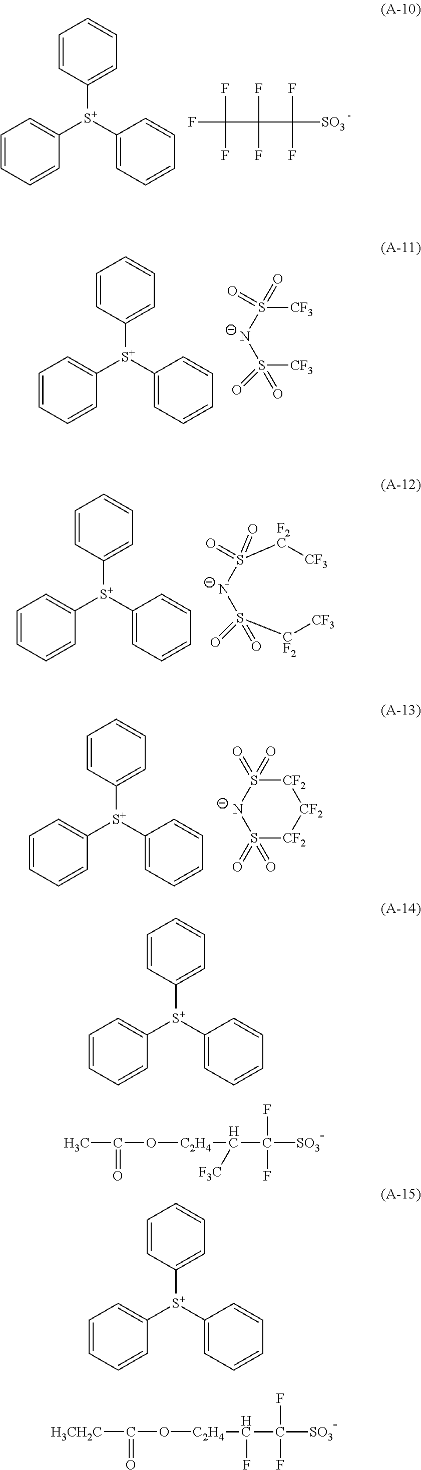

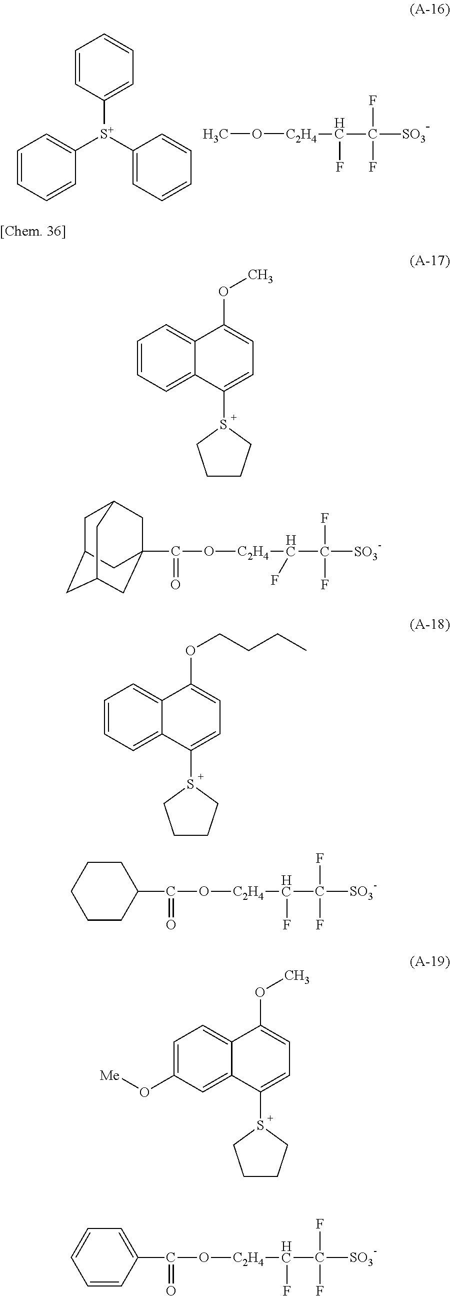

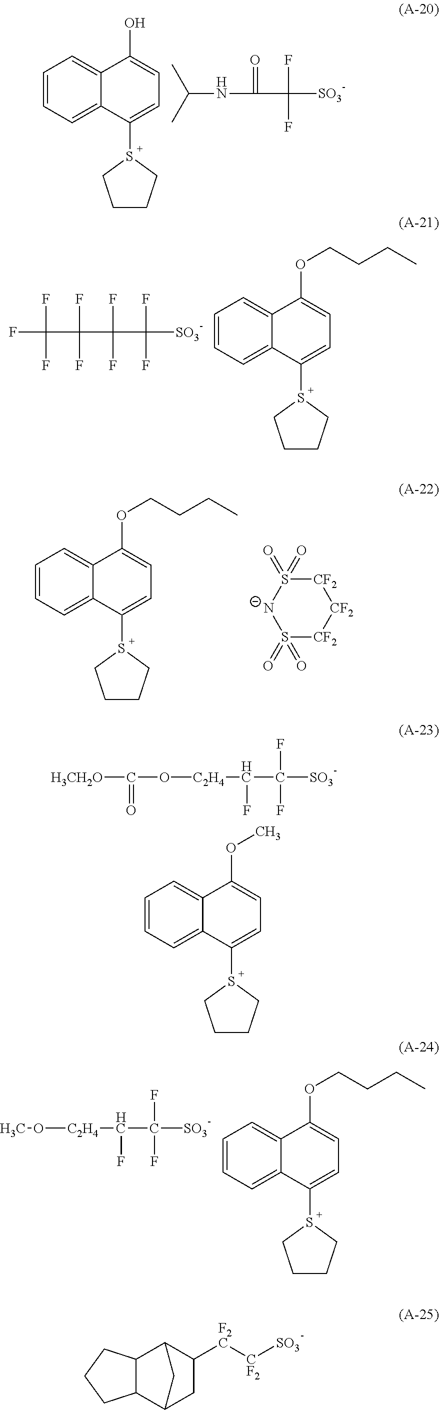

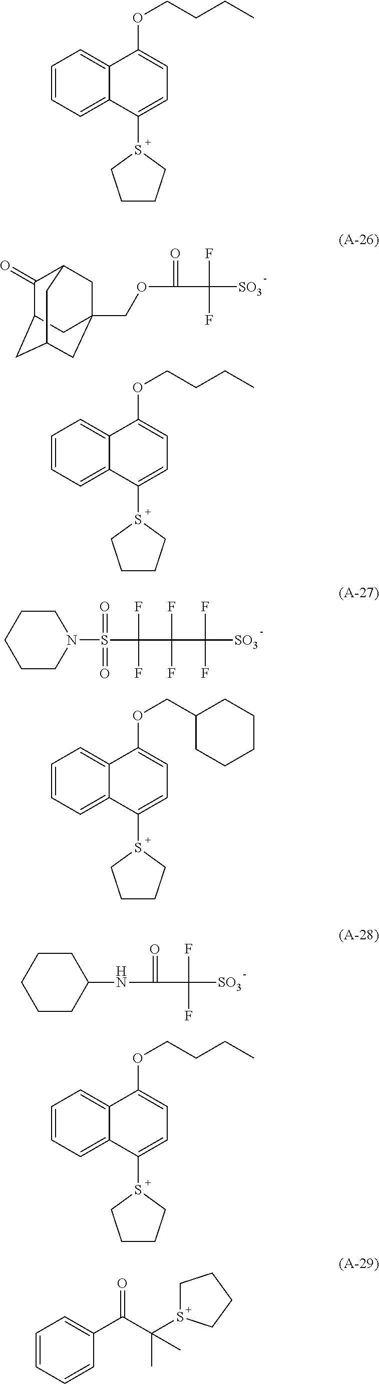

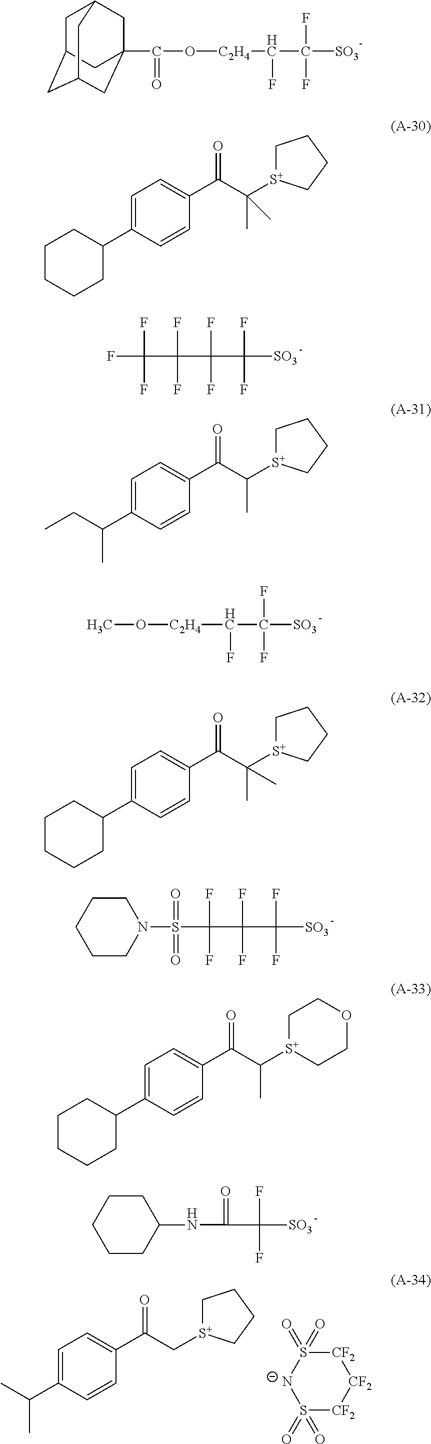

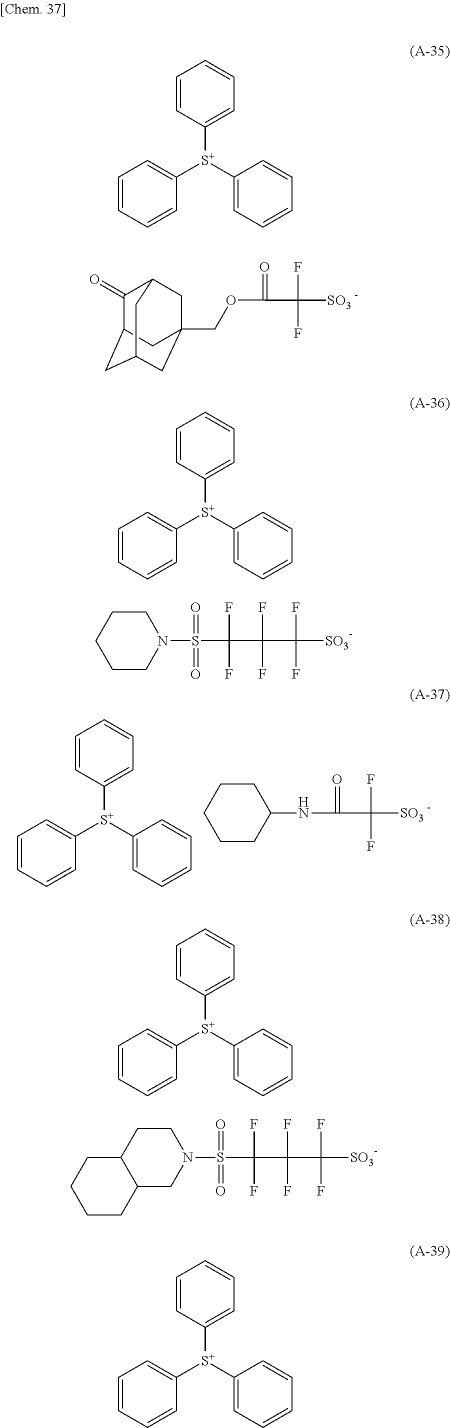

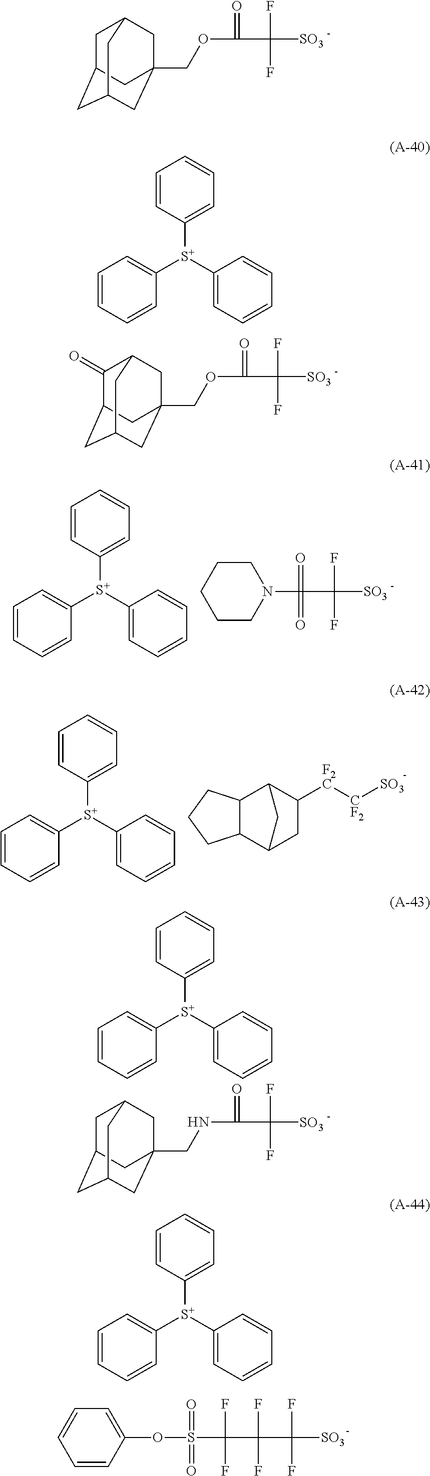

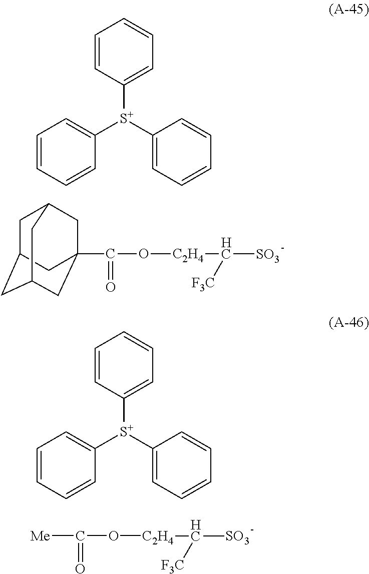

The salt of sulfonic acid or disulfonyl imidic acid represented by General Formulae (I) to (V) (for example, an onium salt or a metal salt) can be synthesized using a general sulfonic acid esterification reaction or sulfonamide reaction. For example, a method in which a sulfonamide bond, a sulfonate bond or a sulfonamide bond is formed by selectively reacting one of the sulfonyl halide portion of a bissulfonyl halide compound with an amine, an alcohol, an amide compound or the like, and then the other sulfonyl halide portion is hydrolyzed, or a method in which a cyclic sulfonic acid anhydride is ring-opened by an amine, an alcohol or an amide compound, may be used.

The salt of sulfonic acid or disulfonyl imidic acid represented by General Formulae (I) to (V) may include a metal salt of sulfonic acid or disulfonyl imidic acid, an onium salt of sulfonic acid or disulfonyl imidic acid, or the like. The metal in the metal salt of sulfonic acid or disulfonyl imidic acid may include Na⁺, Li⁺, K⁺, or the like. The onium cation in the onium salt of sulfonic acid or disulfonyl imidic acid may include an ammonium cation, a sulfonium cation, an iodonium cation, a phosphonium cation, a diazonium cation, or the like.

The salt of sulfonic acid or disulfonyl imidic acid represented by General Formulae (I) to (V) may be used as an acid generator itself, but may be a precursor of a target acid generator.

That is, the acid generator used in the present invention may also be synthesized by a salt exchange between the salt of sulfonic acid or disulfonyl imidic acid represented by General Formulae (I) to (V) and a photoactive onium salt having a desired cation structure.

The actinic ray-sensitive or radiation-sensitive resin composition of the present invention may contain other photoacid generators in addition to the combination of the above compound of (A-1). Similarly, the actinic ray-sensitive or radiation-sensitive resin composition of the present invention may contain other photoacid generators in addition to the combination of the above compound of (A-2). As the other photoacid generators, the compounds represented by any of General Formulae (I) to (V), or photoacid generators in the related art other than the compounds represented by any of General Formulae (I) to (V) may be used.

The content of the composition of the present invention of the compound (A) is preferably 0.1 to 30% by mass, more preferably 0.5 to 25% by mass, and even more preferably 5 to 20% by mass with regard to total solid contents of the composition.

In the combination of the compound of (A-1), the mass ratio of the compound represented by General Formula (I) and the compound represented by General Formula (II) or (III) is preferably 99/1 to 20/80, more preferably 99/1 to 40/60, and even more preferably 99/1 to 50/50.

In the combination of the compound of (A-2), the mass ratio of the compound represented by General Formula (IV) and the compound represented by General Formula (V) is preferably 99/1 to 20/80, more preferably 99/1 to 40/60, and even more preferably 99/1 to 50/50.

[2] (B) Resin of which Solubility in Alkali Developer is Increased by being Decomposed by Action of Acid

The actinic ray-sensitive or radiation-sensitive resin composition of the present invention may contain (B) a resin of which solubility in an alkali developer is increased by being decomposed by the action of an acid (hereinafter, referred to as “an acid decomposable resin”, sometimes referred to as “a resin (B)”).

The acid decomposable resin has a group generating an alkali-soluble group by being decomposed by the action of an acid in the main chain or the side chain, or, both the main chain and the side chain of the resin (hereinafter, also referred to as an “acid decomposable group”).

The resin (B) is preferably insoluble or sparingly soluble in an alkali developer.

The acid decomposable group preferably has a structure protected by a group which is detached by decomposing the alkali-soluble group by the action of an acid.

The alkali-soluble group may include a phenolic hydroxyl group, a carboxyl group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, a tris(alkylsulfonyl)methylene group, or the like.

The preferable alkali-soluble group may include a carboxyl group, a fluorinated alcohol group (preferably a hexafluoroisopropanol group) or a sulfonic acid group.

The preferable acid decomposable group is a group in which a hydrogen atom of such an alkali-soluble group is substituted with a group capable of being detached by the action of an acid.

Examples of the group capable of being detached by the action of an acid include —C(R₃₆)(R₃₇)(R₃₈), —C(R₃₆)(R₃₇)(OR₃₉), —C(R₀₁)(R₀₂)(OR₃₉), or the like.

In the formula, R₃₆ to R₃₉ each independently represent an alkyl group, a cycloalkyl group, an aryl group, an aralkyl group or an alkenyl group. R₃₆ and R₃₇ may be bonded to each other to form a ring.

R₀₁ and R₀₂ each independently represent a hydrogen atom, an alkyl group, a cycloalkyl group, an aryl group, an aralkyl group or an alkenyl group.

The preferable acid decomposable group is a cumyl ester group, an enol ester group, an acetal ester group, a tertiary alkyl ester group, or the like. A tertiary alkyl ester group is more preferable.

As the repeating unit having an acid decomposable group which may be included in the resin (B), the following repeating unit represented by the following General Formula (AI) is preferable.

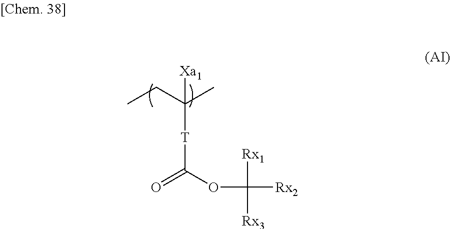

In General Formula (AI), Xa₁ represents a hydrogen atom, a methyl group which may have a substituent, or a group represented by —CH₂—R₁₁. R₁₁ represents a hydroxyl group or a monovalent organic group, and is, for example, an alkyl group having 5 or less carbon atoms, an acyl group having 5 or less carbon atoms, preferably an alkyl group having 3 or less carbon atoms, and is more preferably a methyl group. Xa₁ preferably represents a hydrogen atom, a methyl group, a trifluoromethyl group or a hydroxymethyl group.

T represents a single bond or a divalent linking group.

Rx₁ to Rx₃ each independently represent an alkyl group (linear or branched) or a cycloalkyl group (monocyclic or polycyclic).

Two of Rx₁ to Rx₃ may be bonded to each other to form a cycloalkyl group (monocyclic or polycyclic).

The divalent linking group of T may include an alkylene group, a —COO-Rt— group, a —O-Rt— group, or the like. In the formula, Rt represents an alkylene group or a cycloalkylene group.

T is preferably a single bond or a —COO-Rt— group. Rt is preferably an alkylene group having 1 to 5 carbon atoms and more preferably a —CH₂— group, a —(CH₂)₂— group, a —(CH₂)₃— group.

The alkyl group of Rx₁ to Rx₃ is preferably an alkyl group having 1 to 4 carbon atoms such as a methyl group, an ethyl group, an n-propyl group, an isopropyl group, an n-butyl group, an isobutyl group or a t-butyl group.

The cycloalkyl group of Rx₁ to Rx₃ is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group or an adamantyl group.

As the cycloalkyl group formed by two of Rx₁ to Rx₃ being bonded, a monocyclic cycloalkyl group such as a cyclopentyl group or a cyclohexyl group, or a polycyclic cycloalkyl group such as a norbornyl group, a tetracyclodecanyl group, a tetracyclododecanyl group or an adamantyl group is preferable. A monocylic cycloalkyl group having 5 to 6 carbon atoms is particularly preferable.

One of the methylene groups constituting the ring of the above cycloalkyl group formed by two of Rx₁ to Rx₃ being bonded to each other may be substituted by an oxygen atom.

An embodiment in which Rx₁ is a methyl group or an ethyl group, and Rx₂ and Rx₃ are bonded to each other to form cycloalkyl group described above is preferable.

Each of the above groups may have a substituent, and as the substituent, for example, an alkyl group (having 1 to 4 carbon atoms), a halogen atom, a hydroxyl group, an alkoxy group (having 1 to 4 carbon atoms), a carboxyl group, an alkoxycarbonyl group (having 2 to 6 carbon atoms) or the like may be included, and having 8 or less carbon atoms is preferable.

The content as the sum of the repeating units having an acid decomposable group is preferably 20 to 70 mol %, and more preferably 30 to 60 mol % with regard to all repeating units in the resin (B).

Preferable specific examples of the repeating unit having an acid decomposable are shown below, however, the present invention is not limited to these.

In the specific examples, Rx and Xa₁ represent a hydrogen atom, CH₃, CF₃ or CH₂OH. Each of Rxa and Rxb represents an alkyl group having 1 to 4 carbon atoms. Z represents a substituent including a polar group, and when present in plural number, each of them is independent. p represents 0 or a positive integer. Specific examples and preferable examples of Z are the same specific examples and preferable examples of R₁₀ in General Formula (II-1) described later.

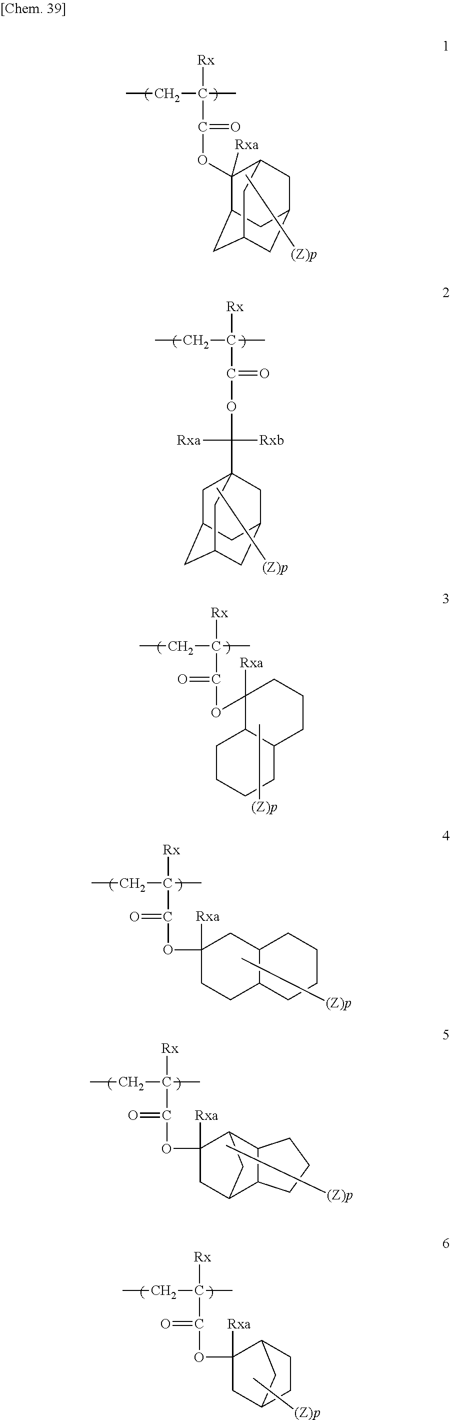

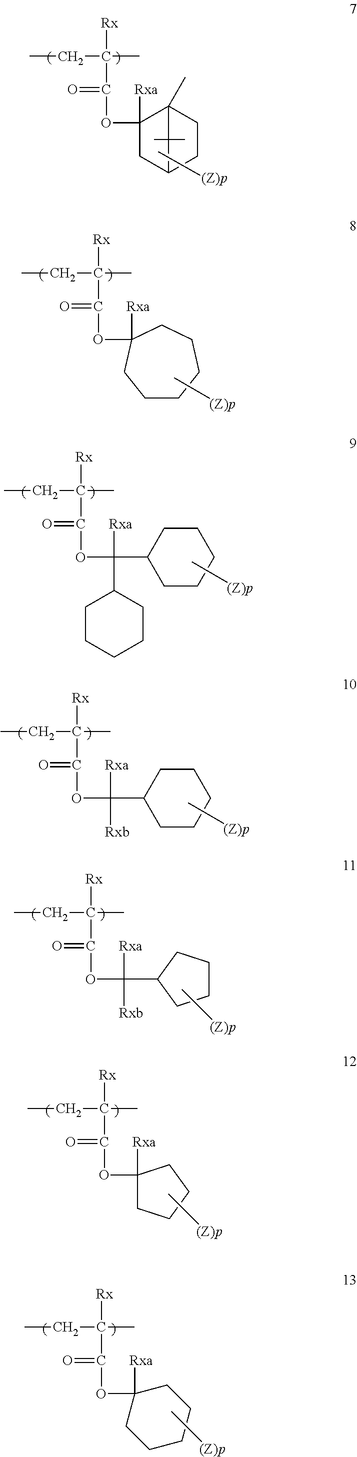

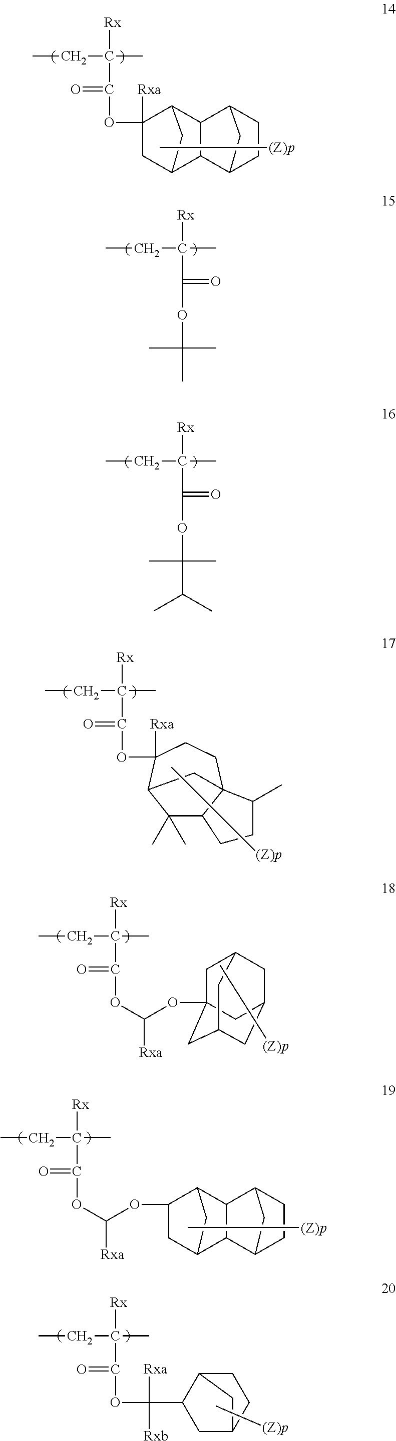

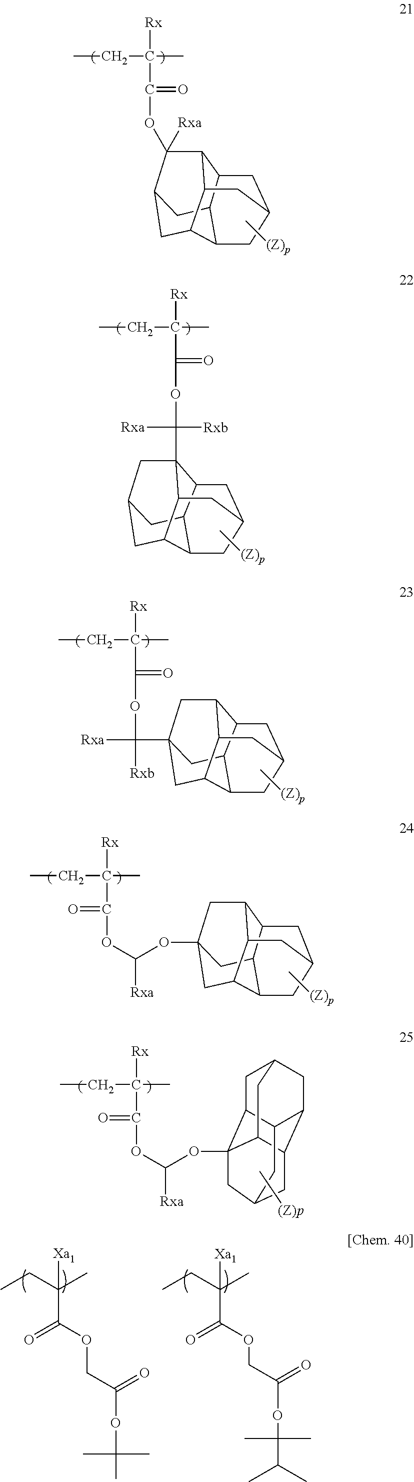

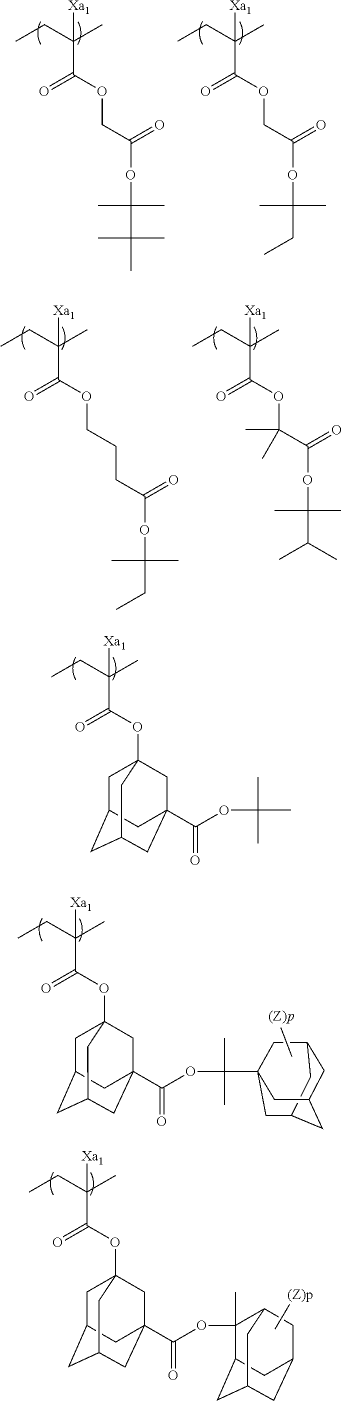

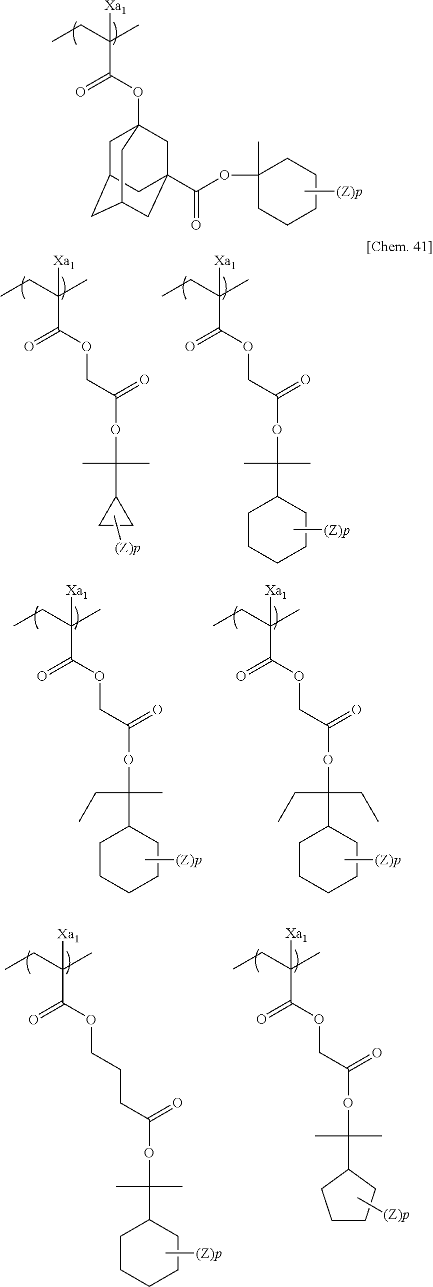

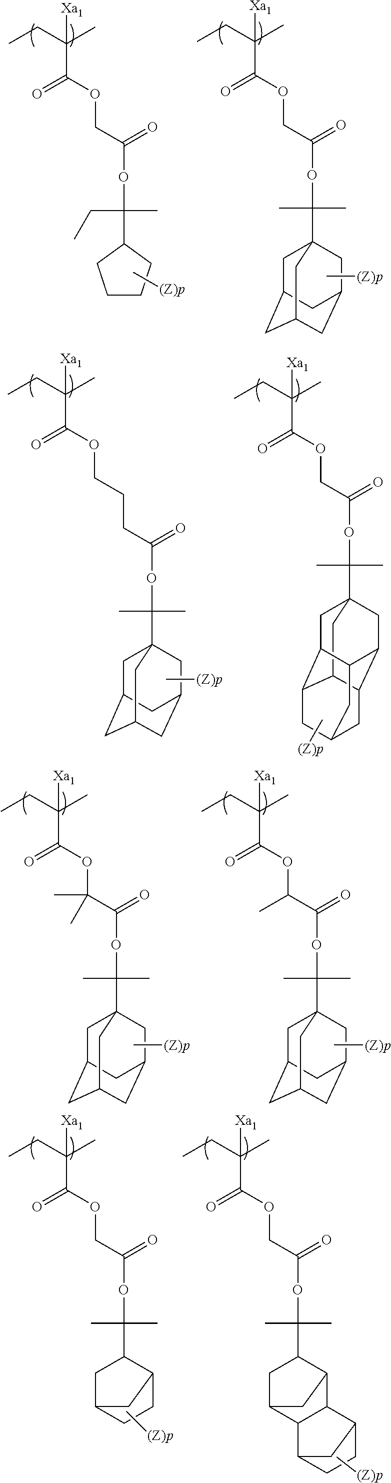

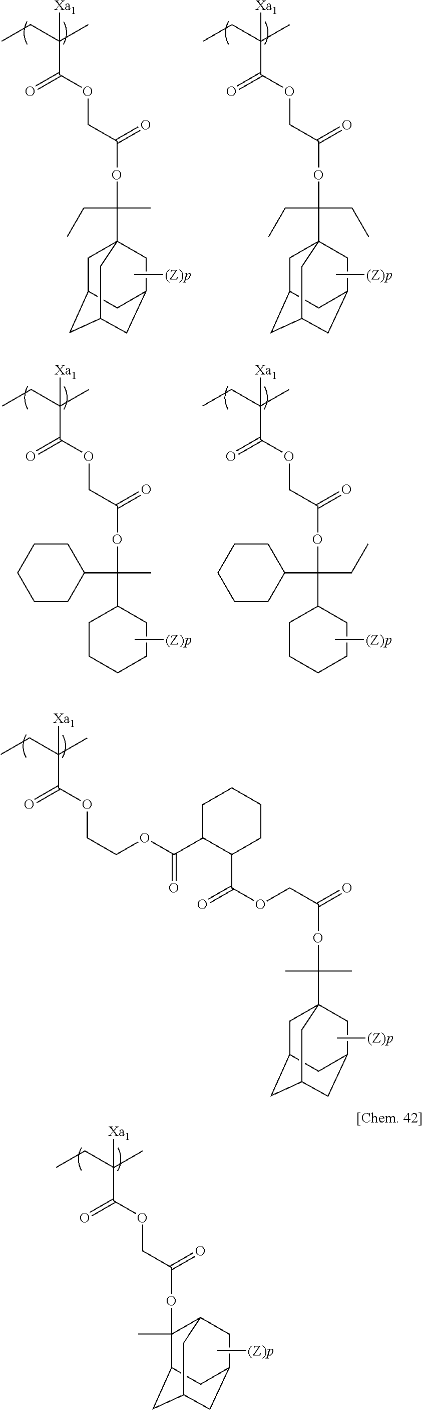

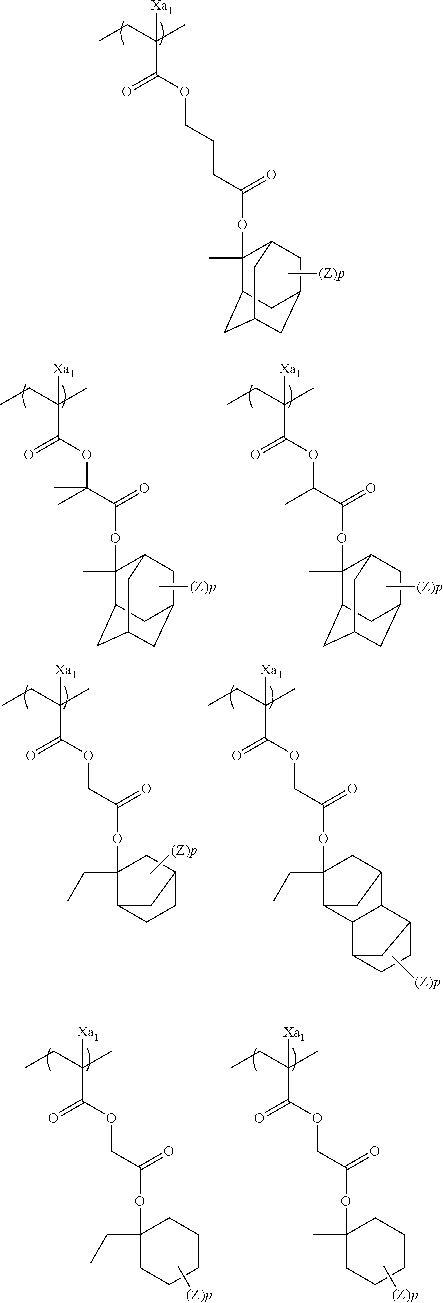

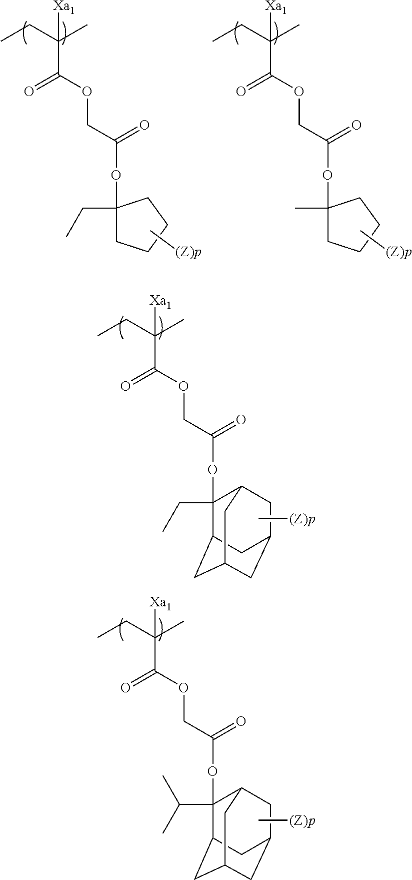

The resin (B), as the repeating unit represented by General Formula (AI), is preferably a resin having at least any of the repeating units represented by General Formula (I) or the repeating units represented by General Formula (II), and is more preferably a resin having the repeating units represented by General Formula (I).

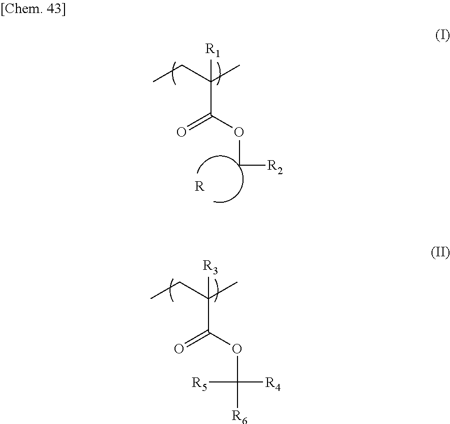

In General Formulae (I) and (II), R₁ and R₃ each independently represent a hydrogen atom, a methyl group which may have a substituent, or a group represented by —CH₂—R₁₁. R₁₁ represents a hydroxyl group or a monovalent organic group.

R₂, R₄, R₅, and R₆ each independently represent an alkyl group or a cycloalkyl group.

R represents an atomic group necessary for forming an alicyclic structure with carbon atoms, and the ring members of the alicyclic structure may include an oxygen atom.

R₁ and R₃ preferably represent a hydrogen atom, a methyl group, a trifluoromethyl group or a hydroxymethyl group. Specific examples and preferable examples of the monovalent organic group in R₁₁ are the same as those described for R₁₁ in General Formula (AI).

The alkyl group in R₂ may be linear or branched, and may have a substituent.

The cycloalkyl group in R₂ may be monocyclic or polycyclic, and may have a substituent.

R₂ is preferably an alkyl group, more preferably an alkyl group having 1 to 10 carbon atoms, even more preferably an alkyl group having 1 to 5 carbon atoms, and includes, for example, a methyl group or an ethyl group.

R represents an atomic group necessary for forming an alicyclic structure with carbon atoms. The alicyclic structure formed by R with the carbon atoms is preferably a monocyclic alicyclic structure, and the number of carbon atoms is preferably 3 to 7 and more preferably 5 or 6.

R₃ is preferably a hydrogen atom or a methyl group, and more preferably a methyl group.

The alkyl group in R₄, R₅, and R₆ may be linear or branched, and may have a substituent. The alkyl group is preferably an alkyl group having 1 to 4 carbon atoms such as a methyl group, an ethyl group, an n-propyl group, an isopropyl group, an n-butyl group, an isobutyl, group or a t-butyl group.

The cycloalkyl group in R₄, R₅, and R₆ may be monocyclic or polycyclic, and may have a substituent. The cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group or an adamantyl group.

The repeating unit represented by General Formula (I) is preferably a repeating unit represented by the following General Formula (AIII).

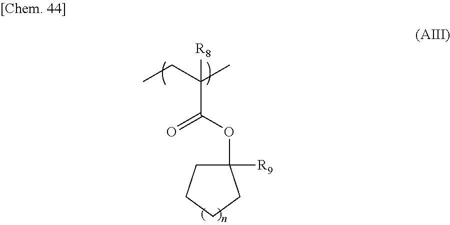

In the above general formula, R₈ represents a hydrogen atom or an alkyl group. R₉ represents an alkyl group. n represents an integer of 1 to 6.

The alkyl group of R₈ is preferably an alkyl group having 1 to 10 carbon atoms, and may have a substituent.

n is preferably an integer of 1 to 3, and more preferably 1 or 2.

The substituent each of the above groups may have includes the same groups described above as the substituents each of the groups in General Formula (AI) may have.

The repeating unit represented by General Formula (II) is preferably a repeating unit represented by the following General Formula (II-1).

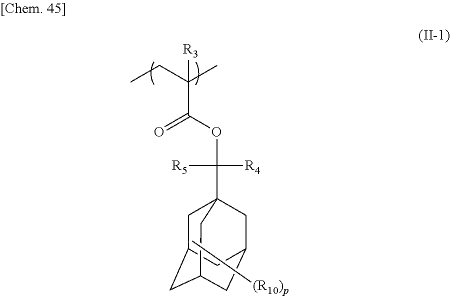

In General Formula (II-1), R₃ to R₅ each independently are synonymous with those in General Formula (II).

R₁₀ represents a substituent including a polar group. R₁₀s may be the same as or different from each other when present in plural number. Examples of the substituent including a polar group include a hydroxyl group, a cyano group, an amino group, an alkylamide group or a sulfonamide group itself, or a linear or branched alkyl group or a cycloalkyl group having at least one of these, and an alkyl group having a hydroxyl group is preferable. A branched alkyl group having a hydroxyl group is more preferable. As the branched alkyl group, an isopropyl group is particularly preferable.

p represents an integer of 0 to 15. p is preferably 0 to 2, and more preferably 0 or 1.

The resin (B) may include one type of the repeating unit having an acid decomposable group or may include two or more types, however, it is more preferable the resin (B) be a resin including at least two types of the repeating units represented by General Formula (I) as the repeating unit represented by General Formula (AI), or a resin including the repeating unit represented by General Formula (I) and the repeating unit represented by General Formula (II) as the repeating unit represented by General Formula (AI).

As the preferable combination when the resin (B) is a combination of two or more types of the repeating units having an acid decomposable group, those included below are preferable. In the following formula, Rs each independently represent a hydrogen atom or a methyl group.

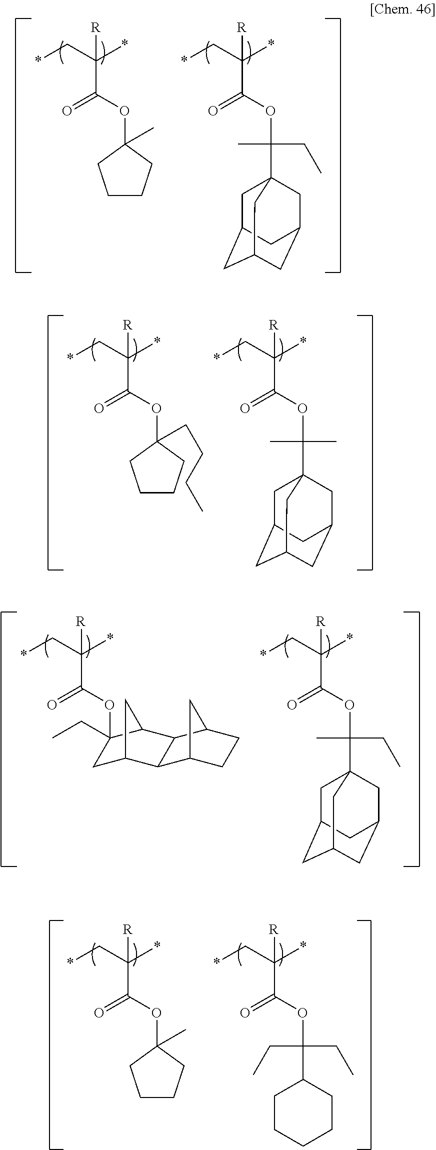

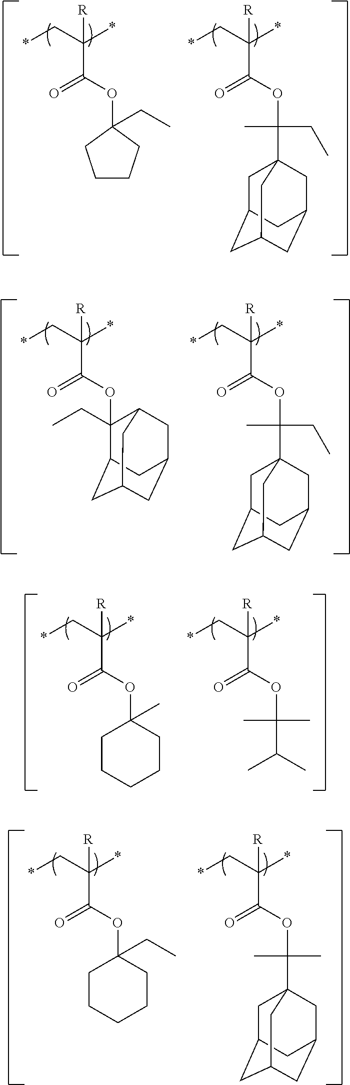

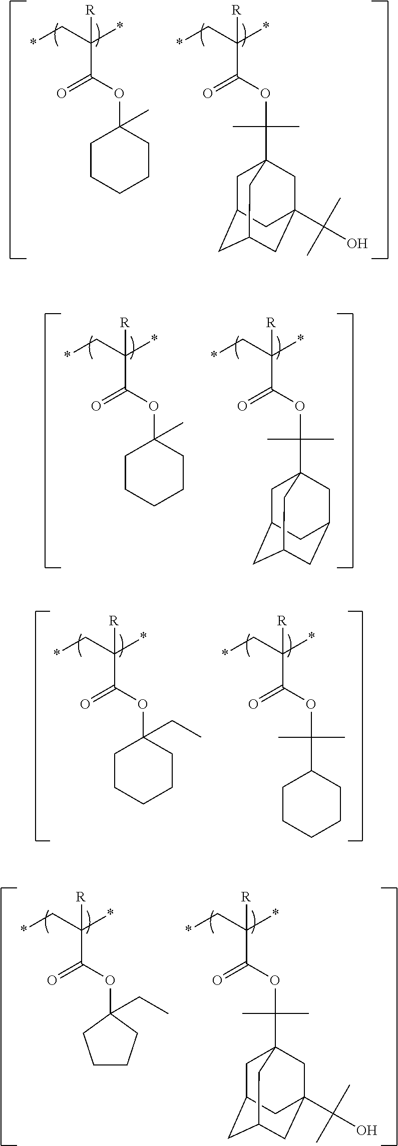

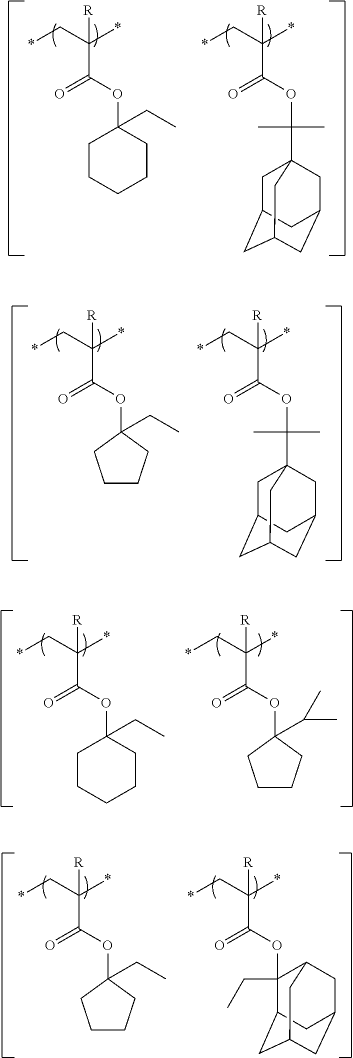

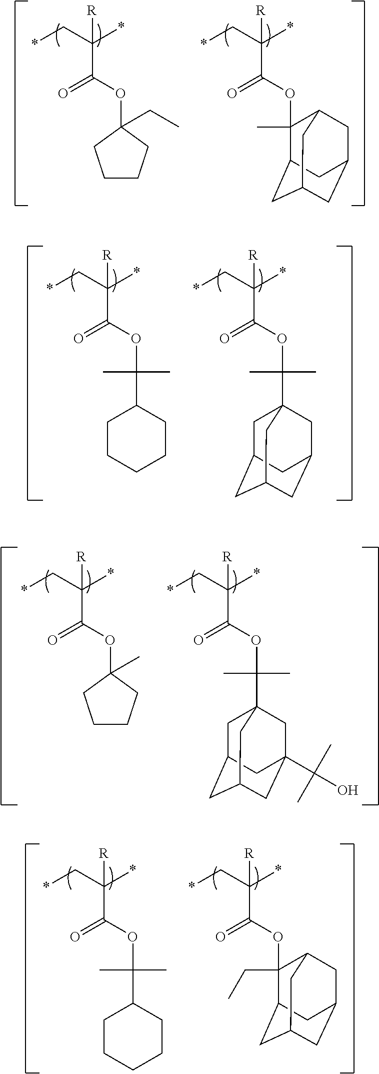

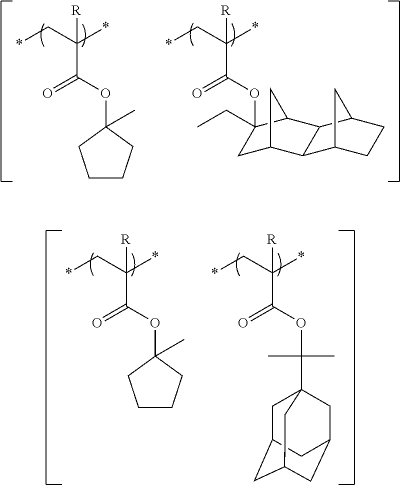

The resin (B) preferably contains a repeating unit having a lactone structure or a sultone (a cyclic sulfonate) structure.

As the lactone group or a sultone group, any group may be used as long as the group has a lactone structure or a sultone structure, however, a lactone structure or a sultone structure having a 5- to 7-membered ring is preferable, and a structure in which another ring structure is condensed to a lactone structure or a sultone structure having a 5- to 7-membered ring to form a bicyclo structure or a spiro structure is preferable. Containing a repeating unit having a lactone structure represented by any of the following General Formulae (LC1-1) to (LC1-17) or a sultone structure represented by any of the following General Formulae (SL1-1) to (SL1-3) is more preferable. In addition, the lactone structure or the sultone structure may be bonded directly to a main chain. The preferable lactone structures are (LC1-1), (LC1-4), (LC1-5) and (LC1-8), and (LC1-4) is more preferable. By using specific lactone structures or sultone structures, LWR and development defects are improved.

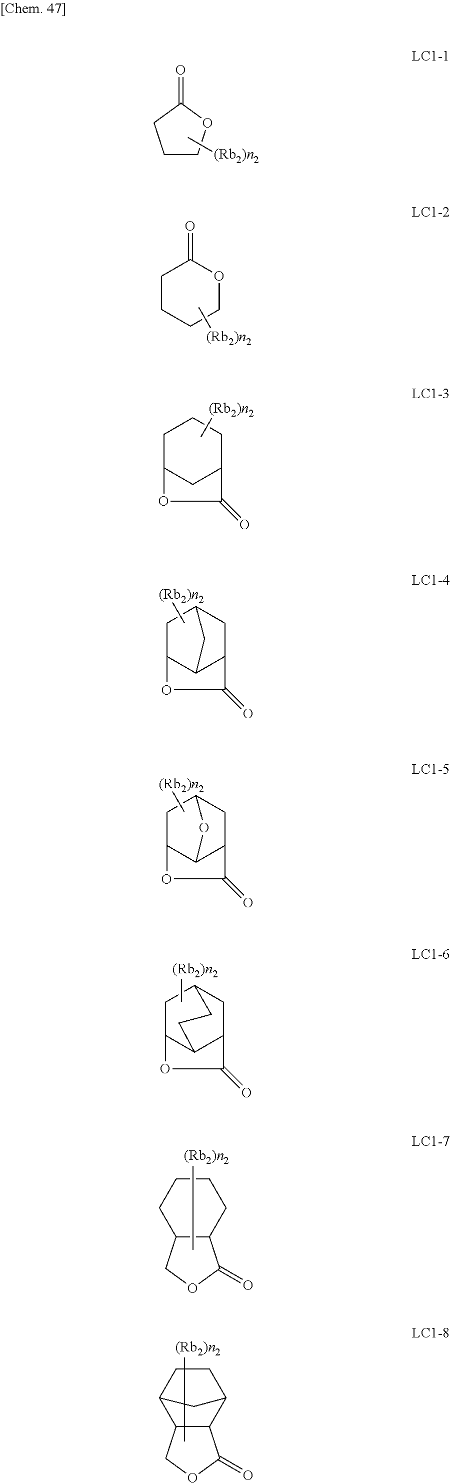

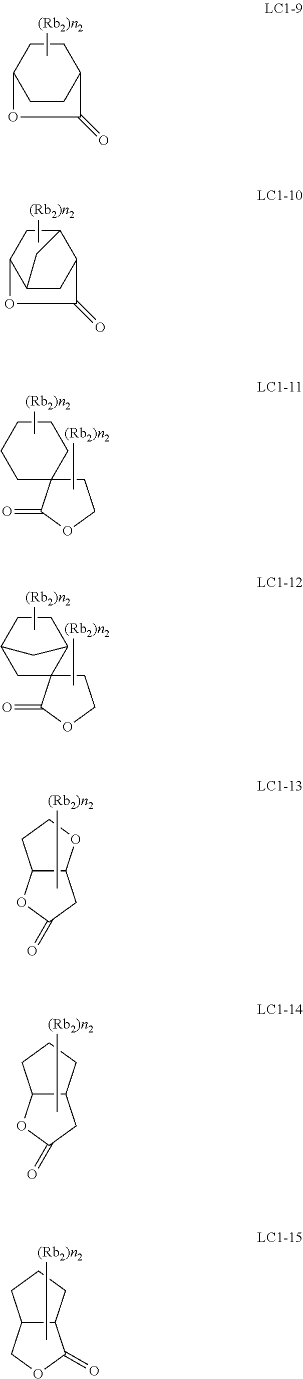

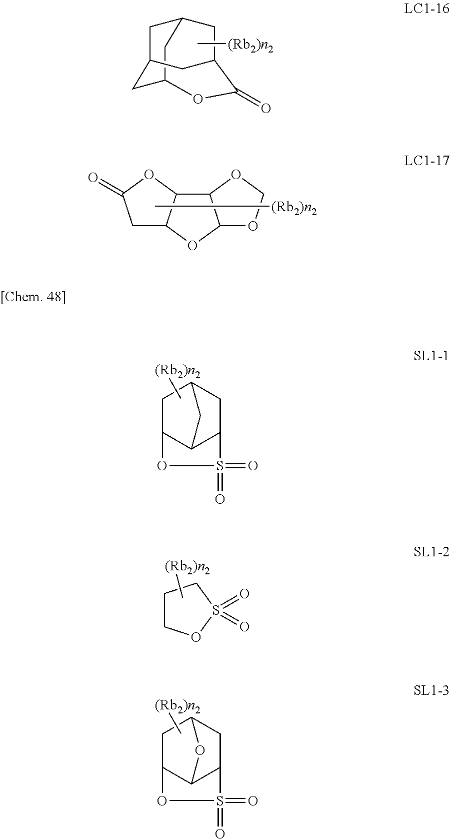

The lactone structure portion or the sultone structure portion may or may not have a substituent (Rb₂). As the preferable substituent (Rb₂), an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, an acid decomposable group, or the like, may be included. An alkyl group having 1 to 4 carbon atoms, a cyano group or an acid decomposable group is more preferable. n₂ represents an integer of 0 to 4. If n₂ is 2 or more, the substituents (Rb₂)s which are present in plural number may be the same as or different from each other, and the substituents (Rb₂)s which are present in plural number may be bonded to each other to form a ring.

The resin (B) preferably contains a repeating unit having a lactone structure or a sultone structure represented by the following General Formula (VI).

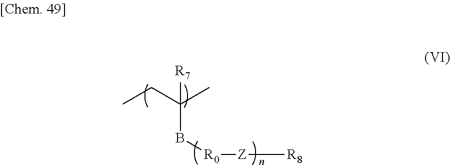

In General Formula (VI), B represents an ester bond (a group represented by —COO—) or an amide bond (a group represented by —CONH—).

R₀s, when present in plural number, each independently represents an alkylene group, a cycloalkylene group or a combination thereof.

Zs, when present in plural number, each independently represents a single bond, an ether bond, an ester bond, an amide bond, a urethane bond,

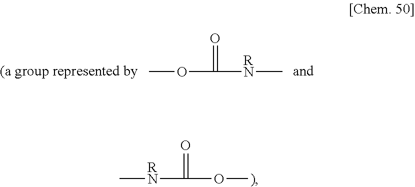

or a urea bond

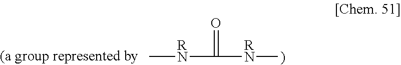

Here, Rs each independently represent a hydrogen atom, an alkyl group, a cycloalkyl group or an aryl group.

R₈ represents a monovalent organic group having a lactone structure or a sultone structure.

n is the number of repetitions of the structure represented by —R₀—Z—, and represents an integer of 0 to 2. When n is 1 or 2, 1 is a preferable embodiment and as a result, focus of depth latitude can be further improved.

R₇ represents a hydrogen atom, a halogen atom or an alkyl group.

The alkylene group or a cycloalkylene group of R₀ may have a substituent.

Z is preferably an ether bond or an ester bond, and particularly preferably an ester bond.

The alkyl group of R₇ is preferably an alkyl group having 1 to 4 carbon atoms, more preferably a methyl group or an ethyl group, and particularly preferably a methyl group. The alkylene group and the cycloalkylene group of R₀, and the alkyl group of R₇ may be substituted, respectively, and examples of the substituent include a halogen atom such as a fluorine atom, a chlorine atom or a bromine atom, a mercapto group, a hydroxy group, an alkoxy group such as a methoxy group, an ethoxy group, an isopropoxy group, a t-butoxy group or a benzyloxy group, an acetoxy group such as an acetyloxy group or a propionyloxy group. R₇ is preferably a hydrogen atom, a methyl group, a trifluoromethyl group or a hydroxymethyl group.

The chain alkylene group of R₀ is preferably a chain alkylene group having 1 to 10 carbon atoms, more preferably having 1 to 5 carbon atoms, and includes, for example, a methylene group, an ethylene group, a propylene group or the like. The cycloalkylene group is preferably a cycloalkylene group having 3 to 20 carbon atoms, and includes, for example, a cyclohexylene group, a cyclopentylene group, a norbornylene group, an adamantylene group or the like. A chain alkylene group is more preferable and a methylene group is particularly preferable in order to express the effects of the present invention.

The monovalent organic group having a lactone structure or a sultone structure represented by R₈ is not particularly limited as long as the group has a lactone structure or a sultone structure, and specific examples include the lactone structure or the sultone structure represented by General Formulae (LC1-1) to (LC1-17) and (SL1-1) to (SL1-3) and among these, the structure represented by (LC1-4) is particularly preferable. In addition, n₂ is preferably 2 or less in (LC1-1) to (LC1-17) and (SL1-1) to (SL1-3).

In addition, R₈ is preferably a monovalent organic group containing an unsubstituted lactone structure or a sultone structure, or a monovalent organic group containing a lactone structure or a sultone structure having a methyl group, a cyano group or an alkoxycarbonyl group as a substituent, and more preferably a monovalent organic group containing a lactone structure having a cyano group as a substituent (cyanolactone) or a sultone structure having a cyano group as a substituent (cyanosultone).

Specific examples of the repeating unit containing a group having a lactone structure or a sultone structure represented by General Formula (VI) are shown below, however, the present invention is not limited to these.

In the following specific examples, R represents a hydrogen atom, an alkyl group which may have a substituent or a halogen atom, and preferably represents a hydrogen atom, a methyl group, a hydroxymethyl group or an acetyloxymethyl group.

In the following formula, Me represents a methyl group.

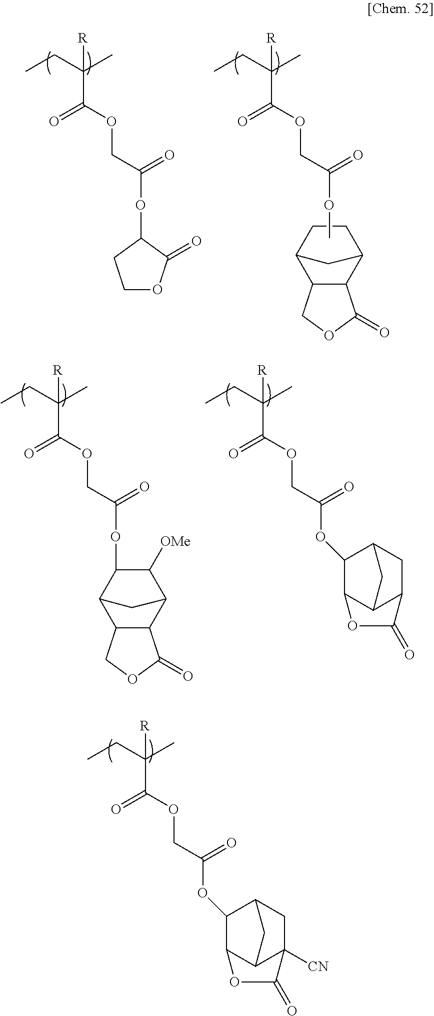

As the repeating unit having a lactone structure or a sultone structure, a repeating unit represented by the following General Formula (VI-1) or (VI-1′) is more preferable.

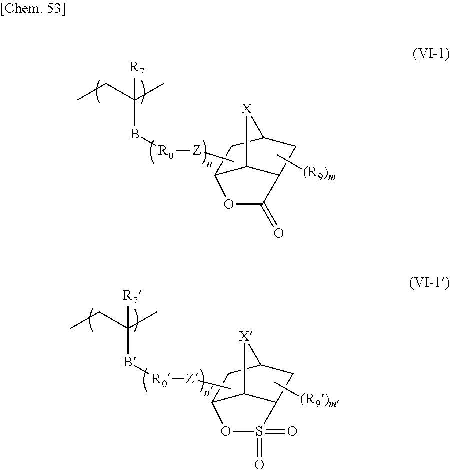

In General Formulae (VI-1) and (VI-1′), R₇, B, R₀, Z and n are synonymous with those in General Formula (VI).

R₇′, B′, R₀′, Z′ and n′ are synonymous with R₇, B, R₀, Z and n in General Formula (VI), respectively.

R₉s, when present in plural number, each independently represent an alkyl group, a cycloalkyl group, an alkoxycarbonyl group, a cyano group, a hydroxyl group or an alkoxy group, and when R₉ s are present in plural number, two R₉s may be bonded to each other to form a ring.

R₉s, when present in plural number, each independently represent an alkyl group, a cycloalkyl group, an alkoxycarbonyl group, a cyano group, a hydroxyl group or an alkoxy group, and when R₉s are present in plural number, two R₉s may be bonded to each other to form a ring.

X and X′ each independently represent an alkylene group, an oxygen atom or a sulfur atom.

m and m′ are the number of substituents, and each independently represents an integer of 0 to 5. It is preferable that m and m′ each independently represent 0 or 1.

The alkyl group of R₉ and R₉′ is preferably an alkyl group having 1 to 4 carbon atoms, more preferably a methyl group or an ethyl group, and most preferably a methyl group. The cycloalkyl group may include a cyclopropyl group, a cyclobutyl group, a cyclopentyl group or a cyclohexyl group. The alkoxycarbonyl group may include a methoxycarbonyl group, an ethoxycarbonyl group, an n-butoxycarbonyl group, a t-butoxycarbonyl group, or the like. The alkoxy group may include a methoxy group, an ethoxy group, a propoxy group, an isopropoxy group, a butoxy group, or the like. These groups may have a substituent, and the substituent may include a hydroxy group, an alkoxy group such as a methoxy group or an ethoxy group, a cyano group, a halogen atom such as a fluorine atom. R₉ and R₉′ are more preferably a methyl group, a cyano group or an alkoxycarbonyl group, and even more preferably a cyano group.

The alkylene group of X and X′ may include a methylene group or an ethylene group. X and X′ are preferably an oxygen atom or a methylene group, and more preferably a methylene group.

When m and m′ are 1 or more, it is preferable that at least one R₉ and R₉′ be substituted at the α-position or β-position of the carbonyl group of the lactone, and being substituted at the α-position is particularly preferable.

Specific examples of the group having a lactone structure or the repeating unit having a sultone structure represented by General Formula (VI-1) or (VI-1′) are shown below, however, the present invention is not limited to these. In the following specific examples, R represents a hydrogen atom, an alkyl group which may have a substituent or a halogen atom, and preferably represent a hydrogen atom, a methyl group, a hydroxymethyl group, or an acetyloxymethyl group.

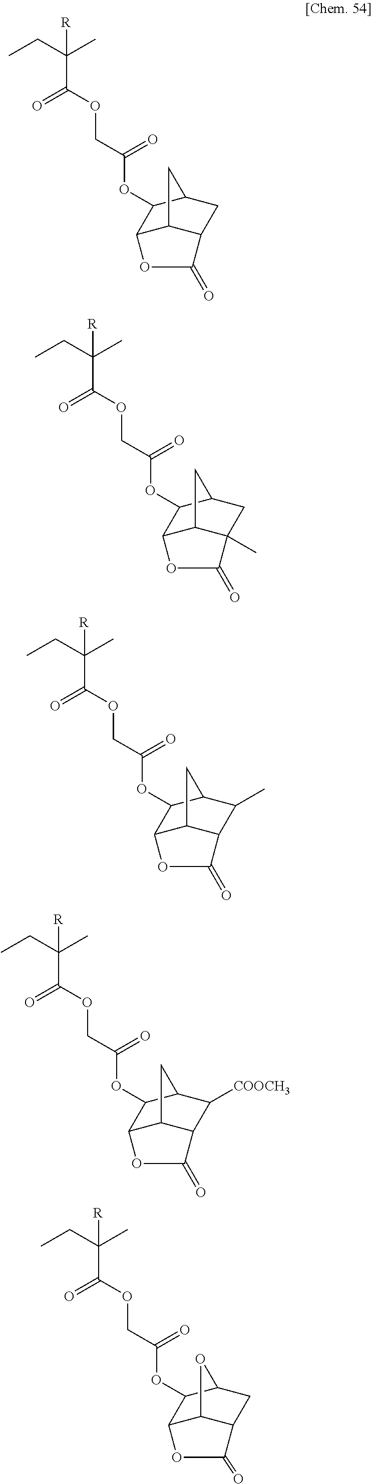

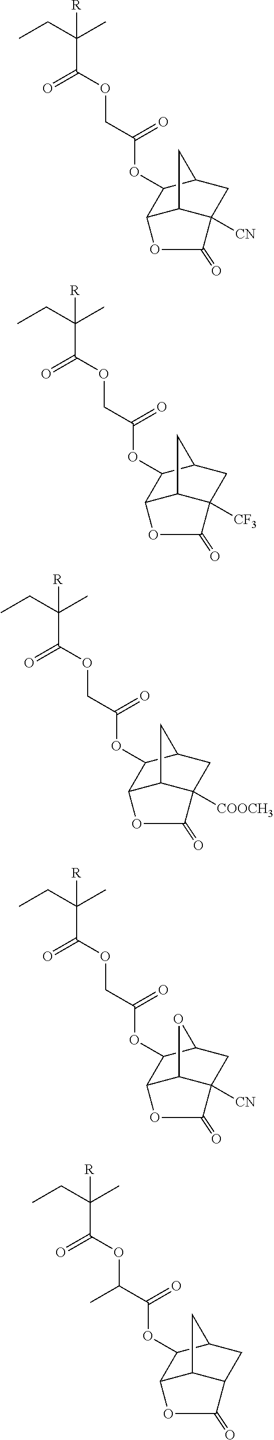

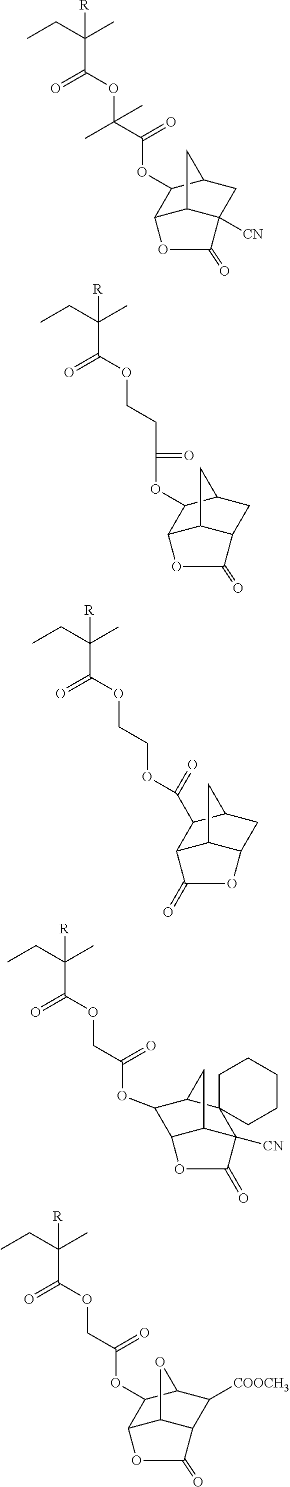

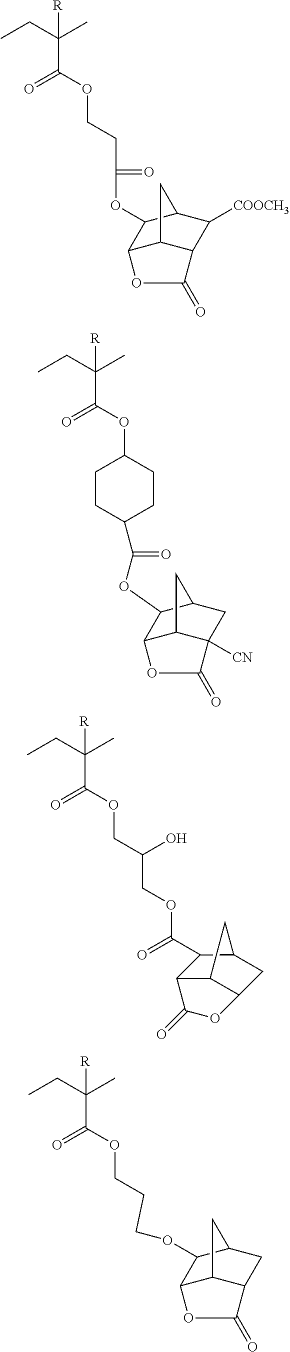

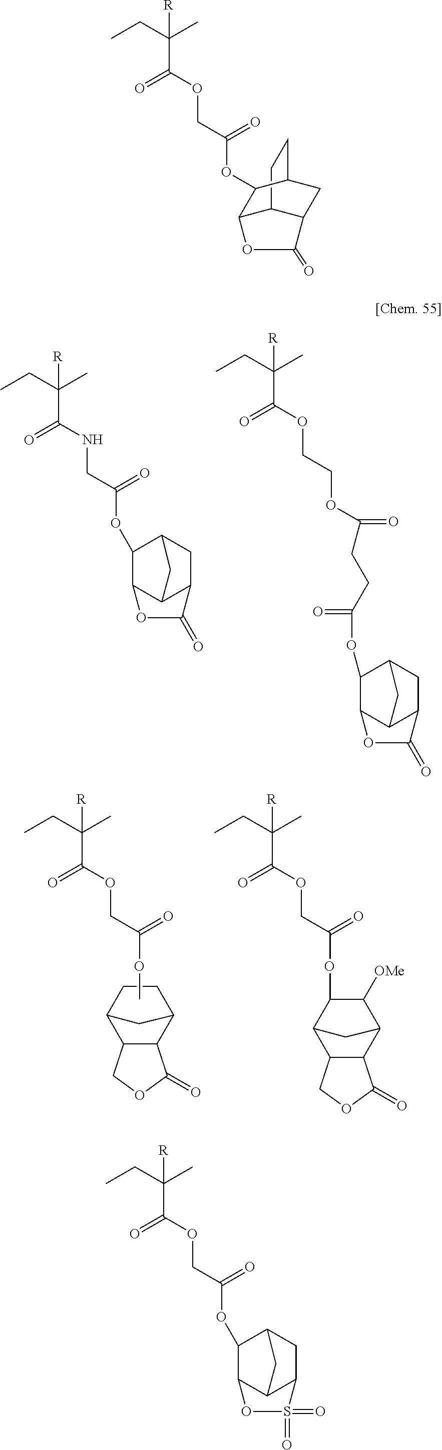

In one embodiment, the unit represented by General Formula (VI) may be a repeating unit represented by the following General Formula (AII′).

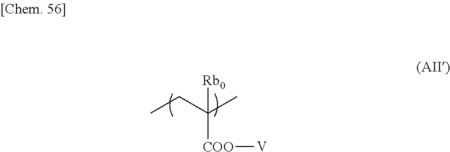

In General Formula (AII′), Rb₀ represents a hydrogen atom, a halogen atom or an alkyl group having 1 to 4 carbon atoms. The preferable substituent the alkyl group of Rb₀ may have may includes a hydroxyl group or a halogen atom. The halogen atom of Rb₀ may include a fluorine atom, a chlorine atom, a bromine atom or an iodine atom. Rb₀ is preferably a hydrogen atom, a methyl group, a hydroxymethyl group or a trifluoromethyl group, and particularly preferably a hydrogen atom or a methyl group.

V represents a group having a structure represented by any of General Formulae (LC1-1) to (LC1-17) and (SL1-1) to (SL1-3).

The resin (B) may also contain the repeating unit having a lactone structure or a sultone structure described above in addition to the unit represented by General Formula (VI).

Specific examples of the repeating unit having a lactone group or a sultone group are shown below in addition to the specific examples included above, however, the present invention is not limited to these.

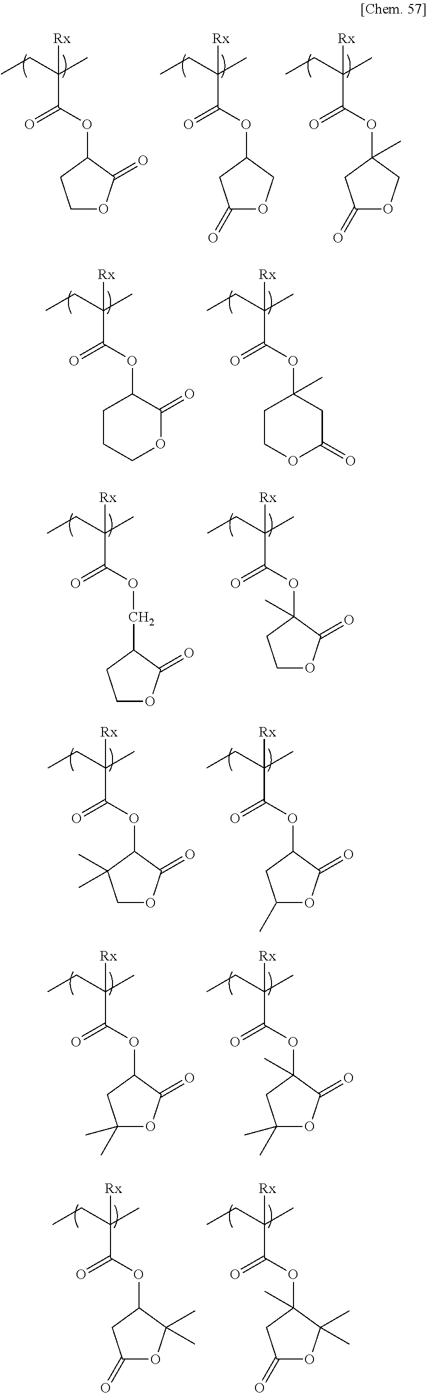

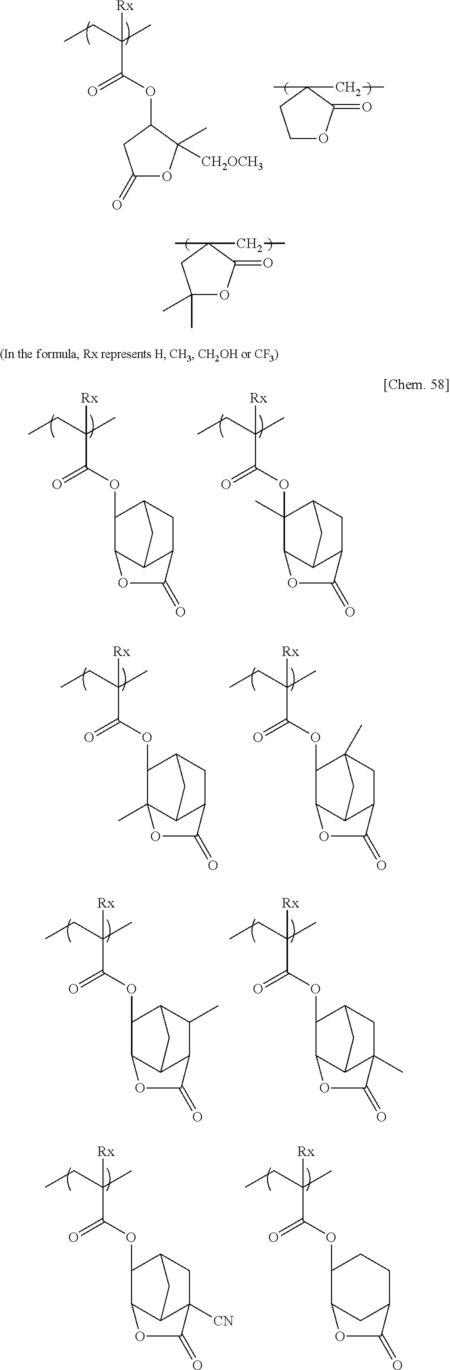

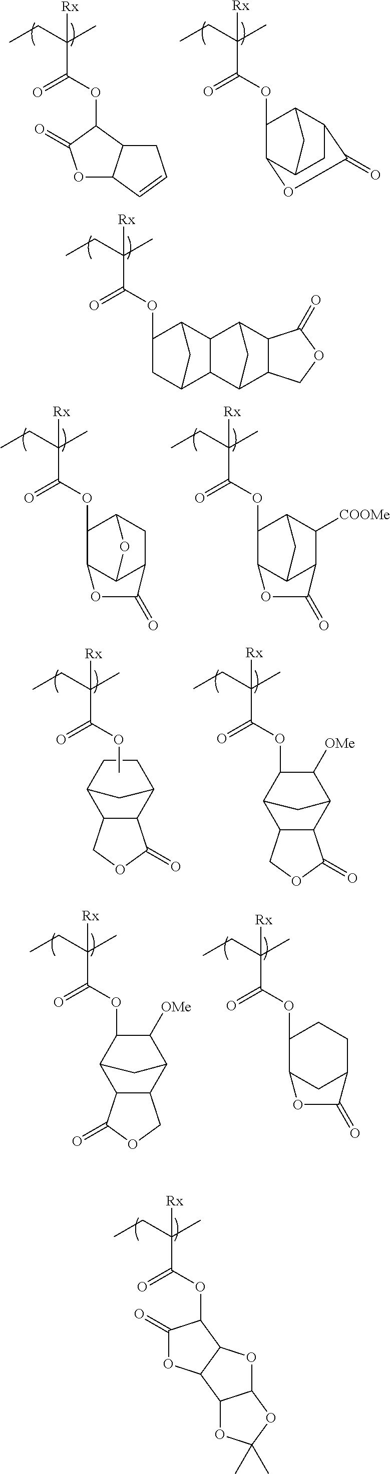

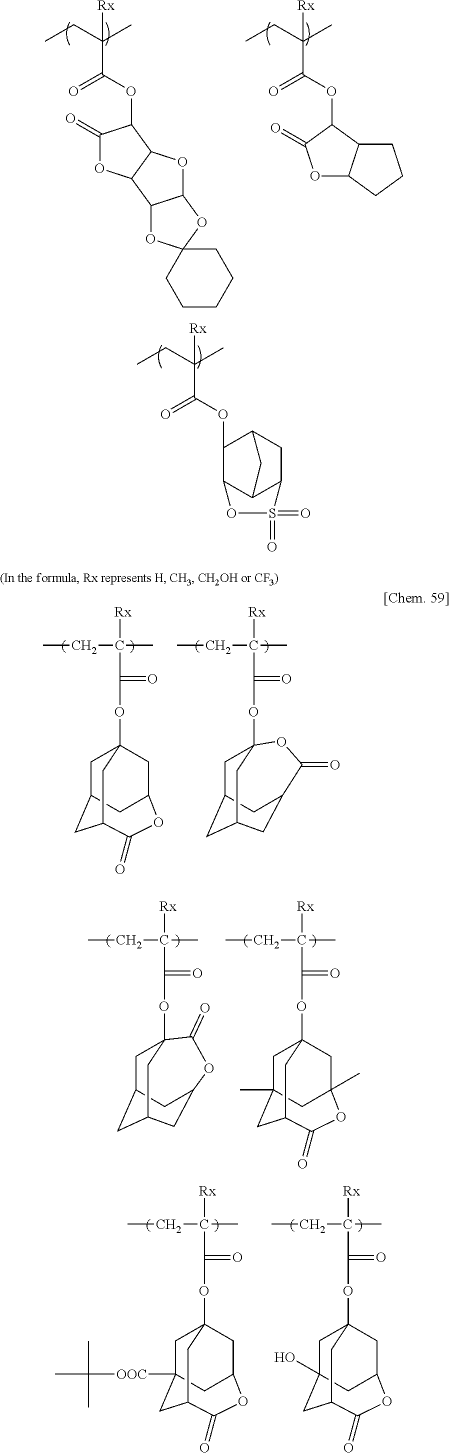

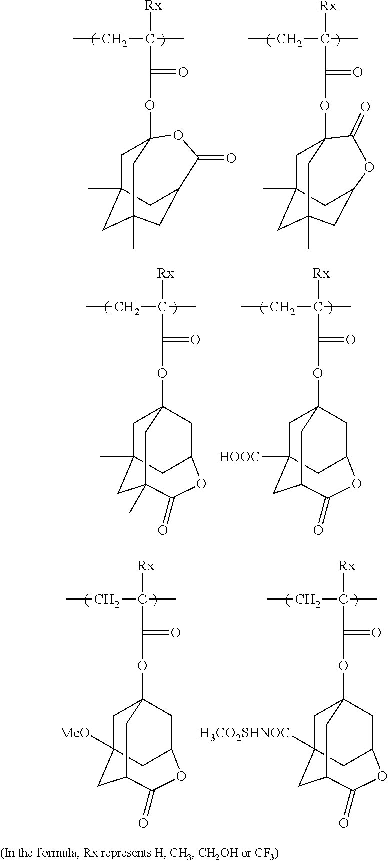

The repeating units particularly preferable among the above specific examples may include the following repeating units. By selecting the optimal lactone group or sultone group, pattern profile and density dependence are improved.

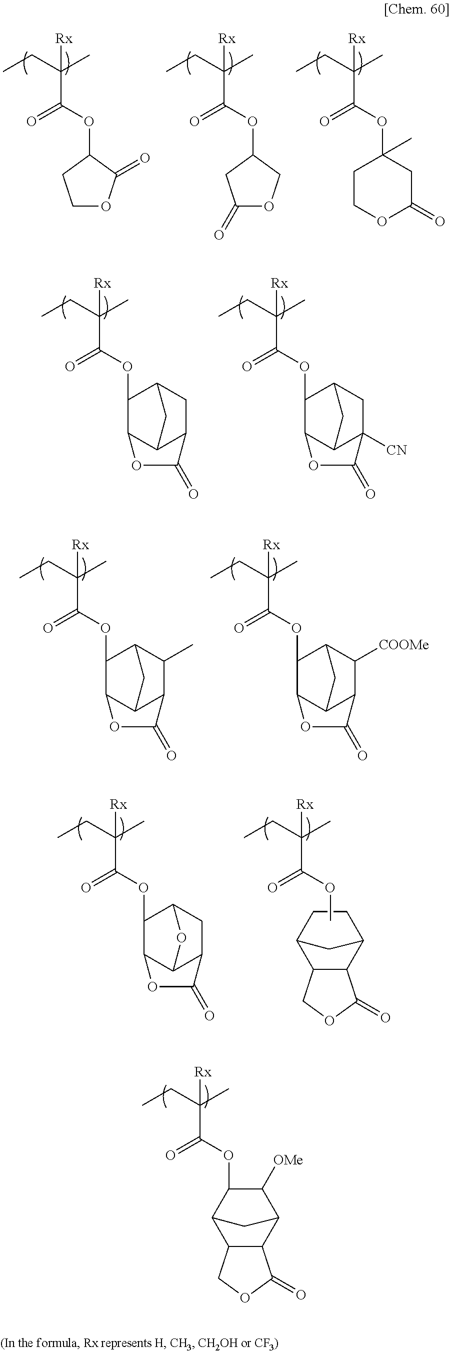

The repeating unit having a lactone group or a sultone group typically includes optical isomers, however, any optical isomer may be used. In addition, one optical isomer may be used alone or a plurality of optical isomers may be mixed and used. When one optical isomer is mainly used, an optical purity (ee) thereof is preferably 90% or more, and more preferably 95% or more.

The resin (B) may have two or more types of the repeating units having a lactone structure or a sultone structure. For example, the resin (B) containing two or more types of repeating units having a lactone structure, the resin (B) containing two or more types of repeating units having a sultone structure, and the resin (B) containing a repeating unit having a lactone structure and a repeating unit having a sultone structure may be included. In particular, in General Formula (VI), a combination of two or more types selected from the lactone repeating units in which n is 1 is preferable.

The content of the repeating unit having a lactone structure or a sultone structure, the total content when a plurality of types are included, is preferably 15 to 60 mol %, more preferably 20 to 60 mol %, and even more preferably 30 to 50 mol % with regard to all repeating units in the resin (B).

The resin (B) preferably contains a repeating unit having a hydroxyl group or a cyano group in addition to those in General Formulae (AI) and (VI). As a result, substrate adhesion and developer affinity are improved. The repeating unit having a hydroxyl group or a cyano group is preferably a repeating unit having an alicyclic hydrocarbon structure substituted with a hydroxyl group or a cyano group and preferably a repeating unit having no acid decomposable groups. As the alicyclic hydrocarbon structure in the alicyclic hydrocarbon structure substituted with a hydroxyl group or a cyano group, an adamantyl group, a diamantyl group or a norbornane group is preferable. As the preferable alicyclic hydrocarbon structure substituted with a hydroxyl group or a cyano group, a partial structure represented by the following General Formulae (VIIa) to (VIId) is preferable.

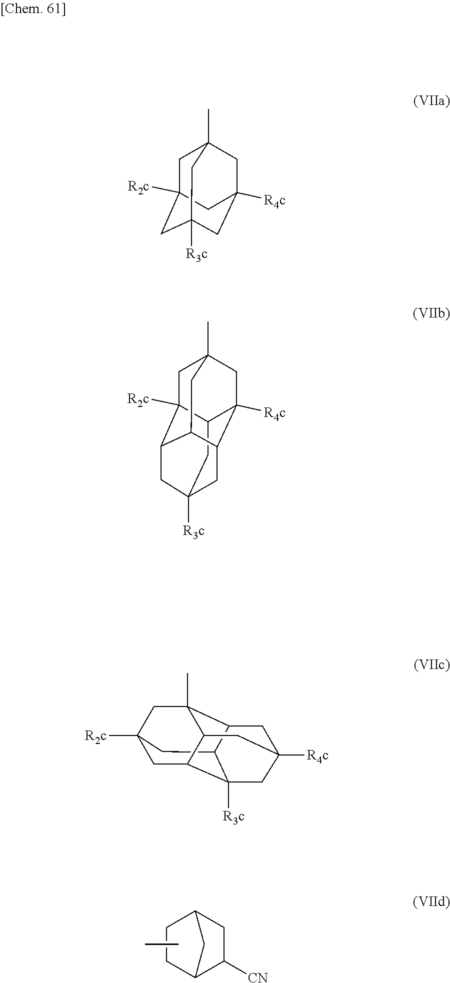

In General Formulae (VIIa) to (VIIc), R_{2c} to R_{4c} each independently represent a hydrogen atom, a hydroxyl group or a cyano group. However, at least one of R_{2c} to R_{4c} represents a hydroxyl group, or a cyano group. Preferably, one or two of R_{2c} to R_{4c} are hydroxyl groups with the remainder being hydrogen atoms. In General Formula (VIIa), it is more preferable that two of R_{2c} to R_{4c} be hydroxyl groups and the remaining be hydrogen atoms.

The repeating units having a partial structure represented by General Formulae (VIIa) to (VIId) may include a repeating unit represented by the following General Formulae (AIIa) to (AIId).

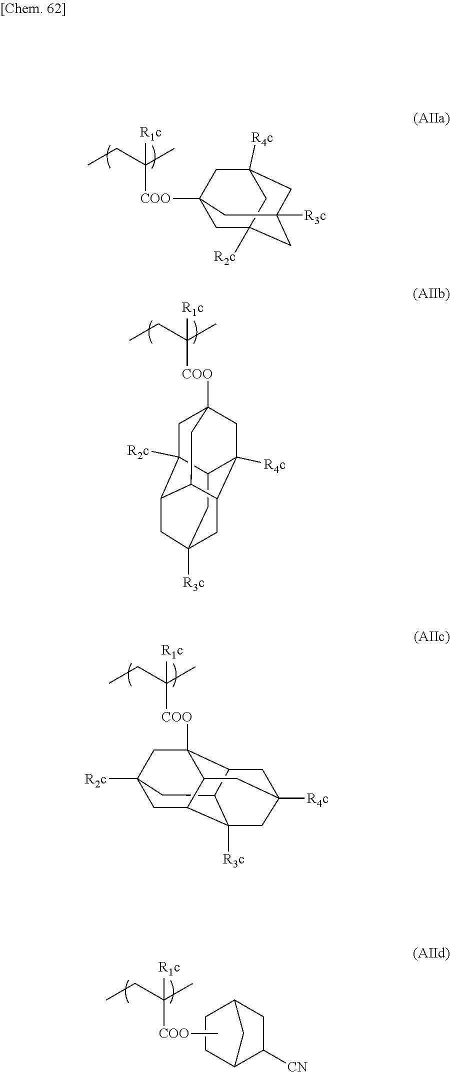

In General Formulae (AIIa) to (AIId), R_{1c} represents a hydrogen atom, a methyl group, a trifluoromethyl group or a hydroxymethyl group.

R₂, to R_{4c} are synonymous with R₂, to R₄, in General Formulae (VIIa) to (VIIc).

The resin (B) may or may not contain a repeating unit having a hydroxyl group or a cyano group, but when the resin (B) does, the content of the repeating unit having a hydroxyl group or a cyano group is preferably 5 to 40 mol %, more preferably 5 to 30 mol % and even more preferably 10 to 25 mol % with regard to all repeating units in the resin (B).

Specific examples of the repeating unit having a hydroxyl group, or a cyano group are shown below, however, the present invention is not limited to these.

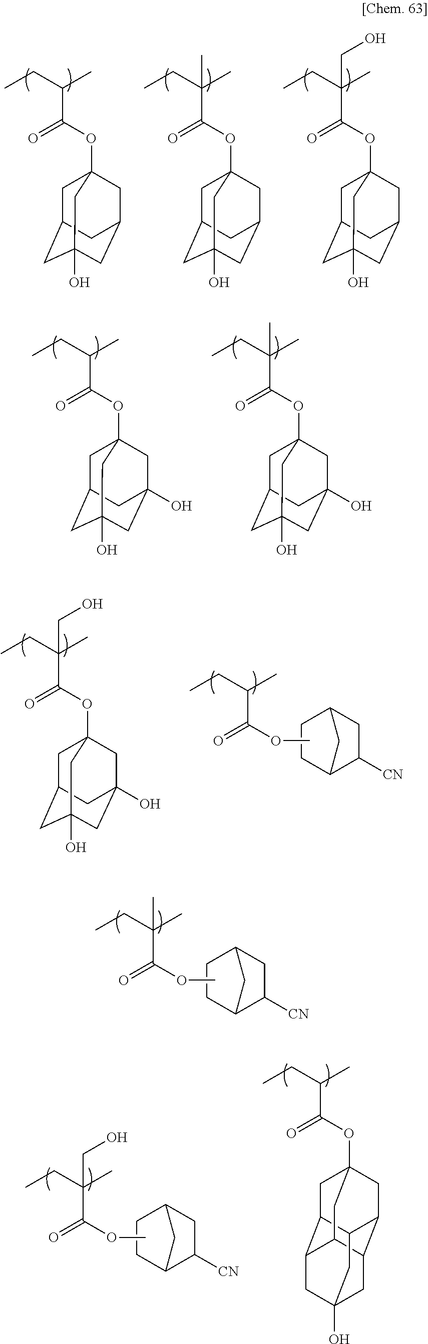

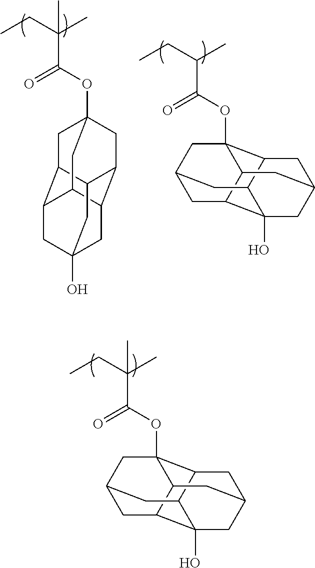

The resin (B) used in the actinic ray-sensitive or radiation-sensitive resin composition of the present invention may contain a repeating unit having an alkali-soluble group. The alkali-soluble group may include a carboxyl group, a sulfonamide group, a sulfonylimide group, a bissulfonylimide group, an aliphatic alcohol of which an α-position is substituted with an electron-withdrawing group (for example, a hexafluoroisopropanol group), and containing a repeating unit having a carboxyl group is more preferable. By containing the repeating unit having an alkali-soluble group, resolution in a contact hole application increases. As the repeating unit having an alkali-soluble group, a repeating unit in which the alkali-soluble group is bonded directly to a main chain of the resin such as a repeating unit of acrylic acid or methacrylic acid, a repeating unit in which the alkali-soluble group is bonded to a main chain of the resin through a linking group, and introducing the repeating unit to the end of the polymer chain using a polymerization initiator or a chain transfer agent having an alkali-soluble group when polymerized are all preferable, and the linking group may have a monocyclic or polycyclic cyclic hydrocarbon structure. A repeating unit of acrylic acid or methacrylic acid is particularly preferable.

The resin (B) may or may not contain the repeating unit having an alkali-soluble group, but when the resin (B) does, the content of the repeating unit having an alkali-soluble group is preferably 1 to 20 mol %, more preferably 3 to 15 mol % and even more preferably 5 to 10 mol % with regard to all repeating units in the resin (B).

Specific examples of the repeating unit having an alkali-soluble group are shown below, however, the present invention is not limited to these.

In the specific examples, Rx represents H, CH₃, CH₂OH or CF₃.

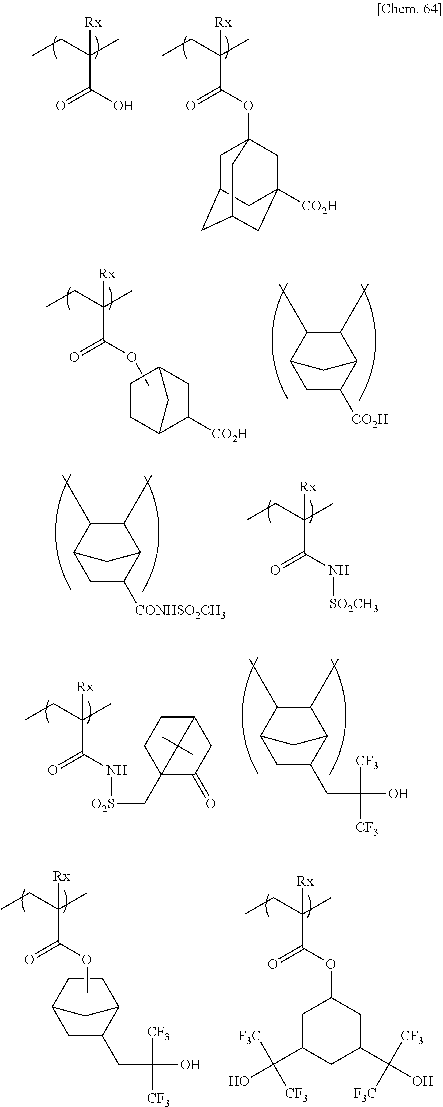

The resin (B) of the present invention may further contain a repeating unit which has an alicyclic hydrocarbon structure having no polar groups (for example, the alkali-soluble group, the hydroxyl group or the cyano group), and does not show acid decomposability. The repeating unit such as this may include a repeating unit represented by General Formula (IV).

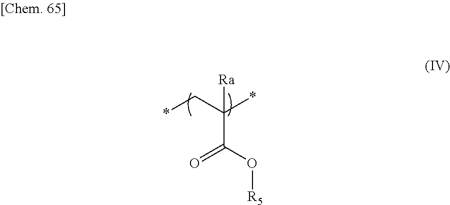

In General Formula (IV), R₅ represents a hydrocarbon group having at least one cyclic structure and having no polar groups.

Ra represents a hydrogen atom, an alkyl group or a —CH₂—O—Ra₂ group. In the formula, Ra₂ represents a hydrogen atom, an alkyl group or an acyl group. Ra is preferably a hydrogen atom, a methyl group, a hydroxymethyl group or a trifluoromethyl group, and a hydrogen atom or a methyl group is particularly preferable.

The cyclic structure R₅ has includes a monocyclic hydrocarbon group and a polycyclic hydrocarbon group. Examples of the monocyclic hydrocarbon group include a cycloalkyl group having 3 to 12 carbon atoms such as a cyclopentyl group, a cyclohexyl group, a cycloheptyl group or a cyclooctyl group, or a cycloalkenyl group having 3 to 12 carbon atoms such as a cyclohexenyl group. The monocyclic hydrocarbon group is preferably a monocyclic hydrocarbon group having 3 to 7 carbon atoms, and more preferably a cyclopentyl group or a cyclohexyl group.

The polycyclic hydrocarbon group includes a ring-assembled hydrocarbon group and a crosslinked cyclic hydrocarbon group, and examples of the ring-assembled hydrocarbon group include a bicyclohexyl group or a perhydronaphthalenyl group. Examples of the crosslinked cyclic hydrocarbon ring include a dicyclic hydrocarbon ring such as a pinane ring, a bornane ring, a norpinane ring, a norbornane ring or a bicyclooctane ring (a bicyclo[2.2.2]octane ring or a bicyclo[3.2.1]octane ring), a tricyclic hydrocarbon ring such as a homobrendane ring, an adamantine ring, a tricyclo[5.2.1.0^{2,6}]decane ring or a tricyclo[4.3.1.1^{2,5}]undecane ring, a tetracyclic hydrocarbon ring such as a tetracyclo[4.4.0.1^{2,5}.1^{7,10}]dodecane ring or a perhydro-1,4-methano-5,8-methanonaphthalene ring, or the like. In addition, the crosslinked cyclic hydrocarbon ring may also include a condensed cyclic hydrocarbon ring, for example, a condensed cyclic ring in which a plurality of 5- to 8-membered cycloalkane rings such as a perhydronaphthalene (decalin) ring, a perhydroanthracene ring, a perhydrophenanthrene ring, a perhydroacenaphthene ring, a perhydrofluorene ring, a perhydroindene ring, and a perhydrophenalene ring are condensed.

The preferable crosslinked cyclic hydrocarbon ring may include a norbornyl group, an adamantyl group, a bicyclooctanyl group, a tricyclo[5.2.1.0^{2,6}]decanyl group, or the like. The more preferable crosslinked cyclic hydrocarbon ring may include a norbornyl group or an adamantyl group.

These alicyclic hydrocarbon groups may have a substituent, and the preferable substituent may include a halogen atom, an alkyl group, a hydroxyl group in which the hydrogen atom is substituted, an amino group in which the hydrogen atom is substituted, or the like. The preferable halogen atom may include a bromine atom, a chlorine atom or a fluorine atom, and the preferable alkyl group may include a methyl group, an ethyl group, a butyl group or a t-butyl group. The above alkyl group may further have a substituent, and the substituent the alkyl group may further have includes a halogen atom, an alkyl group, a hydroxyl group in which the hydrogen atom is substituted, or an amino group in which the hydrogen atom is substituted.

Examples of the group in which the hydrogen atom is substituted include an alkyl group, a cycloalkyl group, an aralkyl group, a substituted methyl group, a substituted ethyl group, an alkoxycarbonyl group, an aralkyloxycarbonyl group, or the like. The preferable alkyl group may include an alkyl group having 1 to 4 carbon atoms, the preferable substituted methyl group may include a methoxymethyl group, a methoxythiomethyl group, a benzyloxymethyl group, a t-butoxymethyl group or a 2-methoxyethoxymethyl group, the preferable substituted ethyl group may include a 1-ethoxyethyl group or a 1-methyl-1-methoxyethyl group, the preferable acyl group may include an aliphatic acyl group having 1 to 6 carbon atoms such as a formyl group, an acetyl group, a propionyl group, a butyryl group, an isobutyryl group, a valeryl group or a pivaloyl group, and the alkoxycarbonyl group may include an alkoxycarbonyl group having 1 to 4 carbon atoms, or the like.

The resin (B) may or may not contain a repeating unit which has an alicyclic hydrocarbon structure having no polar groups and does not show acid decomposability, however, when the resin (B) does, the content of this repeating unit is preferably 1 to 40 mol % and more preferably 2 to 20 mol % with regard to all repeating units in the resin (B).

Specific examples of the repeating unit which has an alicyclic hydrocarbon structure having no polar groups and does not show acid decomposability are shown below, however, the present invention is not limited to these. In the formula, Ra represents H, CH₃, CH₂OH or CF₃.

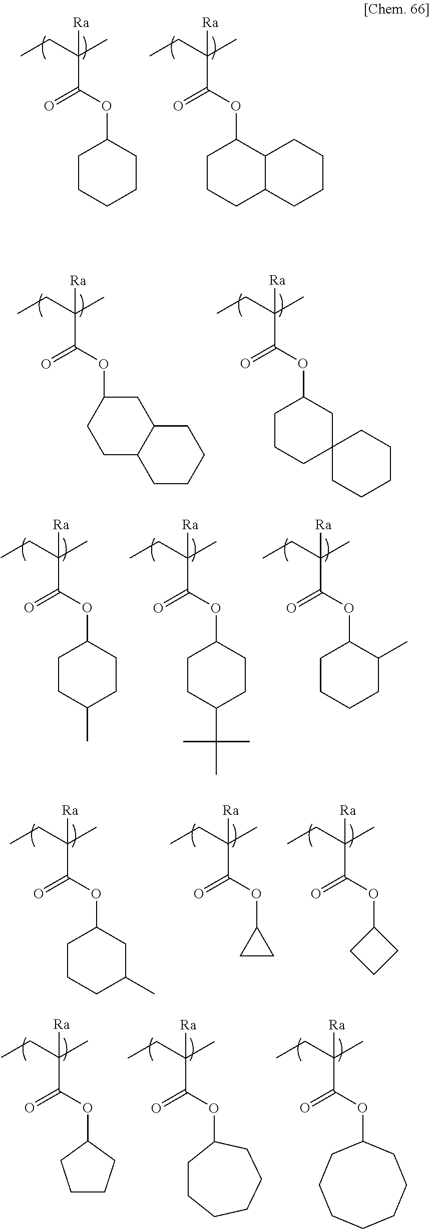

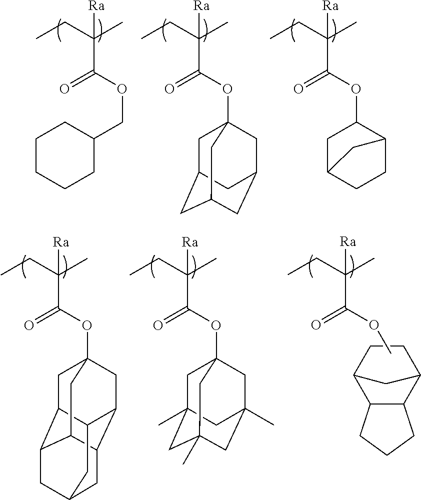

The resin (B) used in the composition of the present invention may have a variety of repeating structural units in addition to the above repeating structural units for the purpose of adjusting dry etching resistance or standard developer suitability, substrate adhesion, a resist profile, or characteristics generally needed for a resist such as resolution, heat resistance and sensitivity.

The repeating unit structures such as this may include, but are not limited to, repeating unit structures corresponding to the following monomers.

As a result, fine-tuning of the performances required for a resin used in the composition of the present invention, particularly, (1) solubility for a coating solvent, (2) film formability (glass transition point), (3) alkali developability, (4) film reduction (hydrophobicity, alkali-soluble group selection), (5) adhesion of the unexposed portion to the substrate, (6) dry etching resistance, or the like, becomes possible.

Examples of the monomer such as this may include a compound having one addition-polymerizable unsaturated bond selected from acrylates, methacrylates, acrylamides, methacrylamides, allyl compounds, vinyl ethers, vinyl esters and the like, or the like.

In addition to these, addition-polymerizable unsaturated compounds copolymerizable with the monomers corresponding to a variety of repeating structural units described above may be copolymerized.

In the resin (B) used in the composition of the present invention, the molar ratio of the content of each repeating structural unit is appropriately determined in order to adjust dry etching resistance of the resist, standard developer suitability, substrate adhesion, a resist profile, and generally required performances of a resist such as resolution, heat resistance and sensitivity.

Practically, the resin (B) used in the composition of the present invention preferably does not have an aromatic ring when the composition of the present invention is for ArF exposure in terms of transparency to ArF light. More specifically, in all repeating units of the resin (B), the ratio of the repeating unit having an aromatic group is preferably 5 mol % or less, more preferably 3 mol % or less, and ideally 0 mol %, that is, an aromatic group is not present. In addition, the resin (B) preferably has a monocyclic or polycyclic alicyclic hydrocarbon structure.

In addition, the resin (B) preferably does not contain a fluorine atom or a silicon atom from the viewpoint of compatibility with a hydrophobic resin described later.

In the resin (B) used in the composition of the present invention, it is preferable that all the repeating units be composed of (meth)acrylate-based repeating units. In this case, any of the repeating units in which all the repeating units are methacrylate-based repeating units, all the repeating units are acrylate-based repeating units, and all the repeating units are methacrylate-based repeating units and acrylate-based repeating units may be used, however, the acrylate-based repeating unit being 50 mol % or less of all the repeating units is preferable. In addition, a copolymer, including 20 to 50 mol % of the (meth)acrylate-based repeating units having an acid decomposable group, 20 to 50 mol % of the (meth)acrylate-based repeating units having a lactone group, 5 to 30 mol % of the (meth)acrylate-based repeating units having an alicyclic hydrocarbon structure substituted with a hydroxyl group or a cyano group, and further including 0 to 20 mol % of other (meth)acrylate-based repeating units, is also preferable.

When KrF excimer laser light, an electron beam, X-rays, and a high-energy light beam with a wavelength of 50 nm or less (EUV and the like) are irradiated on the composition of the present invention, the resin (B) preferably further contains a hydroxystyrene-based repeating unit. More preferably, containing a hydroxystyrene-based repeating unit, a hydroxystyrene-based repeating unit protected by an acid decomposable group and an acid decomposable repeating unit such as tertiary alkyl(meth)acrylate is preferable.

Preferable examples of the hydroxystyrene-based repeating unit having an acid decomposable group include a repeating unit composed of t-butoxycarbonyloxy styrene, 1-alkoxyethoxy styrene, tertiary alkyl(meth)acrylate, or the like, and a repeating unit composed of 2-alkyl-2-adamantyl(meth)acrylate and dialkyl(1-adamantyl)methyl(meth)acrylate is more preferable.

The resin (B) in the present invention can be synthesized in accordance with conventional methods (for example, radical polymerization). Examples of the general synthesis method include a batch polymerization method in which polymerization is carried out by dissolving monomer species and an initiator in a solvent and heating the solution, a dropwise adding polymerization method in which a solution of monomer species and an initiator is added dropwise to a heating solvent over a period of 1 to 10 hours or the like, and a dropwise adding polymerization method is preferable. Examples of the reaction solvent include a solvent which dissolves the composition of the present invention such as ethers such as tetrahydrofuran, 1,4-dioxane or diisopropyl ether, ketones such as methyl ethyl ketone or methyl isobutyl ketone, ester solvents such as ethyl acetate, amide solvents such as dimethyl formamide or dimethyl acetamide, propylene glycol monomethyl ether acetate described later, propylene glycol monomethyl ether or cyclohexanone. Polymerization using the same solvent as the solvent used in the actinic ray-sensitive or radiation-sensitive resin composition of the present invention is more preferable. This suppresses generation of the particles during storage.

The polymerization reaction is preferably carried out under an inert gas atmosphere such as nitrogen or argon. As the polymerization initiator, commercially available radical initiators (an azo-based initiator, peroxide, or the like) are used to start the polymerization. The radical initiator is preferably an azo initiator, and the azo initiator having an ester group, a cyano group or a carboxyl group is preferable. Preferable initiators may include azobisisobutyronitrile, azobisdimethylvaleronitrile, dimethyl 2,2′-azobis(2-methyl propionate), or the like. The initiator is added, or added in installments as necessary, and after the reaction is complete, the resultant is poured into a solvent, and the target polymer is collected using a method such as powder or solid recovery. The concentration of the reaction is 5 to 50% by mass and preferably 10 to 30% by mass. The reaction temperature is normally 10 to 150° C., preferably 30 to 120° C., and more preferably 60 to 100° C.

After the reaction is complete, the resultant is allowed to cool to room temperature and purified. Purification may be carried out using common methods such as a liquid-liquid extraction method in which residual monomers and oligomer components are removed by washing with water or combining appropriate solvents, a purification method in a solution state such as ultrafiltration in which those with less than or equal to a specific molecular weight are extracted and removed, a re-precipitation method in which residual monomers and the like are removed by coagulating the resin in a poor solvent through a dropwise addition of the resin solution to a poor solvent, and a purification method in a solid state in which separated resin slurry is washed with a poor solvent. For example, the resin is precipitated as solids by contacting the resin with a sparingly soluble or insoluble solvent (a poor solvent) in 10 times or less of the volume of the reaction solution, and preferably 5 to 10 times the volume.

The solvent used during precipitation or re-precipitation from the polymer solution (precipitation or re-precipitation solvent) may be a poor solvent of the polymer, and may be appropriately selected and used from hydrocarbons, halogenated hydrocarbons, nitro compounds, ethers, ketones, esters, carbonates, alcohols, carboxylic acids, water, and a mixed solvent including these solvents, depending on the types of the polymer.

The amount of the precipitation or re-precipitation solvent used may be appropriately selected considering efficiency and yield, but in general, is 100 to 10,000 parts by mass, preferably 200 to 2,000 parts by mass, and is more preferably 300 to 1,000 parts by mass with regard to 100 parts by mass of the polymer solution.

The precipitation or re-precipitation temperature may be appropriately selected considering efficiency and operability, but is normally in the order of 0 to 50° C., and preferably in the vicinity of room temperature (for example, approximately 20 to 35° C.). Precipitation or re-precipitation operation may be carried out by well-known methods of batch-type or continuous-type using a commonly employed mixing vessel such as a stirring tank.

Typically, the precipitated or re-precipitated polymer is provided for use after being subjected to commonly employed solid-liquid separation such as filtration and centrifugation, and then dried. Filtration is carried out using a filtration material with solvent resistance, preferably under reduced pressure. Drying is carried out at a temperature of approximately 30 to 100° C., preferably approximately 30 to 50° C. under atmospheric pressure or reduced pressure (preferably under reduced pressure).

In addition, after the resin is precipitated and separated once, the resin is re-dissolved in a solvent, and then the resin may be brought into contact with a solvent in which the resin is sparingly soluble or insoluble. In other words, after the radical polymerization reaction above is complete, a method may be used in which the polymer is brought into contact with a solvent in which the polymer is sparingly soluble or insoluble, and the resin is precipitated (step a), the resin is separated from the solution (step b), then, the resin is re-dissolved in a solvent and the resin solution A is prepared (step c), after that, the resin solid is precipitated by bringing the resin solution A into contact with a solvent in which the resin is sparingly soluble or insoluble in less than 10 times volume of the resin solution A (preferably 5 times or less volume) (step d), and the resin precipitated is separated (step e).

Moreover, in order to suppress aggregation or the like of the resin after the composition is prepared, a step, in which the resin synthesized is dissolved in a solvent to become a solution and the solution is heated at approximately 30 to 90° C. for approximately 30 minutes to 4 hours, may be added as disclosed in, for example, JP2009-037108A.

The weight-average molecular weight of the resin (B) used in the composition of the present invention, as a polystyrene conversion value by a GPC method, is preferably 1,000 to 200,000, more preferably 2,000 to 20,000, even more preferably 3,000 to 15,000, and particularly preferably 3,000 to 11,000. By keeping the weight-average molecular weight as 1,000 to 200,000, deterioration of heat resistance and dry etching resistance may be prevented and deterioration of developability or deterioration of film formability due to an increase in viscosity may be prevented.

The degree of dispersion (molecular weight distribution, Mw/Mn) is typically in the range of 1.0 to 3.0, preferably 1.0 to 2.6, more preferably 1.0 to 2.0, and particularly preferably 1.4 to 2.0. The smaller the molecular weight distribution is, the resolution and the resist shape are excellent, the side wall of the resist pattern is also smooth, and the roughness property is excellent. In the present specification, the weight-average molecular weight (Mw) and the number average molecular weight (Mn) of the resin (B), may be measured using, for example, an HLC-8120 (manufactured by Tosoh Co., Ltd.), and, for a column, a TSK gel Multipore HXL-M (manufactured by Tosoh Co., Ltd., 7.8 mm ID×30.0 cm), and as an eluent, THF (tetrahydrofuran) are used.

In the actinic ray-sensitive or radiation-sensitive resin composition of the present invention, the mixing amount of the resin (B) in the total composition is preferably 30 to 99% by mass, and more preferably 60 to 95% by mass in total solid contents.

In addition, the resin (B) of the present invention may be used either alone or as a combination of two types or more.

Furthermore, other resins in addition to the resin (B) may be used in combination as long as the effects of the present invention are not impaired. The other resins may include the acid decomposable resin which may contain the repeating unit which the resin (B) is capable of containing, and other well-known acid decomposable resins.

[3] Hydrophobic Resin

The actinic ray-sensitive or radiation-sensitive resin composition of the present invention may contain a hydrophobic resin which has at least any of a fluorine atom and a silicon atom, particularly when applied to liquid immersion exposure (hereinafter, also referred as a “hydrophobic resin (HR)”). As a result, the hydrophobic resin (HR) can be localized on the surface layer of the film, and may improve the immersion liquid traceability by improving a static/dynamic contact angle of the resist film surface for water when a liquid immersion medium is water.

The hydrophobic resin (HR) is preferably designed to be localized on the surface as described above, however, unlike surfactants, does not need to have a hydrophilic group within the molecule and does not necessarily contribute to uniformly mixing the polar/non-polar substances.

The hydrophobic resin (HR) typically includes a fluorine atom and/or a silicon atom. The fluorine atom and/or the silicon atom in the hydrophobic resin (HR) may be included in the main chain of the resin or included in the side chain.

When the hydrophobic resin (HR) includes a fluorine atom, a resin having an alkyl group having a fluorine atom, a cycloalkyl group having a fluorine atom, or an aryl group having a fluorine atom is preferable as the partial structure having a fluorine atom.

The alkyl group having a fluorine atom (preferably having 1 to 10 carbon atoms and more preferably having 1 to 4 carbon atoms) is a linear or branched alkyl group in which at least one hydrogen atom is substituted with a fluorine atom, and may have further substituents in addition to a fluorine atom.

The cycloalkyl group having a fluorine atom is a monocyclic or polycyclic cycloalkyl group of which at least one hydrogen atom is substituted with a fluorine atom, and may have further substituents in addition to a fluorine atom.

The aryl group having a fluorine atom is an aryl group such as a phenyl group, a naphthyl group, or the like, of which at least one hydrogen atom is substituted with a fluorine atom, and may have further substituents in addition to a fluorine atom.

As the alkyl group having a fluorine atom, the cycloalkyl group having a fluorine atom, and the aryl group having a fluorine atom may include a group represented by the following General Formulae (F2) to (F4), however, the present invention is not limited to these.

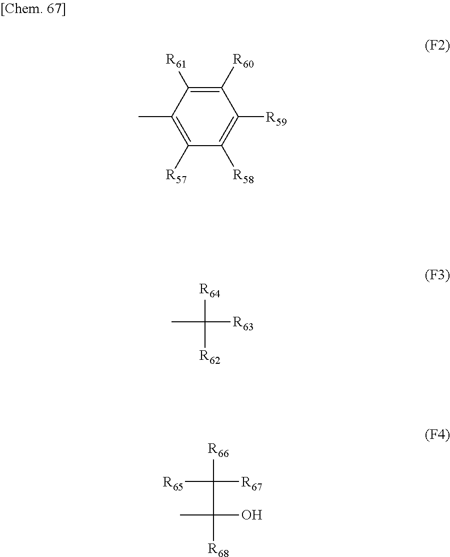

In General Formulae (F2) to (F4), R₅₇ to R₆₈ each independently represent a hydrogen atom, a fluorine atom, or an alkyl group (linear or branched). However, at least one of R₅₇ to R₆₁, at least one of R₆₂ to R₆₄ and at least one of R₆₅ to R₆₈ each independently represent a fluorine atom or an alkyl group of which at least one hydrogen atom is substituted with a fluorine atom (preferably 1 to 4 carbon atoms).

R₅₇ to R₆₁ and R₆₅ to R₆₇ are preferably all fluorine atoms. R₆₂, R₆₃, and R₆₈ are preferably a fluoroalkyl group (preferably having 1 to 4 carbon atoms), and more preferably a perfluoroalkyl group having 1 to 4 carbon atoms. When R₆₂ and R₆₃ are perfluoroalkyl groups, R₆₄ is preferably a hydrogen atom. R₆₂ and R₆₃ may be bonded to each other to form a ring.

Specific examples of the group represented by General Formula (F2) may include a p-fluorophenyl group, a pentafluorophenyl group, and a 3,5-di(trifluoromethyl)phenyl group, or the like.

Specific examples of the group represented by General Formula (F3) may include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, a perfluorocyclohexyl group, or the like. A hexafluoroisopropyl group, a heptafluoroisopropyl group, a hexafluoro(2-methyl)isopropyl group, an octafluoroisobutyl group, a nonafluoro-t-butyl group or a perfluoroisopentyl group is preferable, and a hexafluoroisopropyl group or a heptafluoroisopropyl group is more preferable.

Specific examples of the group represented by General Formula (F4) may include —C(CF₃)₂OH, —C(C₂F₅)₂OH, —C(CF₃)(CH₃)OH, —CH(CF₃)OH, or the like, and —C(CF₃)₂OH is preferable.

The partial structure including a fluorine atom may be bonded directly to the main chain, or may be bonded to the main chain through a group selected from the group consisting of an alkylene group, a phenylene group, an ether bond, a thioether bond, a carbonyl group, an ester bond, an amide bond, a urethane bond, and a ureylene bond, or a group combining two or more of these.

The suitable repeating unit having a fluorine atom may include units shown below.

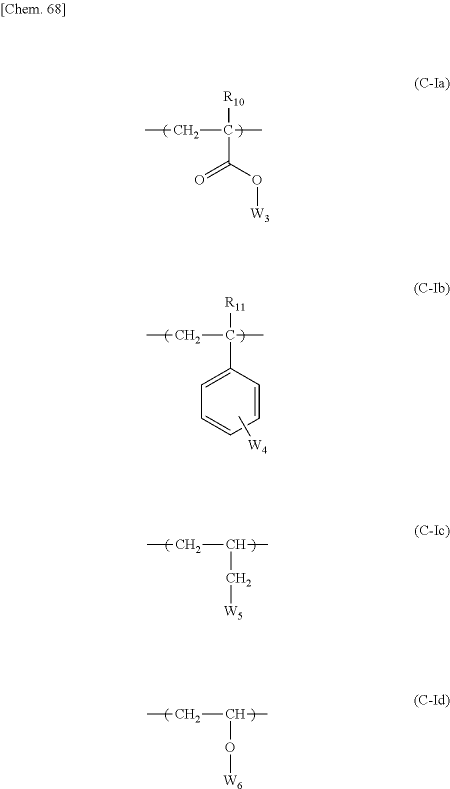

In the formula, R₁₀ and R₁₁ each independently represent a hydrogen atom, a fluorine atom or an alkyl group. The alkyl group is preferably a linear or branched alkyl group having 1 to 4 carbon atoms, may have a substituent, and the alkyl group having a substituent may particularly include a fluorinated alkyl group.

W₃ to W₆ each independently represent an organic group containing at least one or more fluorine atom. Specifically, an atomic group of (F2) to (F4) may be included.

Furthermore, in addition to these, the hydrophobic resin may have a unit represented below as a repeating unit having a fluorine atom.

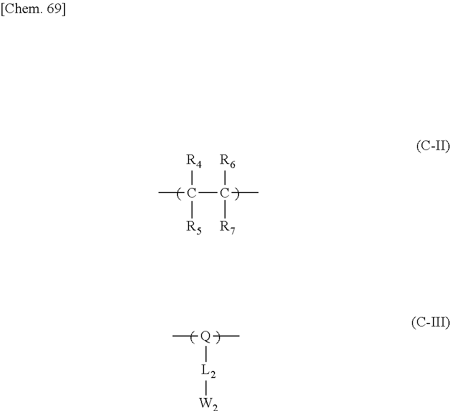

In the formula, R₄ to R₇ each independently represent a hydrogen atom, a fluorine atom, or an alkyl group. The alkyl group is preferably a linear or branched alkyl group having 1 to 4 carbon atoms, may have a substituent, and the alkyl group having a substituent may particularly include a fluorinated alkyl group.

However, at least one of R₄ to R₇ represents a fluorine atom. R₄ and R₅ or R₆ and R₇ may form a ring.

W₂ represents an organic group containing at least one fluorine atom. Specifically, an atomic group of (F2) to (F4) may be included.

L₂ represents a single bond or a divalent linking group. The divalent linking group may be a substituted or unsubstituted arylene group, a substituted or unsubstituted alkylene group, a substituted or unsubstituted cycloalkylene group, —O—, —SO₂—, —CO—, —N(R)— (in the formula, R represents a hydrogen atom or an alkyl group), —NHSO₂— or a divalent linking group combining a plurality of these.

Q represents an alicyclic structure. The alicyclic structure may have a substituent, be a monocyclic type, or a polycyclic type, and may be a bridge type in case of a polycyclic type. The monocyclic type is preferably a cycloalkyl group having 3 to 8 carbon atoms, and may include, for example, a cyclopentyl group, a cyclohexyl group, a cyclobutyl group, a cyclooctyl group or the like. The polycyclic type may include a group having a bicyclo structure, a tricyclo structure, a tetracyclo structure, or the like, having 5 or more carbon atoms, is preferably a cycloalkyl group having 6 to 20 carbon atoms, and may include, for example, an adamantyl group, a norbornyl group, a dicyclopentyl group, a tricyclodecanyl group, a tetracyclododecyl group, or the like. In addition, at least one carbon atom in the cycloalkyl group may be substituted with a hetero atom such as an oxygen atom. The particularly preferable Q may include a norbornyl group, a tricyclodecanyl group, a tetracyclododecyl group, or the like.

The hydrophobic resin may also contain a silicon atom.

As the partial structure having a silicon atom, a resin having an alkylsilyl structure (preferably a trialkylsilyl group) or a cyclic siloxane structure is preferable.

The alkylsilyl structure or the cyclic siloxane structure may include, specifically, a group represented by the following General Formulae (CS-1) to (CS-3).

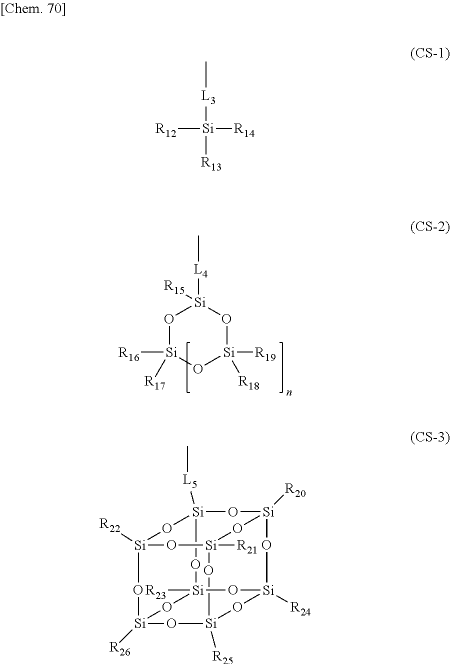

In General Formulae (CS-1) to (CS-3), R₁₂ to R₂₆ each independently represent a linear or branched alkyl group (preferably 1 to 20 carbon atoms) or a cycloalkyl group (preferably 3 to 20 carbon atoms).

L₃ to L₅ represent a single bond or a divalent linking group. As the divalent linking group, a single group or a combination of two or more selected from the group consisting of an alkylene group, a phenylene group, an ether bond, a thioether bond, a carbonyl group, an ester bond, an amide bond, a urethane bond or a ureylene bond, may be included.

n represents an integer of 1 to 5. n is preferably an integer of 2 to 4.

The repeating unit having at least any of a fluorine atom or a silicon atom is preferably a (meth)acrylate-based repeating unit.

Specific examples of the repeating unit having at least any of a fluorine atom or a silicon atom are shown below, however, the present invention is not limited to these. In addition, in the specific examples, X₁ represents a hydrogen atom, —CH₃, —F or —CF₃, and X₂ represents —F or —CF₃.

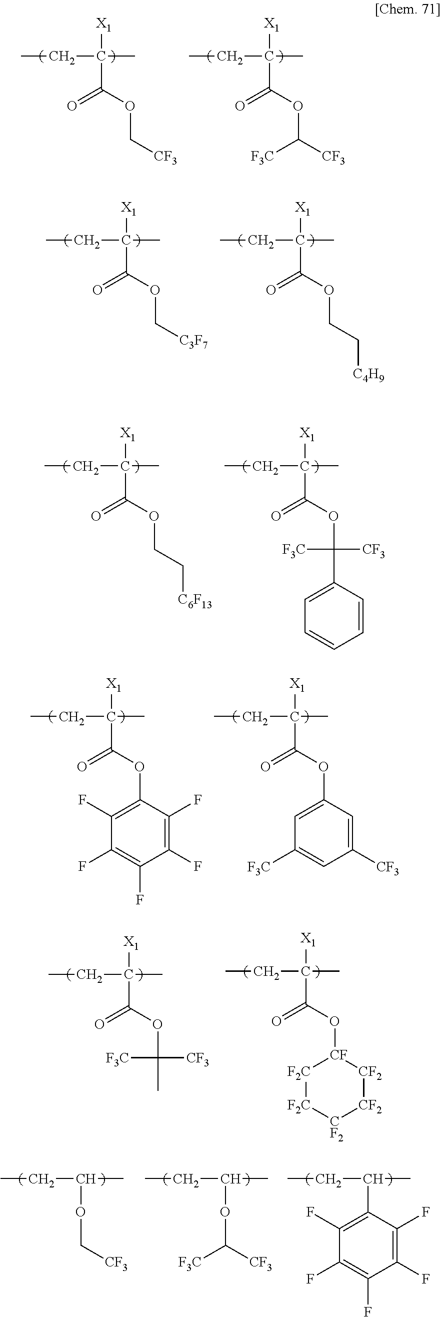

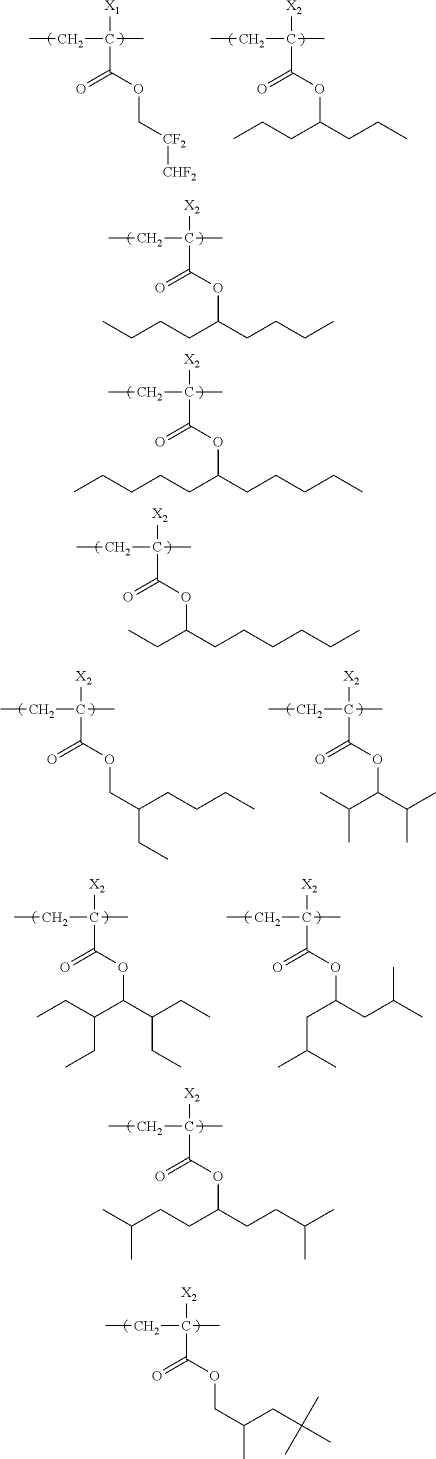

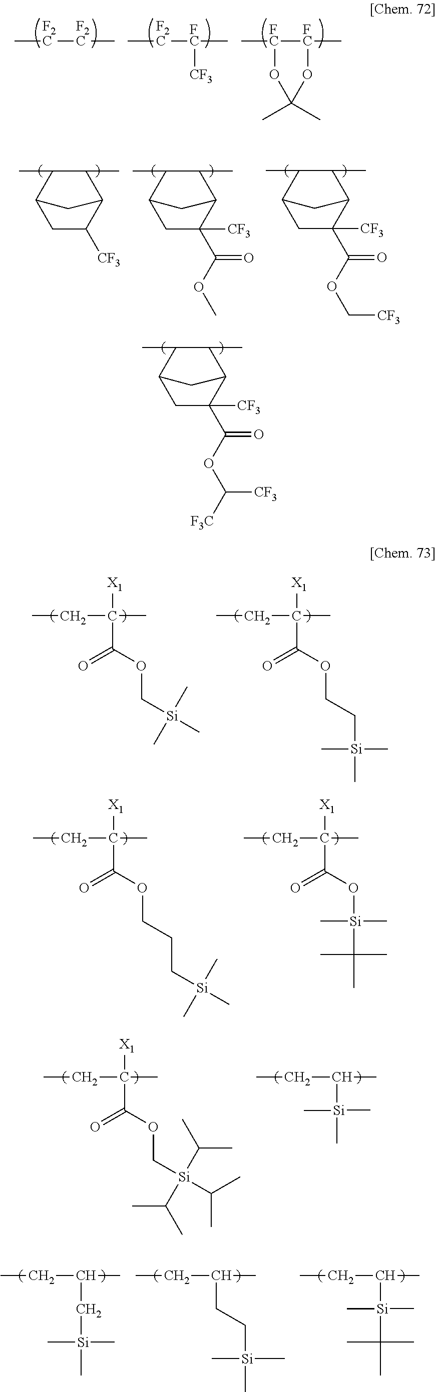

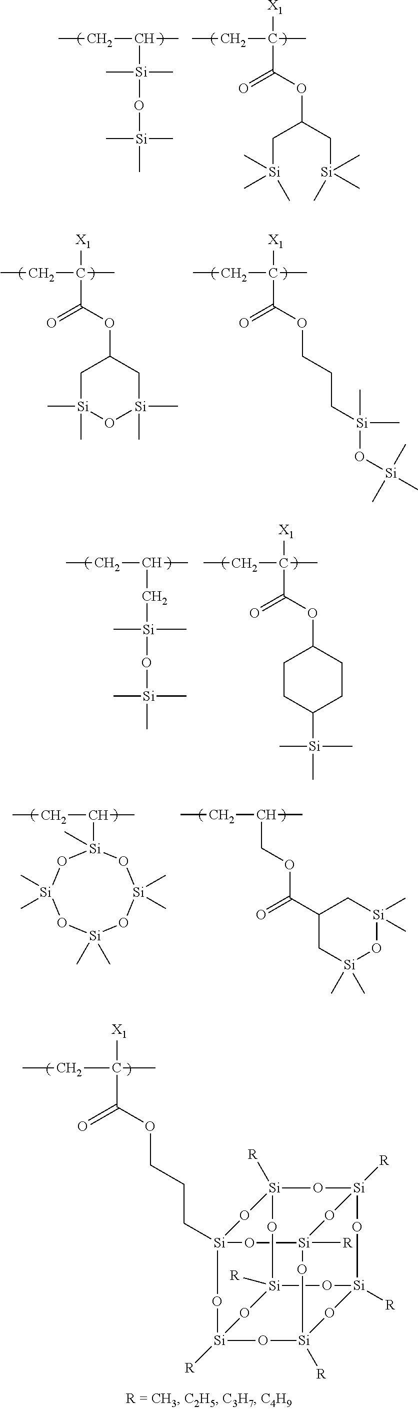

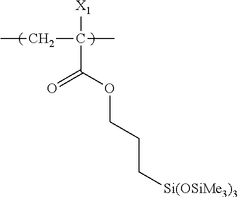

Furthermore, the hydrophobic resin may contain a repeating unit (b) having at least one group selected from the group consisting of the following (x) to (z).

(x) an alkali-soluble group
(y) a group of which solubility in an alkali developer is increased by being decomposed by the action of an alkali developer (hereinafter, also referred to as a polarity conversion group)
(z) a group of which solubility in an alkali developer is increased by being decomposed by the action of an acid

The repeating unit (b) may include the following types.
A repeating unit (b′) which has at least any of a fluorine atom and a silicon atom on one side chain, and at least one group selected from the group consisting of the above (x) to (z)
A repeating unit (b*) which has at least one group selected from the group consisting of the above (x) to (z), and does not have a fluorine atom and a silicon atom
A repeating unit (b″) which has at least one group selected from the group consisting of the above (x) to (z) on one side chain, and has at least any of a fluorine atom and a silicon atom on a side chain different from the above side chain within the same repeating unit The hydrophobic resin preferably has the repeating unit (b′) as the repeating unit (b). That is, it is more preferable that the repeating unit (b) having at least one group selected from the group consisting of the above (x) to (z) have at least any of a fluorine atom and a silicon atom.

Furthermore, when the hydrophobic resin has the repeating unit (b*), a copolymer with a repeating unit which has at least any of a fluorine atom and a silicon atom (a repeating unit different from the above repeating units (b′) and (b″)) is preferable. In addition, in the repeating unit (b″), the side chain having at least one group selected from the group consisting of the above (x) to (z), and the side chain having at least any of a fluorine atom and a silicon atom are bonded to the same carbon atom in the main chain. That is, a positional relation such as the following Formula (K1) is preferable.

In the formula, B1 represents a partial structure having at least one group selected from the group consisting of the above (x) to (z), and B2 represents a partial structure having at least any of a fluorine atom and a silicon atom.

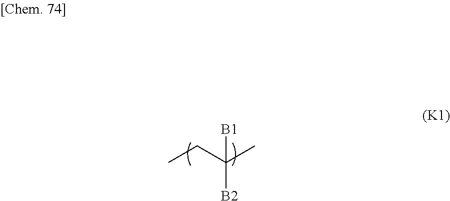

The group selected from the group consisting of the above (x) to (z) is preferably (x) the alkali-soluble group or (y) the polarity conversion group, and more preferably (y) the polarity conversion group.

The alkali-soluble group (x) may include a phenolic hydroxyl group, a carboxylate group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, a tris(alkylsulfonyl)methylene group or the like.

The preferable alkali-soluble group may include a fluorinated alcohol group (preferably hexafluoroisopropanol), a sulfonimide group, and a bis(carbonyl)methylene group.

As the repeating unit (bx) having an alkali-soluble group (x), a repeating unit in which the alkali-soluble group is bonded directly to the main chain of the resin such as a repeating unit of acrylic acid or methacrylic acid, a repeating unit in which the alkali-soluble group is bonded to the main chain of the resin through a linking group, or the like, may be included, or introducing the repeating unit to the end of the polymer chain using a polymerization initiator or a chain transfer agent having an alkali-soluble group when polymerized is also possible, and any of these cases is preferable.

When the repeating unit (bx) is a repeating unit having at least any of a fluorine atom and a silicon atom (that is, when corresponding to the repeating unit (b′) or (b″)), the partial structure having a fluorine atom in the repeating unit (bx) may include the same structure included in the above repeating unit having at least any of a fluorine atom and a silicon atom, and preferably include a group represented by General Formulae (F2) to (F4). Furthermore, in this case, the partial structure having a silicon atom in the repeating unit (bx) may include the same structure included in the above repeating unit having at least any of a fluorine atom and a silicon atom, and preferably include a group represented by General Formulae (CS-1) to (CS-3).

The content of the repeating unit (bx) having an alkali-soluble group (x) is preferably 1 to 50 mol %, more preferably 3 to 35 mol %, and even more preferably 5 to 20 mol % with regard to all repeating units in the hydrophobic resin.

Specific examples of the repeating unit (bx) having an alkali-soluble group (x) are shown below, however, the present invention is not limited to these. In addition, in the specific examples, X₁ represents a hydrogen atom, —CH₃, —F, or —CF₃.

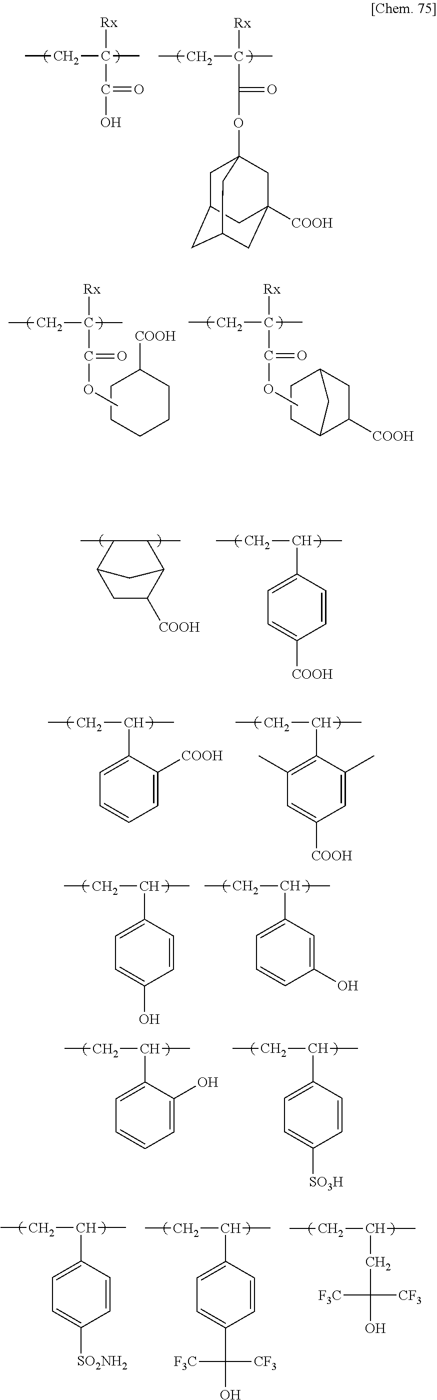

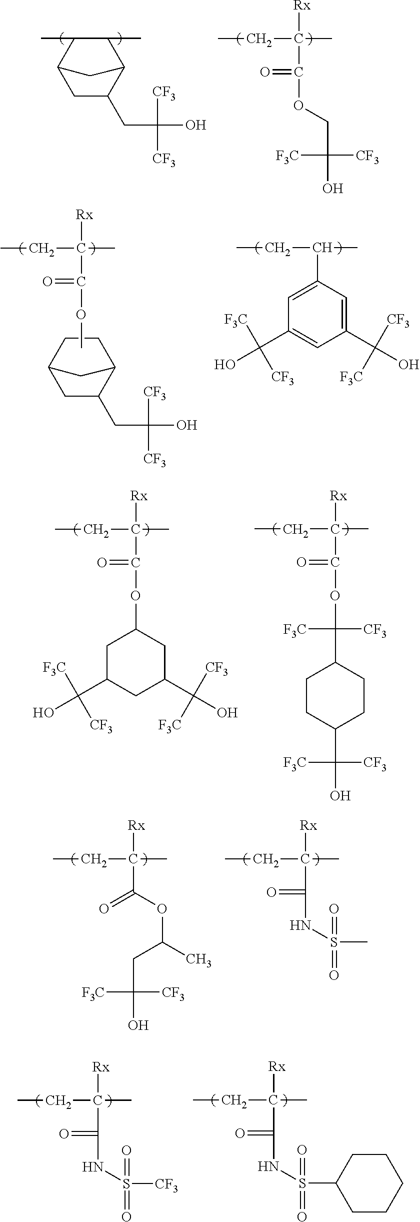

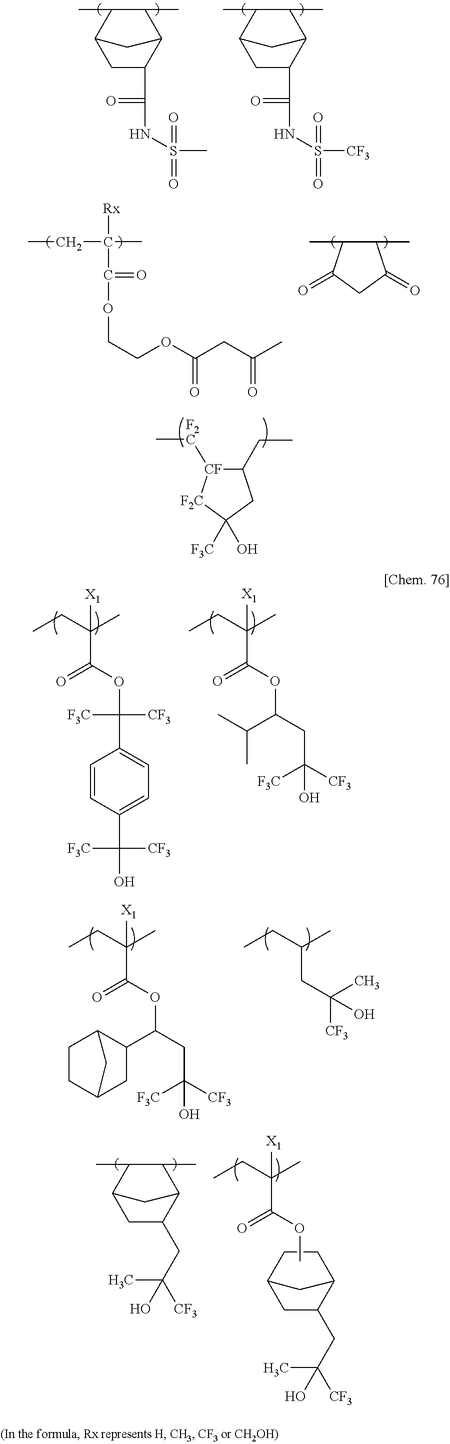

Examples of the polarity conversion group (y) include a lactone group, a carboxylate group (—COO—), an acid anhydride group (—C(O)OC(O)—), an acid imide group (—NHCONH—), a thiocarboxylate group (—COS—), a carbonate group (—OC(O)O—), a sulfate group (—OSO₂O—), a sulfonate group (—SO₂O—) or the like, and is preferably a lactone group.

The polarity conversion group (y) is preferably, for example, introduced to the side chain of the resin by being included in the repeating unit composed of an acrylate or a methacrylate, or introduced to the end of the polymer chain using a polymerization initiator or a chain transfer agent having a polarity conversion group (y) when polymerized.

Specific examples of the repeating unit (by) having a polarity conversion group (y) include a repeating unit having a lactone structure represented by Formulae (KA-1-1) to (KA-1-17).

The repeating unit (by) having a polarity conversion group (y) is preferably a repeating unit having at least any of a fluorine atom and a silicon atom (that is, corresponding to the repeating unit (b′) or (b″)). The resin having such a repeating unit (by) has hydrophobicity, but is preferable in terms of the reduction of development defects, in particular.

Examples of the repeating unit (by) include a repeating unit represented by Formula (K0).

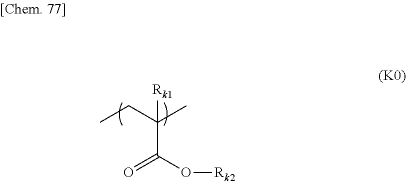

In the formula, Rₖ₁ represents a hydrogen atom, a halogen atom, a hydroxyl group, an alkyl group, a cycloalkyl group, an aryl group or a group including a polarity conversion group.

Rₖ₂ represents an alkyl group, a cycloalkyl group, an aryl group or a group including a polarity conversion group.

However, at least one of Rₖ₁ and Rₖ₂ represents a group including a polarity conversion group.

The polarity conversion group, as described above, represents a group of which solubility in an alkali developer is increased by being decomposed by the action of an alkali developer. The polarity conversion group is preferably a group represented by X in the partial structure represented by General Formula (KA-1) or (KB-1).

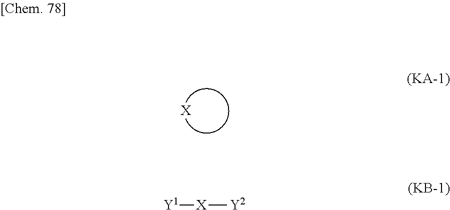

X in General Formula (KA-1) or (KB-1) represents a carboxylate group: —COO—, an acid anhydride group: —C(O)OC(O)—, an acid imide group: —NHCONH—, a thiocarboxylate group: —COS—, a carbonate group: —OC(O)O—, a sulfate group: —OSO₂O—, a sulfonate group: —SO₂O—.

Y¹ and Y² may be the same as or different from each other, and represent an electron-withdrawing group.

In addition, the repeating unit (by) preferably has a group of which solubility in an alkali developer is increased due to inclusion of a partial structure represented by General Formula (KA-1) or (KB-1), but when that partial structure does not have a bond such as a partial structure represented by General Formula (KA-1) or a partial structure represented by General Formula (KB-1) when Y¹ and Y² are monovalent, the group having that partial structure is a group having a monovalent or higher group excluding at least one arbitrary hydrogen atom in that partial structure.

The partial structure represented by General Formula (KA-1) or (KB-1) is bonded to the main chain of the hydrophobic resin through a substituent at an arbitrary position.

The partial structure represented by General Formula (KA-1) is a structure which forms a ring structure with the group as X.

The X in General Formula (KA-1) is preferably a carboxylate group (that is, a case in which a lactone ring structure is formed as KA-1), an acid anhydride group and a carbonate group, and more preferably a carboxylate group.

The ring structure represented by General Formula (KA-1) may have a substituent, and for example, may have an nka number of substituents Zₖₐ₁.

Zₖₐ₁s, when present in plural number, each independently represent a halogen atom, an alkyl group, a cycloalkyl group, an ether group, a hydroxyl group, an amide group, an aryl group, a lactone ring group, or an electron-withdrawing group.

Zₖₐ₁s may be bonded to each other to form a ring. Examples of the ring formed by Zₖₐ₁s being bonded to each other include a cycloalkyl ring or a heteroring (a cyclic ether ring, a lactone ring, or the like).

nka represents an integer of 0 to 10. nka is preferably an integer of 0 to 8, more preferably an integer of 0 to 5, even more preferably an integer of 1 to 4, and most preferably an integer of 1 to 3.

The electron-withdrawing group as Zₖₐ₁ is the same electron-withdrawing group as Y¹ and Y² described later. In addition, other electron-withdrawing groups may be substituted on the above electron-withdrawing group.

Zₖₐ₁ is preferably an alkyl group, a cycloalkyl group, an ether group, a hydroxyl group or an electron-withdrawing group and more preferably an alkyl group, a cycloalkyl group or an electron-withdrawing group. In addition, the ether group is preferably an ether group substituted with an alkyl group or cycloalkyl group and the like, that is, an alkyl ether group or the like. The electron-withdrawing group is synonymous with the above electron-withdrawing group.

The halogen atom as Zₖₐ₁ may include a fluorine atom, a chlorine atom, a bromine atom, an iodine atom, and the like, and is preferably a fluorine atom.

The alkyl group as Zₖₐ₁ may have a substituent, and may be either linear or branched. The linear alkyl group is preferably an alkyl group having 1 to 30 carbon atoms, and more preferably an alkyl group having 1 to 20 carbon atoms, and includes, for example, a methyl group, an ethyl group, an n-propyl group, an n-butyl group, a sec-butyl group, a t-butyl group, an n-pentyl group, an n-hexyl group, an n-heptyl group, an n-octyl group, an n-nonyl group, an n-decanyl group, or the like. The branched alkyl group is preferably an alkyl group having 3 to 30 carbon atoms, and more preferably an alkyl group having 3 to 20 carbon atoms, and includes, for example, an i-propyl group, an i-butyl group, a t-butyl group, an i-pentyl group, a t-pentyl group, an i-hexyl group, a t-hexyl group, an i-heptyl group, a t-heptyl group, an i-octyl group, a t-octyl group, an i-nonyl group, a t-decanyl group, or the like. An alkyl group having 1 to 4 carbon atoms such as a methyl group, an ethyl group, an n-propyl group, an i-propyl group, an n-butyl group, an i-butyl group or a t-butyl group is preferable.

The cycloalkyl group as Zₖₐ₁ may have a substituent, and may be either monocyclic or polycyclic. In the case of being polycyclic, the cycloalkyl group may be a bridged type. That is, in this case, the cycloalkyl group may have a crosslinked structure. The monocyclic cycloalkyl group is preferably a cycloalkyl group having 3 to 8 carbon atoms, and includes, for example, a cyclopropyl group, a cyclopentyl group, a cyclohexyl group, a cyclobutyl group, a cyclooctyl group or the like. The polycyclic cycloalkyl group may include a group having a bicyclo, tricyclo or tetracyclo structure having 5 or more carbon atoms, is preferably a cycloalkyl group having 6 to 20 carbon atoms, and includes, for example, an adamantyl group, a norbornyl group, an isobornyl group, a camphanyl group, a dicyclopentyl group, an α-pinel group, a tricyclodecanyl group, a tetracyclodecanyl group or an androstannyl group. The following structures are also preferable as the cycloalkyl group. Furthermore, at least one carbon atom in the cycloalkyl group may be substituted with a heteroatom such as an oxygen atom.

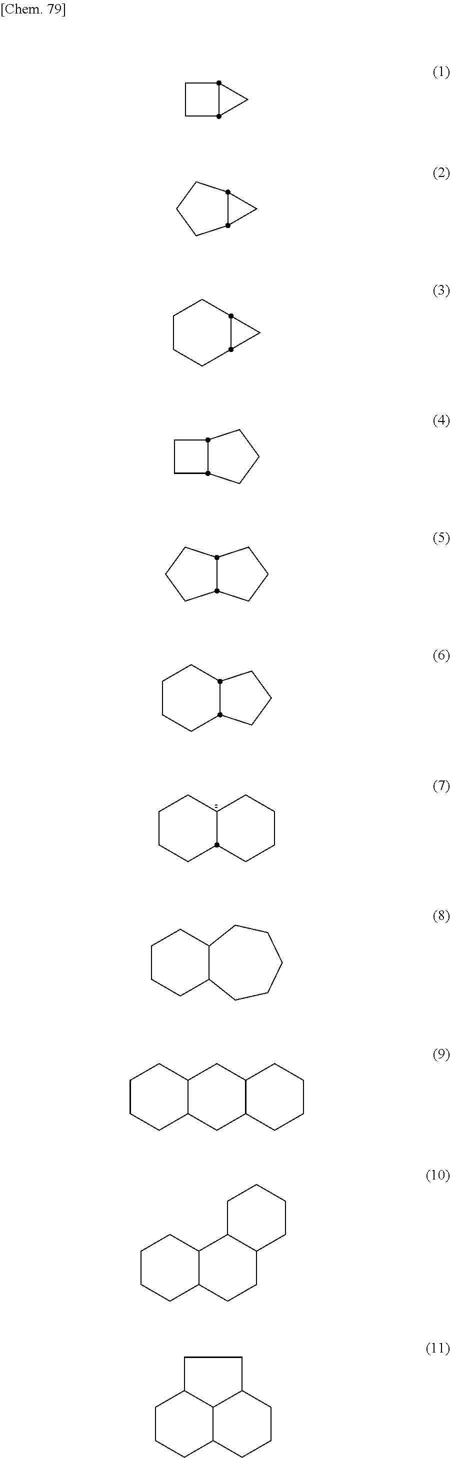

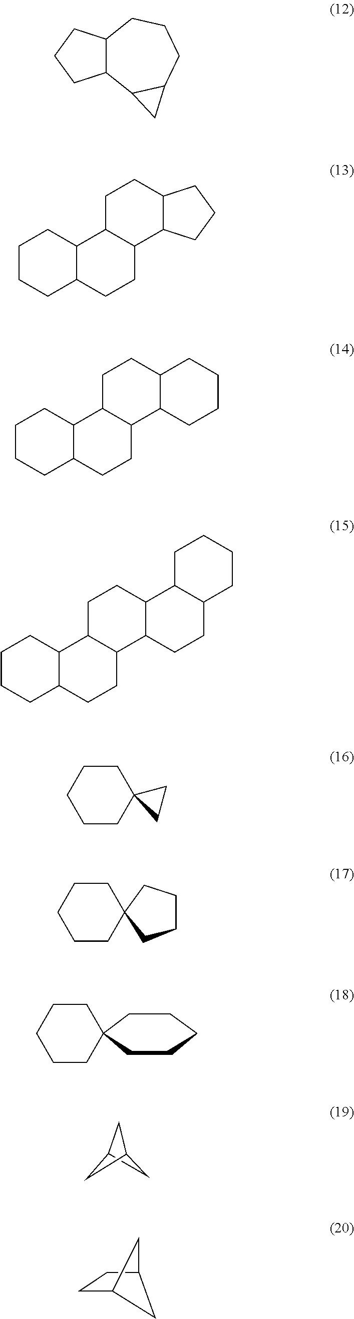

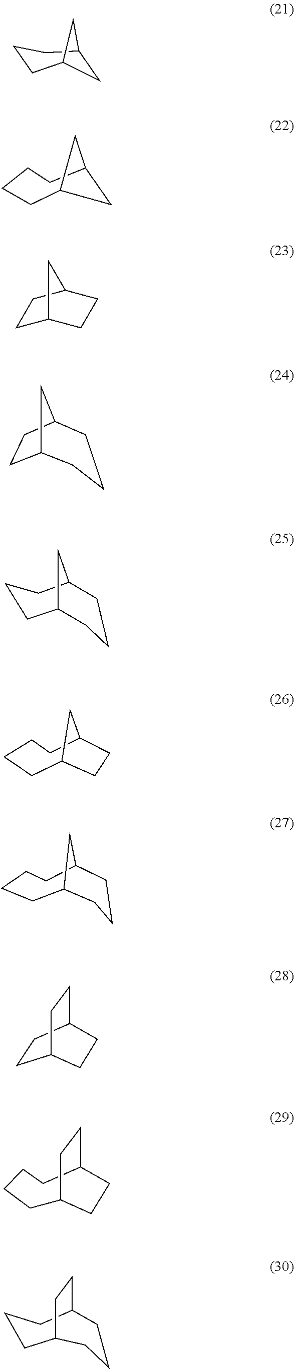

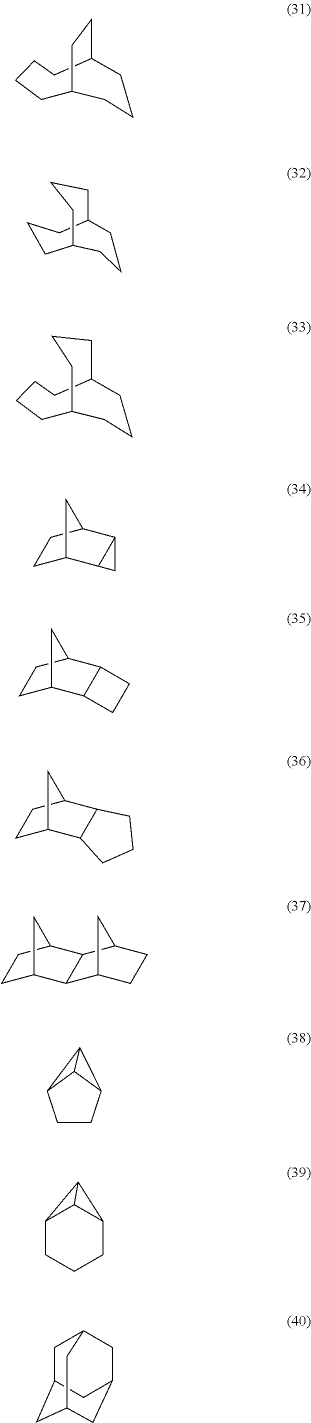

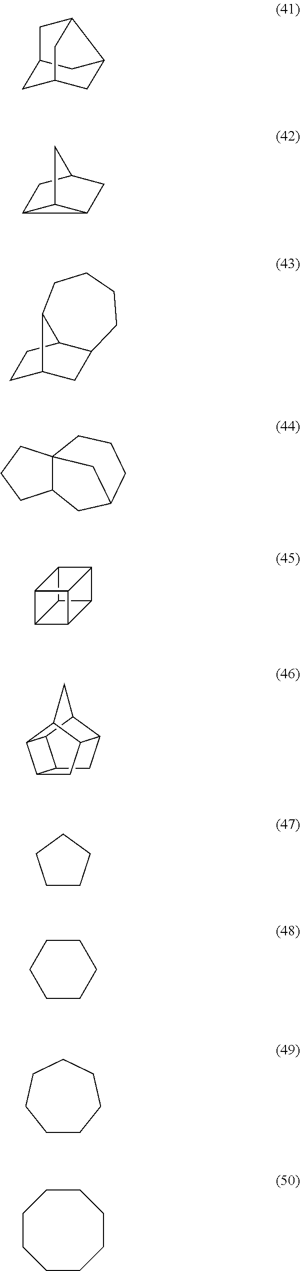

The preferable alicyclic portion may include an adamantyl group, a noradamantyl group, a decalin group, a tricyclodecanyl group, a tetracyclododecanyl group, a norbornyl group, a cedrol group, a cyclohexyl group, a cycloheptyl group, a cyclooctyl group, a cyclodecanyl group or a cyclododecanyl group. An adamantyl group, a decalin group, a norbornyl group, a cedrol group, a cyclohexyl group, a cycloheptyl group, a cyclooctyl group, a cyclodecanyl group, a cyclododecanyl group or a tricyclodecanyl group is more preferable.

The substituent of these alicyclic structures may include an alkyl group, a halogen atom, a hydroxyl group, an alkoxy group, a carboxyl group or an alkoxycarbonyl group. The alkyl group is preferably a lower alkyl group such as a methyl group, an ethyl group, a propyl group, an isopropyl group or a butyl group, and more preferably represents a methyl group, an ethyl group, a propyl group, an isopropyl group. The alkoxy group described above may preferably include an alkoxy group having 1 to 4 carbon atoms such as a methoxy group, an ethoxy group, a propoxy group, a butoxy group. The substituent which the alkyl group and the alkoxy group may have includes a hydroxyl group, a halogen atom, an alkoxy group (preferably having 1 to 4 carbon atoms), or the like.

In addition, the above group may further have a substituent, and the substituent may include a hydroxyl group, a halogen atom (fluorine, chlorine, bromine, iodine), a nitro group, a cyano group, the alkyl group described above, an alkoxy group such as a methoxy group, an ethoxy group, a hydroxyethoxy group, a propoxy group, a hydroxypropoxy group, an n-butoxy group, an isobutoxy group, a sec-butoxy group or a t-butoxy group, an alkoxycarbonyl group such as a methoxycarbonyl group or an ethoxycarbonyl group, an aralkyl group such as a benzyl group, a phenethyl group or a cumyl group, an aralkyloxy group, an acyl group such as a formyl group, an acetyl group, a butyryl group, a benzoyl group, a cyanamyl group or a valeryl group, an acyloxy group such as a butyryloxy group, an alkenyl group such as a vinyl group, a propenyl group or an allyl group, an alkenyloxy group such as a vinyloxy group, a propenyloxy group, an allyloxy group or a butenyloxy group, an aryl group such as a phenyl group or a naphthyl group, an aryloxy group such as a phenoxy group, an aryloxycarbonyl group such as a benzoyloxy group, or the like.

It is preferable that X in General Formula (KA-1) be a carboxylate group, and the partial structure represented by General Formula (KA-1) be a lactone ring and be a 5- to 7-membered lactone ring.

In addition, as in the following (KA-1-1) to (KA-1-17), it is preferable that other ring structure be condensed to a lactone ring having a 5- to 7-membered ring represented by General Formula (KA-1) in a way to form a bicyclo structure or a spiro structure.

The surrounding ring structures to which the ring structure represented by General Formula (KA-1) may be bonded may include those in the following (KA-1-1) to (KA-1-17), or those conforming with these.

The structure containing a lactone ring structure represented by General Formula (KA-1) is more preferably a structure represented by any of the following (KA-1-1) to (KA-1-17). In addition, the lactone structure may be bonded directly to a main chain. The preferable structures are (KA-1-1), (KA-1-4), (KA-1-5), (KA-1-6), (KA-1-13), (KA-1-14) and (KA-1-17).

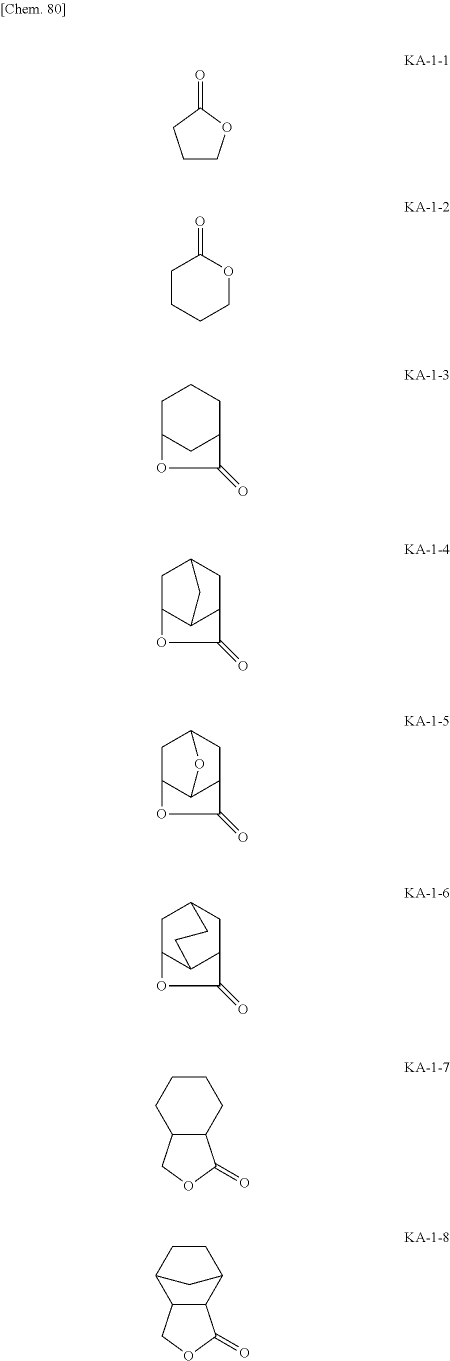

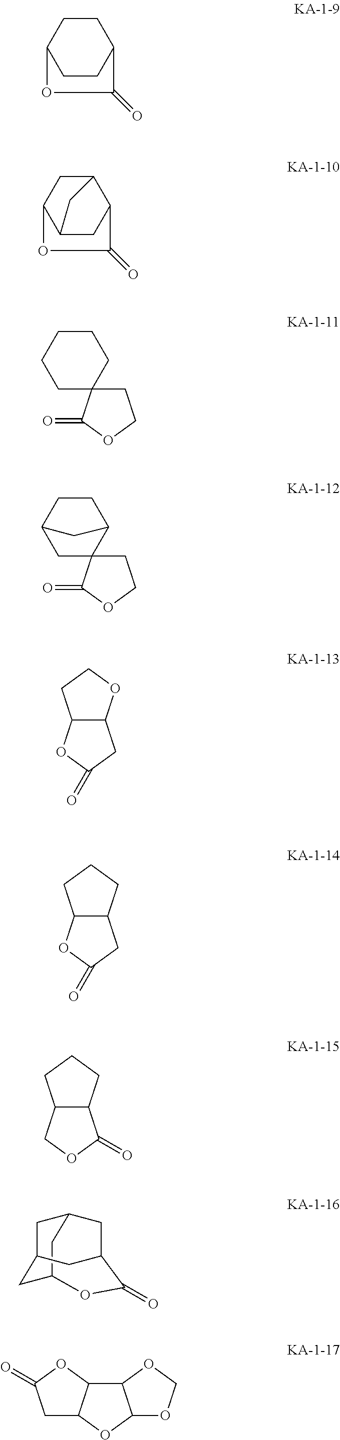

The structure containing the above lactone ring structure may or may have a substituent.

The preferable substituent may include the same substituent as the substituent Zₖₐ₁ which the ring structure represented by General Formula (KA-1) may have.

X in General Formula (KB-1) may preferably include a carboxylate group (—COO—). Y¹ and Y² in General Formula (KB-1) each independently represent an electron-withdrawing group.

The electron-withdrawing group is a partial structure represented by the following Formula (EW). * in Formula (EW) represents a bond directly connected to (KA-1) or a bond directly connected to X in (KB-1).

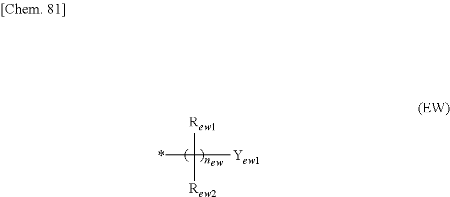

In Formula (EW), R_{ew1} and R_{ew2} each independently represent an arbitrary substituent, and represent, for example, a hydrogen atom, an alkyl group, a cycloalkyl group or an aryl group.

n_{ew} is the number of repetitions of the linking group represented by —C(R_{ew1})(R_{ew2})—, and represents an integer of 0 or 1. When n_{ew} is 0, it represents a single bond, and indicates that Y_{ew1} is bonded directly.

Y_{ew1} may include a halogen atom, a cyano group, a nitrile group, a nitro group, a halo(cyclo)alkyl group or haloaryl group represented by —C(R_{f1})(R_{f2})—R_{f3}, an oxy group, a carbonyl group, a sulfonyl group, a sulfinyl group or a combination thereof, and the electron-withdrawing group may be, for example, the following structure. The term “a halo(cyclo)alkyl group” represents an alkyl group and an at least partially halogenated cycloalkyl group, and the group “a haloaryl group” represents an at least partially halogenated aryl group. In the following structural formulae, R_{ew3} and R_{ew4} each independently represent an arbitrary structure. The partial structure represented by the formula (EW) has an electron-withdrawing property regardless of the structure R_{ew3} and R_{ew4} has, and, for example, may be connected to the main chain of the resin, but is preferably an alkyl group, a cycloalkyl group or a fluorinated alkyl group.

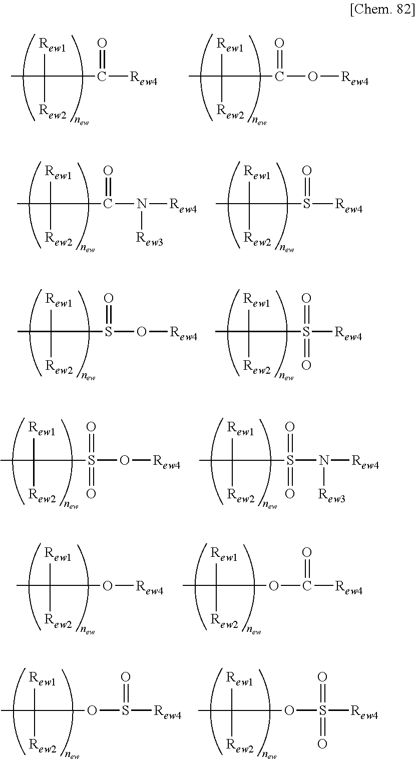

When Y_{ew1} is a divalent or higher group, the remaining bond forms a bond with an arbitrary atom or a substituent. At least any group of Y_{ew1}, R_{ew1} and R_{ew2} may be further connected to the main chain of the hydrophobic resin through a substituent.

Y_{ew1} is preferably a halogen atom, or a halo(cyclo)alkyl group or haloaryl group represented by —C(R_{f1})(R_{f2})—R_{f3}.

At least two of R_{ew1}, R_{ew2} and Y_{ew1} may be bonded to each other to form a ring.

Here, R_{f1} represents a halogen atom, a perhaloalkyl group, a perhalocycloalkyl group or a perhalo aryl group, more preferably represents a fluorine atom, a perfluoroalkyl group or a perfluorocycloalkyl group, and even more preferably a fluorine atom or a trifluoromethyl group.

R_{f2} and R_{f3} each independently represent a hydrogen atom, a halogen atom or an organic group, and R_{f2} and R_{f3} may be bonded to each other to form a ring. The organic group represents, for example, an alkyl group, a cycloalkyl group, an alkoxy group or the like. It is more preferable that R_{f2} represent the same group as R_{f1}, or be bonded to R_{f3} to form a ring.

R_{f1} to R_{f3} may be bonded to each other to form a ring and the ring formed may include a (halo)cycloalkyl ring, a (halo)aryl ring, or the like.

Examples of the (halo)alkyl group in R_{f1} to R_{f3} include an alkyl group in Zₖₐ₁ described above, and a structure in which this is halogenated.

Examples of the (per)halocycloalkyl group and the (per)haloaryl group in R_{f1} to R_{f3}, or in the ring formed by R_{f2} and R_{f3} being bonded include a structure in which the cycloalkyl group in Zₖₐ₁ described above is halogenated, more preferably include a fluorocycloalkyl group represented by —C₍ₙ₎F₍₂ₙ₋ₙ₎H and a perfluoroaryl group represented by —C₍ₙ₎F₍ₙ₋₁₎. Here, the number of carbon atoms n is not particularly limited, however, 5 to 13 is preferable, and 6 is more preferable.

The ring which may be formed by at least two of R_{ew1}, R_{ew2} and Y_{ew1} being bonded may preferably include a cycloalkyl group or a heteroring group, and a lactone ring group is preferable as the heteroring group. Examples of the lactone ring group include a structure represented by the above Formulae (KA-1-1) to (KA-1-17).

Furthermore, the repeating unit (by) may have a plurality of partial structures represented by General Formula (KA-1), or a plurality of partial structures represented by General Formula (KB-1), or both partial structures represented by General Formula (KA-1) or General Formula (KB-1).

In addition, the portion of or the whole partial structure of General Formula (KA-1) may also serve as an electron-withdrawing group as Y¹ or Y² in General Formula (KB-1). For example, when X in General Formula (KA-1) is a carboxylate group, that carboxylate group may also function as an electron-withdrawing group as Y¹ or Y² in General Formula (KB-1).

Furthermore, when the repeating unit (by) corresponds to the repeating unit (b*) or the repeating unit (b″) and has a partial structure represented by General Formula (KA-1), the partial structure represented by General Formula (KA-1) is more preferably a partial structure in which a polarity conversion group is represented by —COO— in the structure represented by General Formula (KA-1).

The repeating unit (by) may be a repeating unit having a partial structure represented by General Formula (KY-0).

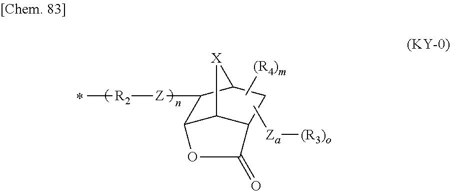

In General Formula (KY-0), R₂ represents a chain or cyclic alkylene group, and R₂s may be the same as or different from each other when present in plural number.

R₃ represents a linear, branched or cyclic hydrocarbon group, and a part or all of the hydrogen atoms on the constituent carbon atoms are substituted with a fluorine atom.

R₄ represents a halogen atom, a cyano group, a hydroxy group, an amide group, an alkyl group, a cycloalkyl group, an alkoxy group, a phenyl group, an acyl group, an alkoxycarbonyl group or a group represented by R—C(═O)— or R—C(═O)O— (R represents an alkyl group or a cycloalkyl group). When R₄ is present in plural number, they may be the same as or different from each other, and two or more of R₄ may be bonded to each other to form a ring.

X represents an alkylene group, an oxygen atom or a sulfur atom.

Z and Za represent a single bond, an ether bond, an ester bond, an amide bond, a urethane bond or a urea bond, and Z and Za may be the same as or different from each other when present in plural number.

* represents a bond to the main chain or side chain of the resin.

o is the number of substituents, and represents an integer of 1 to 7.

m is the number of substituents, and represents an integer of 0 to 7.

n is the number of repetitions, and represents an integer of 0 to 5.

The structure of —R₂—Z— is preferably a structure represented by —(CH₂)₁—COO— (1 represents an integer of 1 to 5).

The preferable carbon number and specific examples of the chain or cyclic alkylene group as R₂ are the same as those described in the chain alkylene group and the cyclic alkylene group in Z₂ of General Formula (bb).

The number of carbon atoms of the linear, branched or cyclic hydrocarbon group as R₃ is preferably 1 to 30 and more preferably 1 to 20 in the case of linear, preferably 3 to 30 and more preferably 3 to 20 in the case of branched, and preferably 6 to 20 in the case of cyclic. Specific examples of R₃ may include the specific examples of the alkyl group and the cycloalkyl groups as Zₖₐ₁ described above.

The preferable carbon number ranges and specific examples of the alkyl group and the cycloalkyl group as R₄ and R are the same as those described in the alkyl group and the cycloalkyl group as Zₖₐ₁ described above.

The acyl group as R₄ is preferably an acyl group having 1 to 6 carbon atoms and may include, for example, a formyl group, an acetyl group, a propionyl group, a butyryl group, an isobutyryl group, a valeryl group, a pivaloyl group or the like.

The alkyl moiety in the alkoxy group and the alkoxycarbonyl group as R₄ may include a linear, branched or cyclic alkyl moiety, and the preferable carbon number and specific examples of the alkyl moiety are the same as those described in the alkyl group and the cycloalkyl groups as Zₖₐ₁ described above.

The alkylene group as X may include a chain or cyclic alkylene group, and preferable carbon number and specific examples are the same as those described in the chain alkylene group and the cyclic alkylene group as R₂.

A receding contact angle of the resist film with water after alkali development can be lowered due to a polarity conversion by the polarity conversion group being decomposed by the action of an alkaline developer. The receding contact angle of the film with water being decreased after the alkali development is preferable from the viewpoint of the suppression of development defects.

The receding contact angle of the resist film with water after alkali development is preferably 50° or less at a temperature of 23±3° C. and a humidity of 45±5%, more preferably 40° or less, even more preferably 35° or less, and most preferably 35° or less.

The receding contact angle is a contact angle measured when the contact line at a droplet-substrate interface is retracted, and is generally known to be useful in simulating the ease of movement of the droplets in a dynamic state. Simply, it can be defined as a contact angle at the time of the interface of the droplet being retracted when the droplets are sucked into the needle again after the droplets discharged from the needle tip end are deposited on a substrate, and the contact angle can be measured using a contact angle measuring method generally referred to as an expansion and contraction method.

A hydrolysis rate in the alkaline developer of the hydrophobic resin is preferably 0.001 nm/second or more, more preferably 0.01 nm/second or more, even more preferably 0.1 nm/second or more, and most preferably 1 nm/second or more.

Here, the hydrolysis rate in the alkaline developer of the hydrophobic resin is a rate at which the film thickness is reduced when the resin film was formed using only the hydrophobic resin in TMAH (an aqueous solution of tetramethylammonium hydroxide) (2.38% by mass) of 23° C.

Furthermore, it is more preferable that the repeating unit (by) be a repeating unit having at least two or more polarity conversion groups.

When the repeating unit (by) has at least two polarity conversion groups, it is preferable that the repeating unit (by) have a group containing a partial structure having two polarity conversion groups represented by the following General Formula (KY-1). In addition, when the structure represented by General Formula (KY-1) does not have a bond, the structure is a group having a monovalent or higher group with at least any one hydrogen atom in the structure being removed.

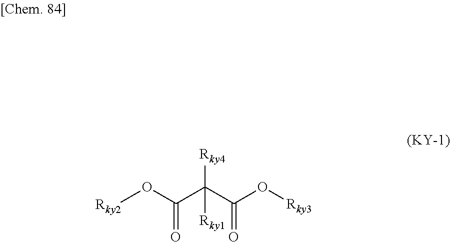

In General Formula (KY-1), R_{ky1} and R_{ky4} each independently represents a hydrogen atom, a halogen atom, an alkyl group, a cycloalkyl group, a carbonyl group, carbonyloxy group, an oxycarbonyl group, an ether group, a hydroxyl group, a cyano group, an amide group or an aryl group. R_{ky1} and R_{ky4} may be bonded to the same atom to form a double bond and, for example, R_{ky1} and R_{ky4} may be bonded to the same oxygen atom to form part of a carbonyl group (═O).

R_{ky2} and R_{ky3} each independently are an electron-withdrawing group or R_{ky3} is an electron-withdrawing group together with R_{ky1} and R_{ky2} being connected to form a lactone ring. The lactone ring formed is preferably a structure of the above (KA-1-1) to (KA-1-17). The electron-withdrawing group includes the same as Y¹ and Y² in Formula (KB-1), and preferably a halogen atom, or a halo(cyclo)alkyl group or haloaryl group represented by the above —C(R_{f1})(R_{f2})—R_{f3}. Preferably, R_{ky3} is a halogen atom, or a halo(cyclo)alkyl group or haloaryl group represented by the above —C(R_{f1})(R_{f2})—R_{f3}, and R_{ky2} forms a lactone ring by being connected to R_{ky1}, or is an electron-withdrawing group which does not have a halogen atom.

R_{ky1}, R_{ky2}, and R_{ky4} may be connected to each other to form a monocyclic or polycyclic structure.

Specifically, R_{ky1} and R_{ky4} may include the same group as Zₖₐ₁ in Formula (KA-1).

The lactone ring formed by R_{ky1} and R_{ky2} being connected is preferably a structure of the above (KA-1-1) to (KA-1-17). The electron-withdrawing group may include the same as Y¹ and Y² in Formula (KB-1).

The structure represented by General Formula (KY-1) is more preferably a structure represented by the following General Formula (KY-2). In addition, the structure represented by General Formula (KY-2) is a group having a monovalent or higher group with at least any one hydrogen atom in the structure being removed.

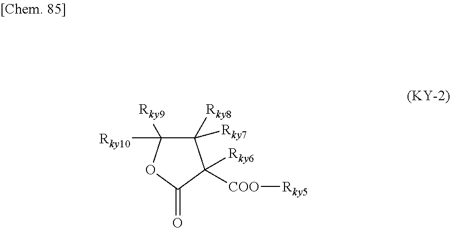

In Formula (KY-2), R_{ky6} to R_{ky10} each independently represent a hydrogen atom, a halogen atom, an alkyl group, a cycloalkyl group, a carbonyl group, a carbonyloxy group, an oxycarbonyl group, an ether group, a hydroxyl group, a cyano group, an amide group or an aryl group.

Two or more of R_{ky6} to R_{ky10} may be connected to one another to form a monocyclic or polycyclic structure.

R_{ky5} represents an electron-withdrawing group. The electron-withdrawing group may include the same as those in Y¹ and Y², and is preferably a halogen atom, or a halo(cyclo)alkyl group or haloaryl group represented by the above —C(R_{f1})(R_{f2})—R_{f3}.

Specifically, R_{ky5} to R_{ky10} may include the same group as Zₖₐ₁ in Formula (KA-1).

The structure represented by Formula (KY-2) is more preferably a partial structure represented by the following General Formula (KY-3).

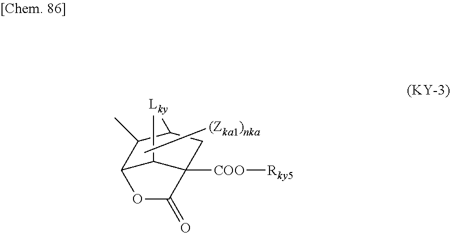

In Formula (KY-3), Zₖₐ₁ and nka are synonymous with Zₖₐ₁ and nka in General Formula (KA-1), respectively. R_{ky5} is synonymous with R_{ky5} in the above Formula (KY-2).

Lₖ represents an alkylene group, an oxygen atom or a sulfur atom. The alkylene group of L_{ky} may include a methylene group, an ethylene group or the like. L_{ky} is preferably an oxygen atom or a methylene group, and more preferably a methylene group.

The repeating unit (b) is not particularly limited as long as the repeating unit is obtained by a polymerization such as an addition polymerization, a condensation polymerization or an addition condensation, however, a repeating unit obtained by an addition polymerization of a carbon-carbon double bond is preferable. Examples thereof may include an acrylate-based repeating unit (including the system having a substituent on the α-position or the β-position), a styrene-based repeating unit (including the system having a substituent on the α-position or the β-position), a vinyl ether-based repeating unit, a norbornene-based repeating unit, a repeating unit of a maleic acid derivative (a maleic anhydride or derivative thereof, maleimide, or the like) or the like, an acrylate-based repeating unit, a styrene-based repeating unit, a vinyl ether-based repeating unit or a norbornene-based repeating unit is preferable, an acrylate-based repeating unit, a vinyl ether-based repeating unit or a norbornene-based repeating unit is more preferable, and an acrylate-based repeating unit is most preferable.

When the repeating unit (by) is a repeating unit having at least any of a fluorine atom and a silicon atom (that is, when corresponding to the repeating unit (b′) or (b″)), the partial structure having a fluorine atom in the repeating unit (by) may include the same structure included in the repeating unit having at least any of a fluorine atom and a silicon atom, and preferably include a group represented by General Formulae (F2) to (F4). Furthermore, in this case, the partial structure having a silicon atom in the repeating unit (by) may include the same structure included in the repeating unit having at least any of a fluorine atom and a silicon atom, and preferably include a group represented by General Formulae (CS-1) to (CS-3).

The content of the repeating unit (by) in the hydrophobic resin is preferably 10 to 100 mol %, more preferably 20 to 99 mol %, even more preferably 30 to 97 mol %, and most preferably 40 to 95 mol % with regard to all repeating units in the hydrophobic resin.

Specific examples of the repeating unit (by) having a group of which solubility is increased in an alkali developer are shown below, however, the present invention is not limited to these.

In the specific examples shown below, Ra represents a hydrogen atom, a fluorine atom, a methyl group or a trifluoromethyl group.

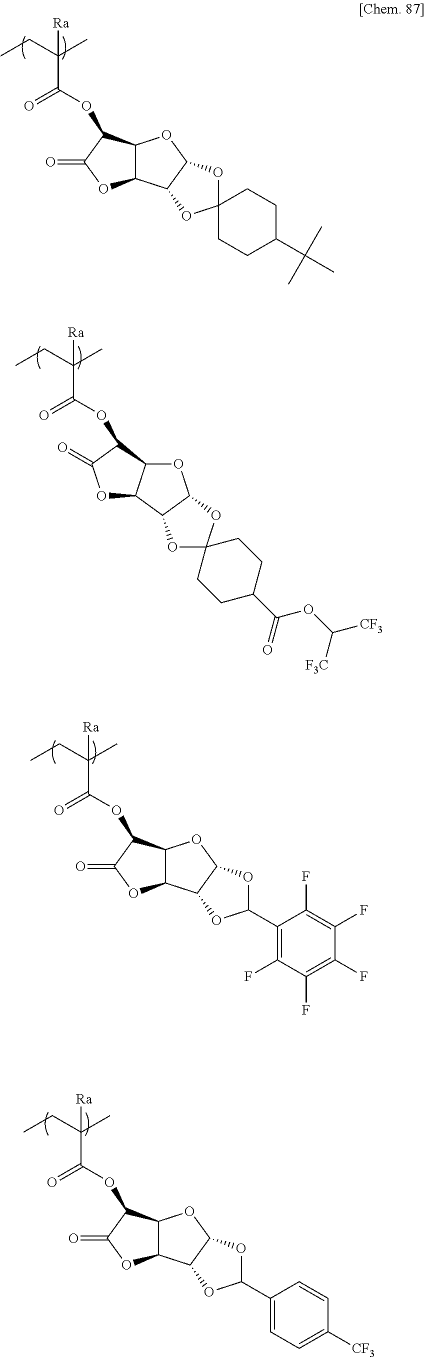

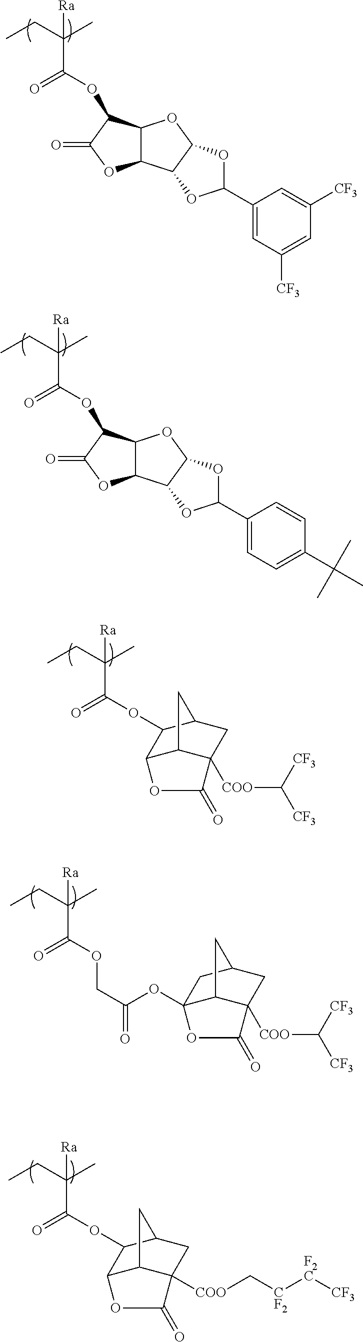

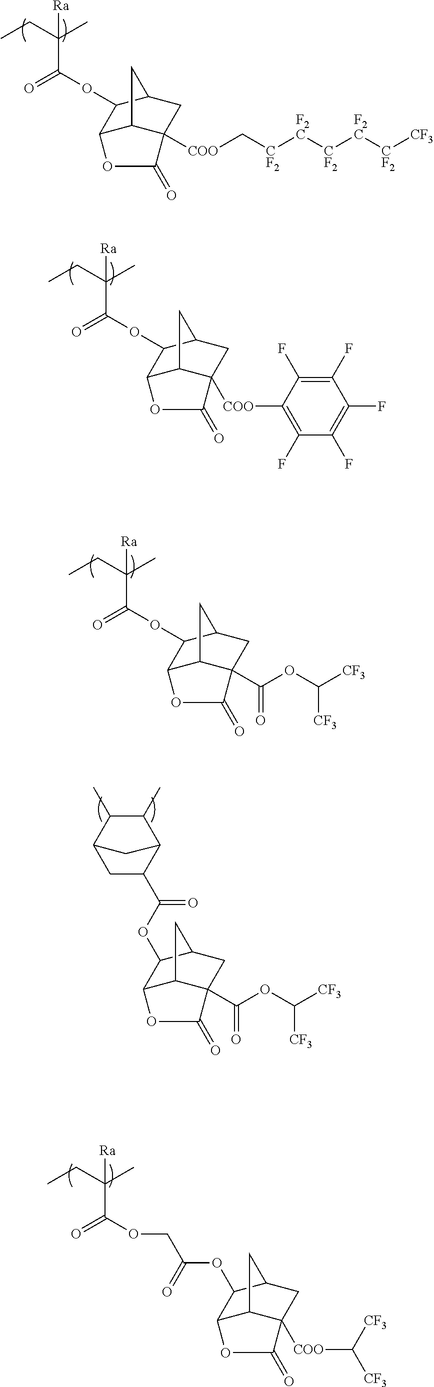

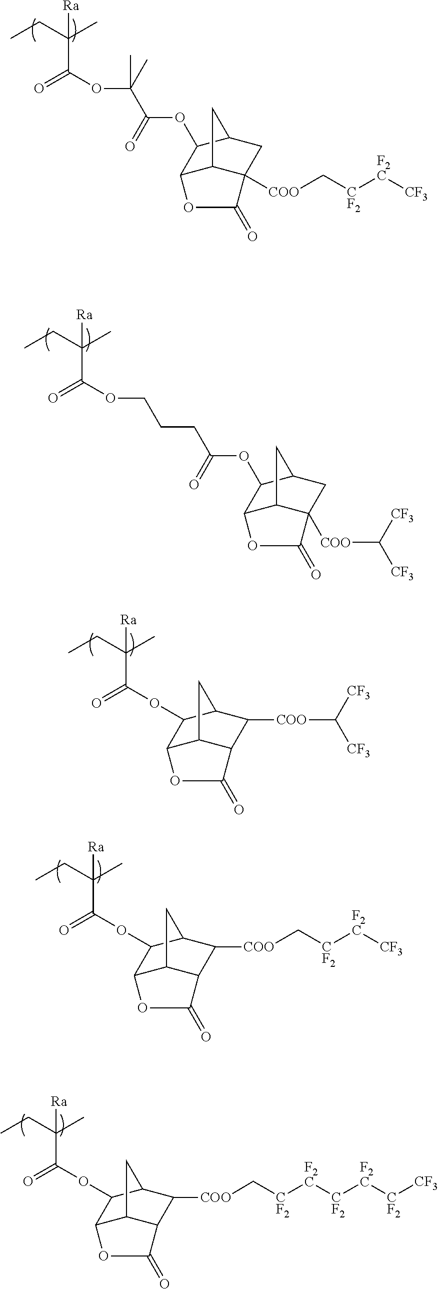

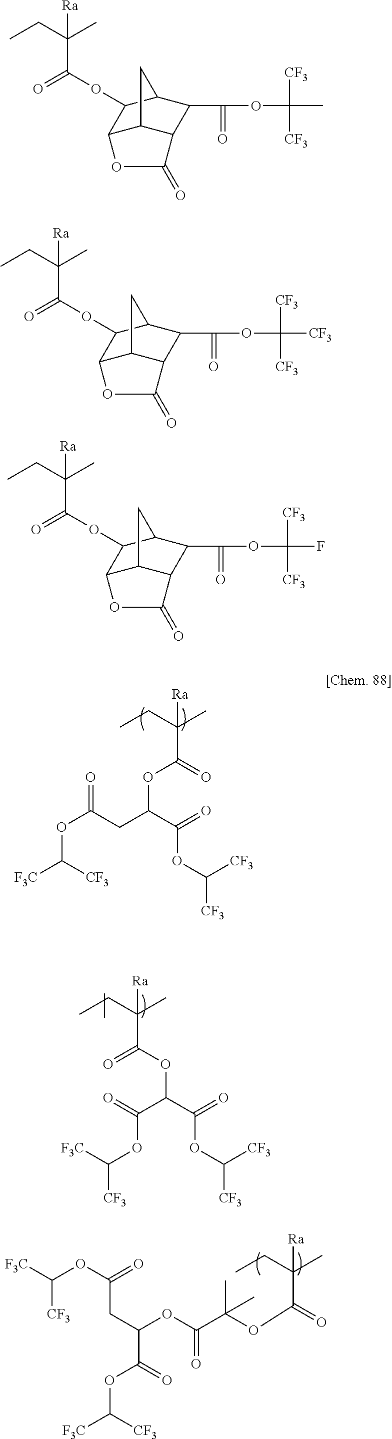

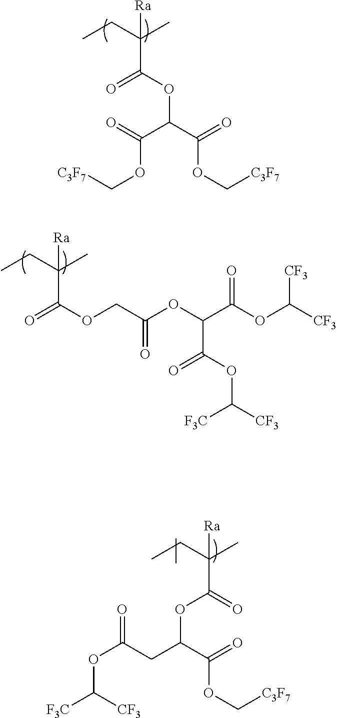

The monomers corresponding to the repeating unit (by) having a polarity conversion group (y) as described above may be synthesized with reference to, for example, a method disclosed in WO2010/067905A.

In the hydrophobic resin, the repeating unit (bz) having a group decomposed by the action of an acid (z) may include the same repeating unit having an acid decomposable group included in the resin (B).

When the repeating unit (bz) is a repeating unit having at least any of a fluorine atom and a silicon atom (that is, when corresponding to the repeating unit (b′) or (b″)), the partial structure having a fluorine atom in the repeating unit (bz) may include the same structure included in the above repeating unit having at least any of a fluorine atom and a silicon atom, and preferably include a group represented by General Formulae (F2) to (F4). Furthermore, in this case, the partial structure having a silicon atom in the repeating unit (bz) may include the same structure included in the above repeating unit having at least any of a fluorine atom and a silicon atom, and preferably include a group represented by General Formulae (CS-1) to (CS-3).

The content of the repeating unit (bz) having a group decomposed by the action of an acid (z) is preferably 1 to 80 mol %, more preferably 10 to 80 mol %, and even more preferably 20 to 60 mol % with regard to all repeating units in the hydrophobic resin.

Hereinbefore, the repeating unit (b) having at least one group selected from the group consisting of the above (x) to (z) has been described, however, in the hydrophobic resin, the content of the repeating unit (b) is preferably 1 to 98 mol %, more preferably 3 to 98 mol %, even more preferably 5 to 97 mol %, and most preferably 10 to 95 mol % with regard to all repeating units in the hydrophobic resin.

The content of the repeating unit (b′) is preferably 1 to 100 mol %, more preferably 3 to 99 mol %, even more preferably 5 to 97 mol %, and most preferably 10 to 95 mol % with regard to all repeating units in the hydrophobic resin.

The content of the repeating unit (b*) is preferably 1 to 90 mol %, more preferably 3 to 80 mol %, even more preferably 5 to 70 mol %, and most preferably 10 to 60 mol % with regard to all repeating units in the hydrophobic resin. The content of the repeating unit having at least any of a fluorine atom and a silicon atom used with the repeating unit (b*) is preferably 10 to 99 mol %, more preferably 20 to 97 mol %, even more preferably 30 to 95 mol %, and most preferably 40 to 90 mol % with regard to all repeating units in the hydrophobic resin.

The content of the repeating unit (b″) is preferably 1 to 100 mol %, more preferably 3 to 99 mol %, even more preferably 5 to 97 mol %, and most preferably 10 to 95 mol % with regard to all repeating units in the hydrophobic resin.

The hydrophobic resin may further have a repeating unit represented by the following General Formula (CIII).

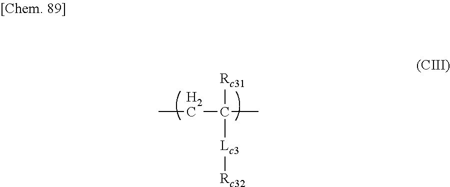

In General Formula (CIII), R_{c31} represents a hydrogen atom, an alkyl group, (may be substituted with a fluorine atom or the like), a cyano group, or a —CH₂—O—R_{ac2} group. In the formula, R_{ac2} represents a hydrogen atom, an alkyl group or an acyl group. R_{c31} is preferably a hydrogen atom, a methyl group, a hydroxymethyl group or a trifluoromethyl group, and particularly preferably a hydrogen atom or a methyl group.

R_{c32} represents an alkyl group, a cycloalkyl group, an alkenyl group, a cycloalkenyl group or an aryl group. These groups may be substituted with a group including a fluorine atom or a silicon atom.

L_{c3} represents a single bond or a divalent linking group.

In General Formula (CIII), the alkyl group of R_{c32} is preferably a linear or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The aryl group is preferably a phenyl group having 6 to 20 carbon atoms or a naphthyl group, and these may have a substituent.

R_{c32} is preferably an unsubstituted alkyl group or an alkyl group substituted with a fluorine atom.

The divalent linking group of L_{c3} is preferably an alkylene group (preferably having 1 to 5 carbon atoms), an oxy group, a phenylene group or an ester bond (a group represented by —COO—).

The hydrophobic resin may preferably further have a repeating unit represented by the following General Formula (BII-AB).

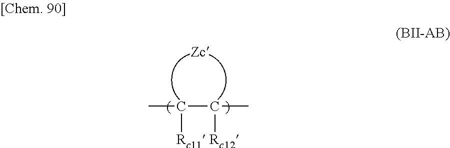

In Formula (BII-AB), R_{c11}′ and R_{c12}′ each independently represent a hydrogen atom, a cyano group, a halogen atom or an alkyl group.

Zc′, including the two carbon atoms (C—C) to which Zc′ is bonded, represents an atomic group to form an alicyclic structure.

When each group in the repeating unit represented by General Formulae (CIII) and (BII-AB) is substituted with a group including a silicon atom or a fluorine atom, the repeating unit also corresponds to the repeating unit having at least any of a fluorine atom or a silicon atom.

Specific examples of the repeating unit represented by General Formulae (CIII) and (BII-AB) are shown below, however, the present invention is not limited to these. In the formula, Ra represents H, CH₃, CH₂OH, CF₃, or CN. In addition, the repeating unit when Ra is CF₃ also corresponds to the above repeating unit having at least any of a fluorine atom or a silicon atom.

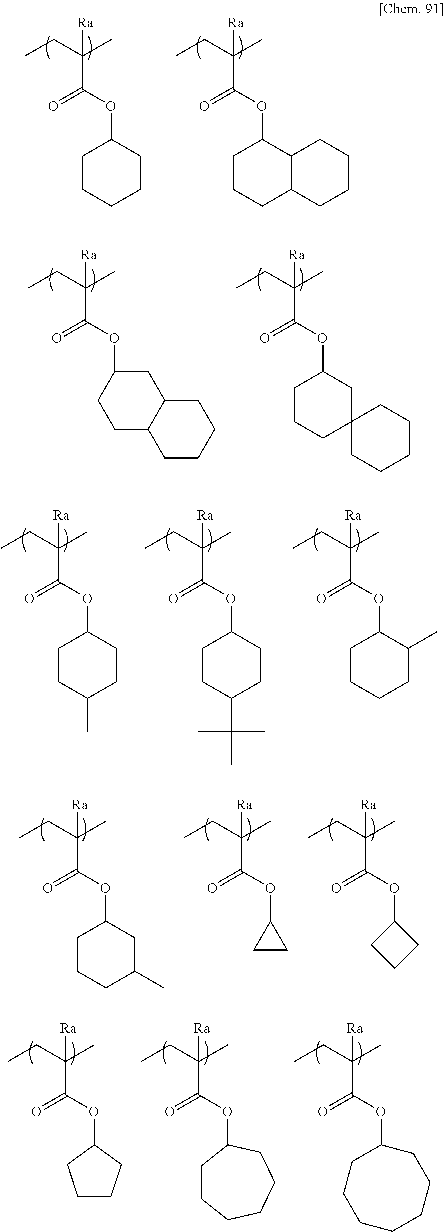

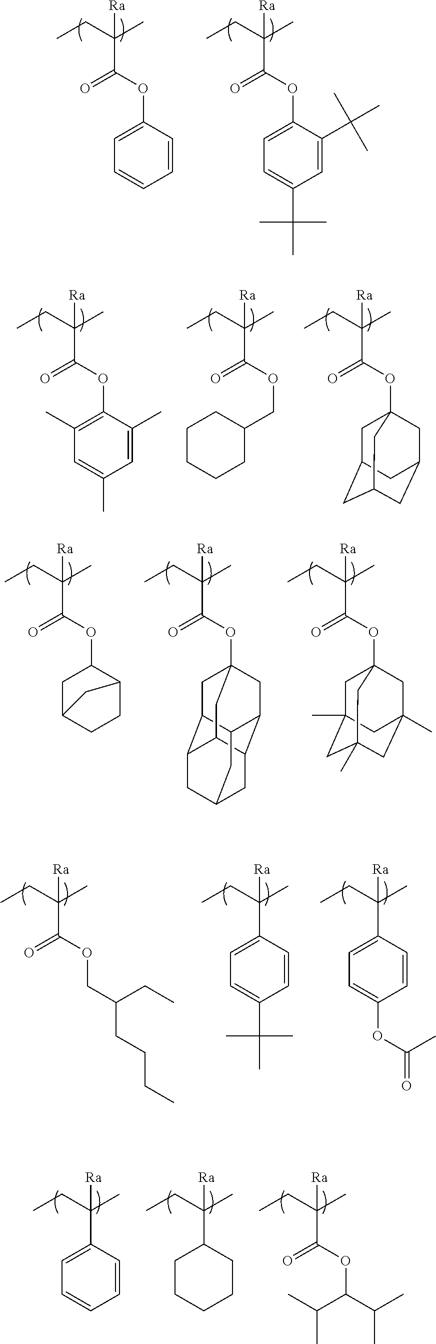

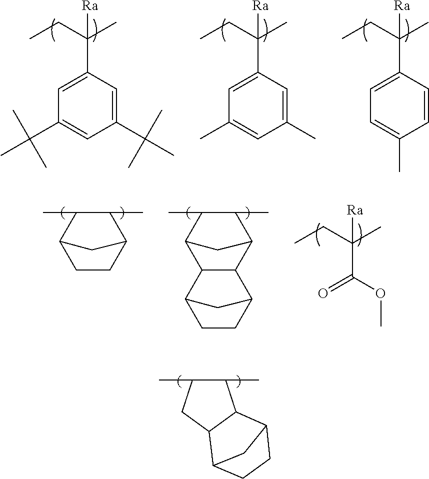

The hydrophobic resin, similar to the resin (B) described above, naturally has fewer impurities such as metal, and also a residual monomer or an oligomer component is preferably 0 to 10% by mass, more preferably 0 to 5% by mass, and even more preferably 0% to 1% by mass. As a result, a resist composition that does not have temporal changes such as the impurities in the liquid, sensitivity or the like may be obtained. In addition, a molecular weight distribution (Mw/Mn, also referred to as a degree of dispersion) is preferably in the range of 1 to 3, more preferably 1 to 2, even more preferably is in the range of 1 to 1.8, and most preferably is in the range of 1 to 1.5 from the viewpoint of resolution, a resist shape, a sidewall of the resist pattern, roughness, and the like.

A variety of commercially available products may be used as the hydrophobic resin, or the hydrophobic resin may be synthesized in accordance with conventional methods (for example, radical polymerization). For example, as the general synthesis method, a bulk polymerization method in which polymerization is carried out by dissolving monomer species and an initiator in a solvent and heating the solution, a dropwise adding polymerization method in which a solution of monomer species and an initiator is added dropwise to a heating solvent over 1 to 10 hours, or the like may be included, and a dropwise adding polymerization method is preferable.

The reaction solvent, the polymerization initiator, the reaction condition (temperature, concentration, and the like), and the purification method after the reaction, are similar to those described in the resin (B).

Specific examples of the hydrophobic resin (HR) are shown below. In addition, the molar ratio of the repeating unit in each resin (corresponding to each repeating unit from left to right), the weight-average molecular weight, and the degree of dispersion are shown in the Table 1 below.

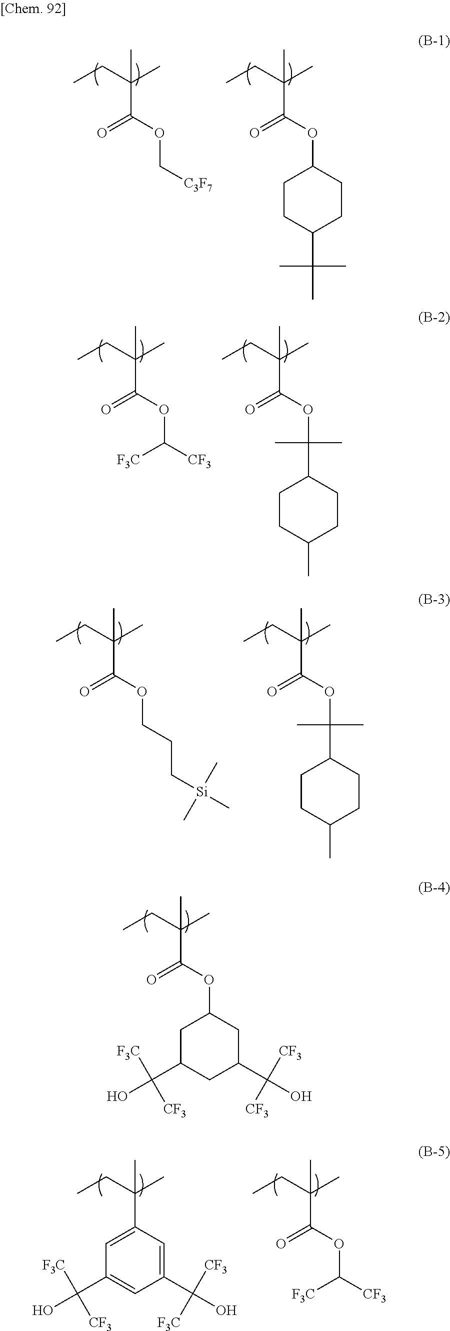

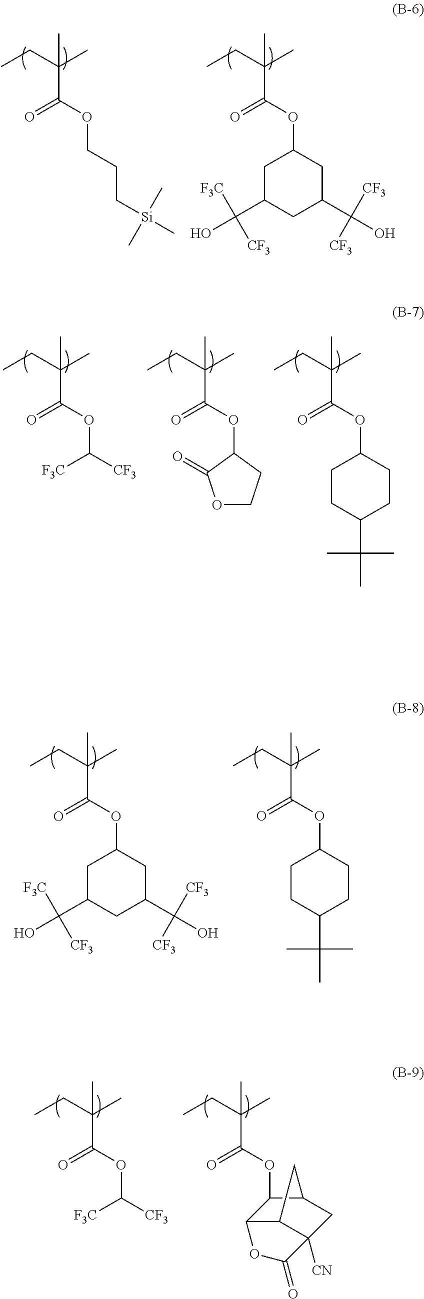

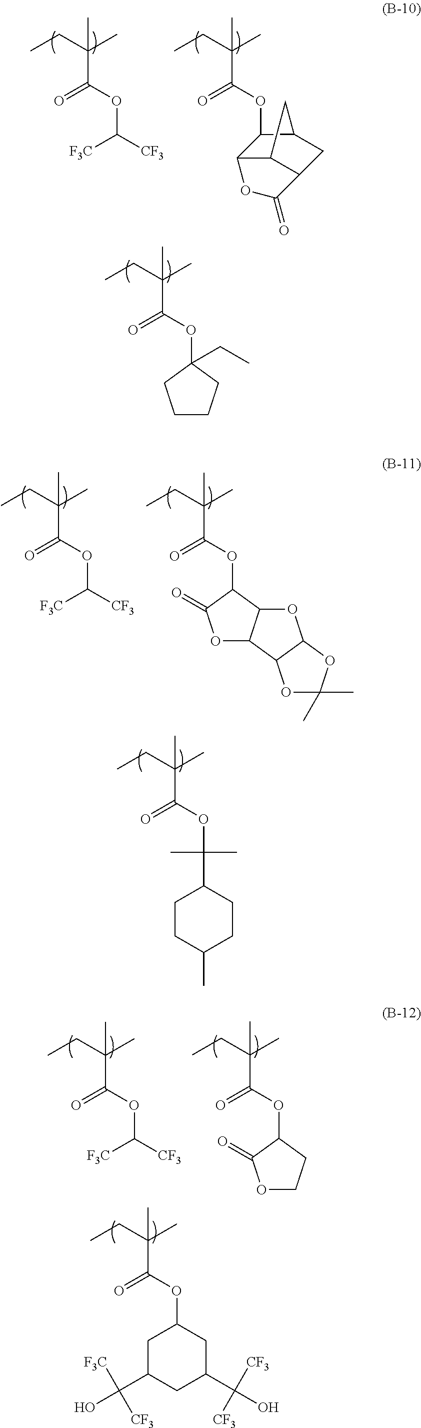

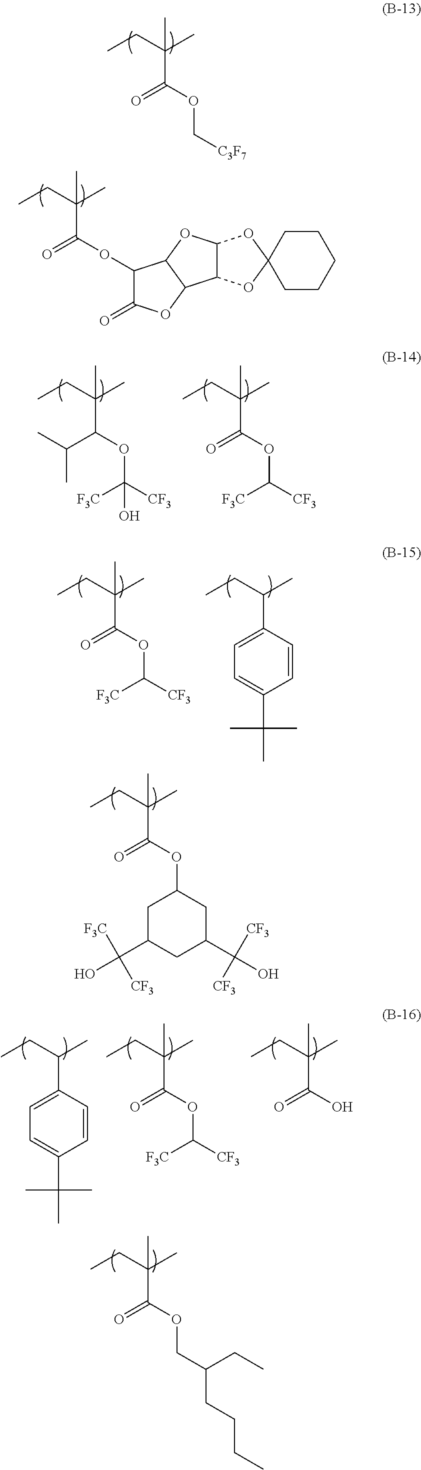

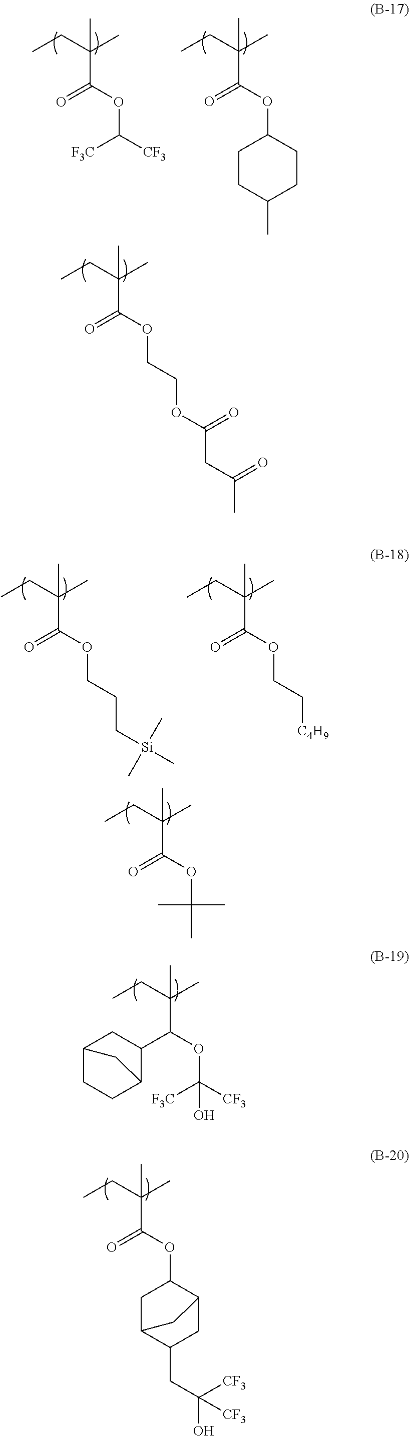

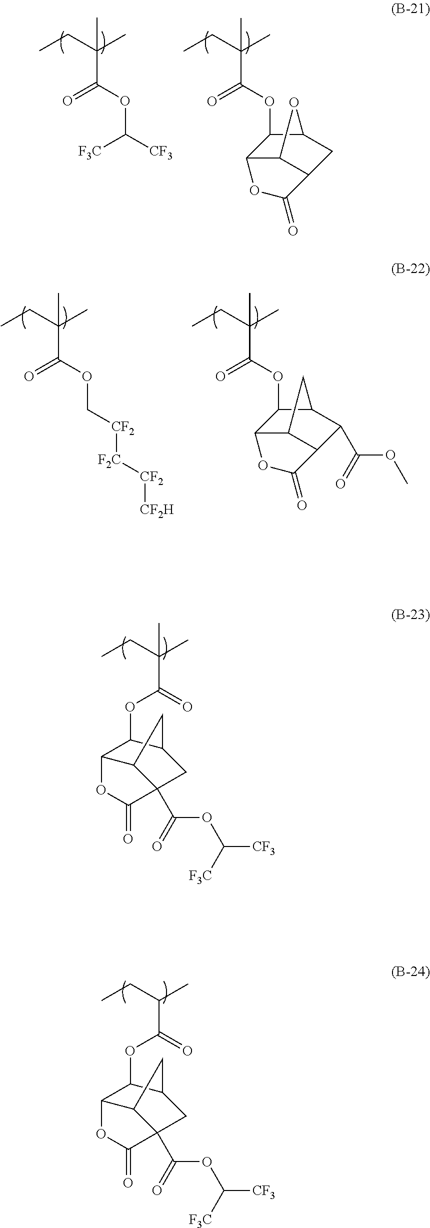

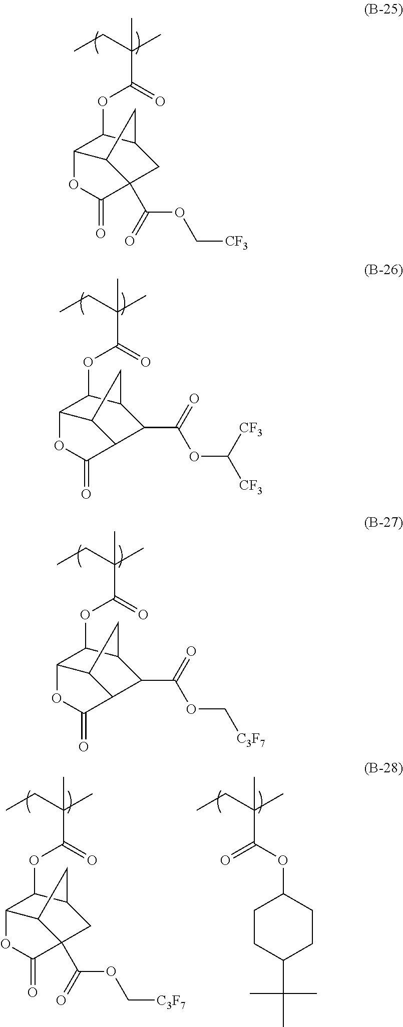

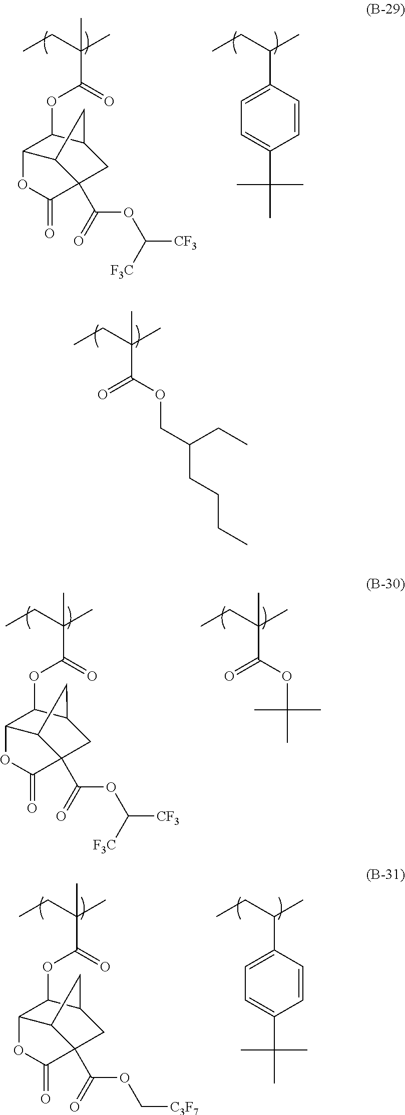

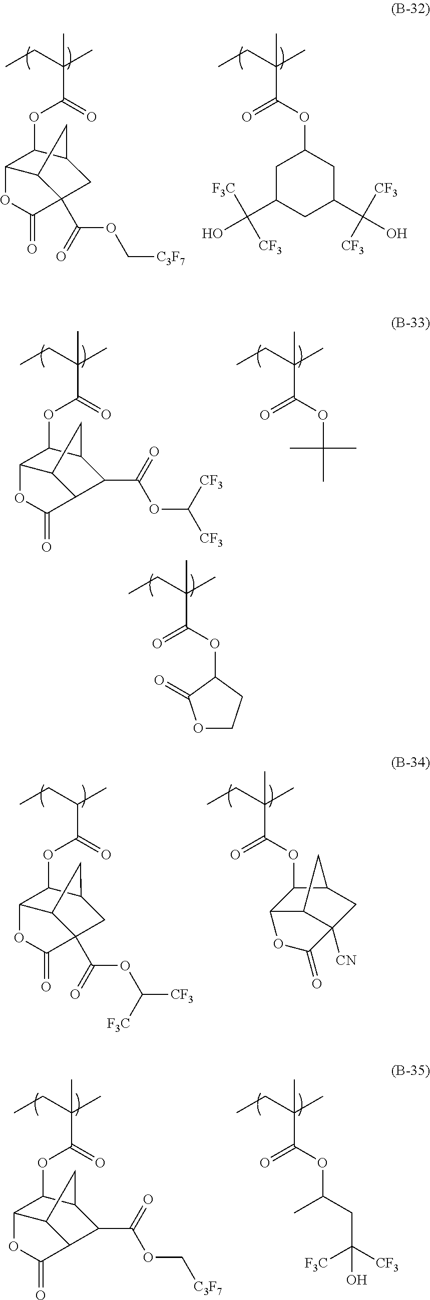

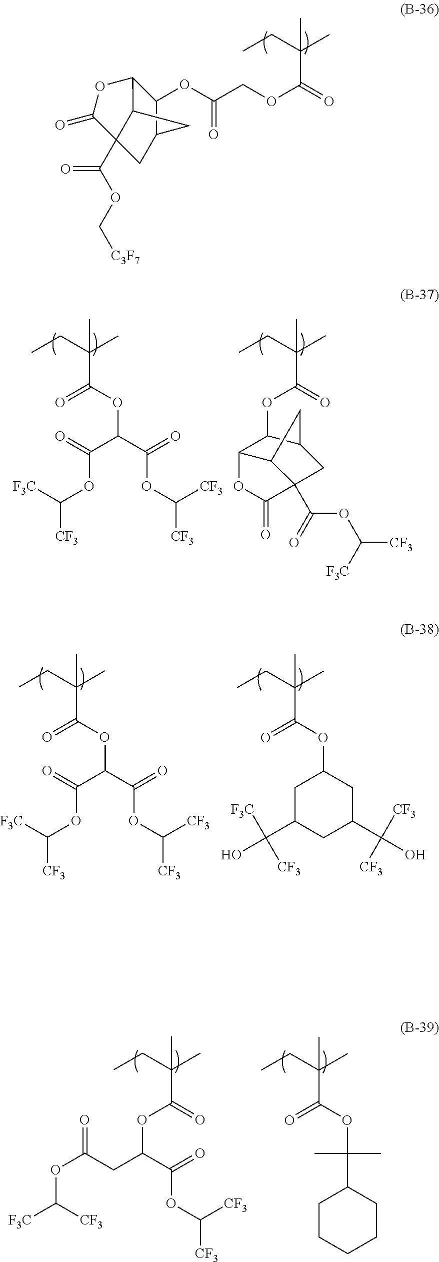

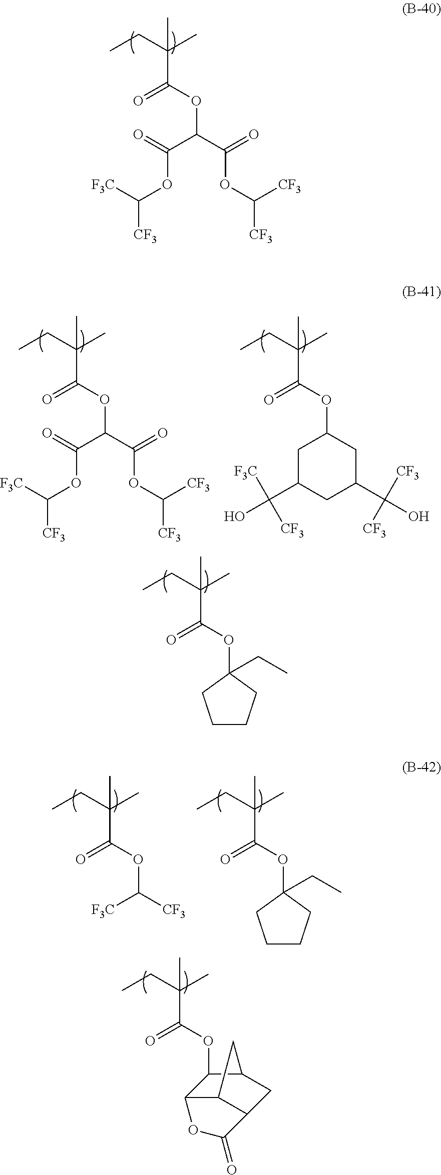

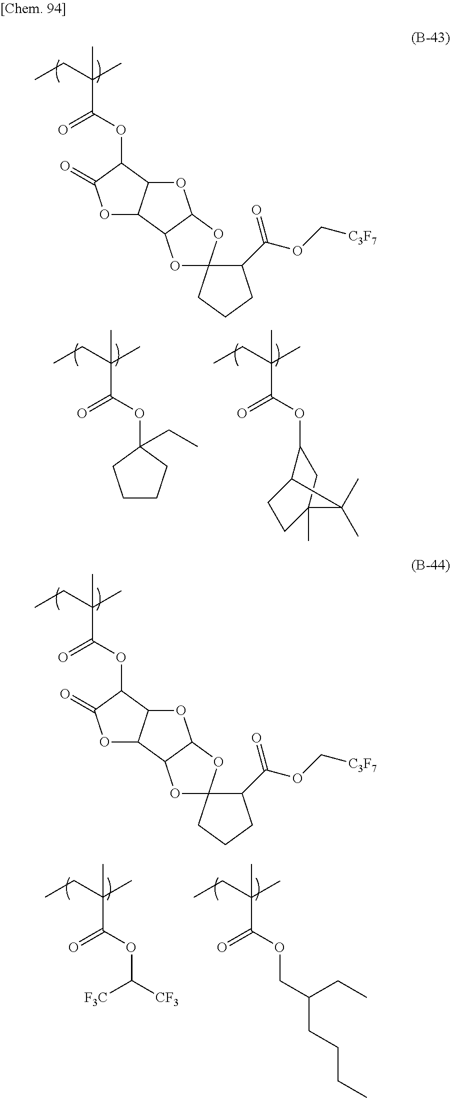

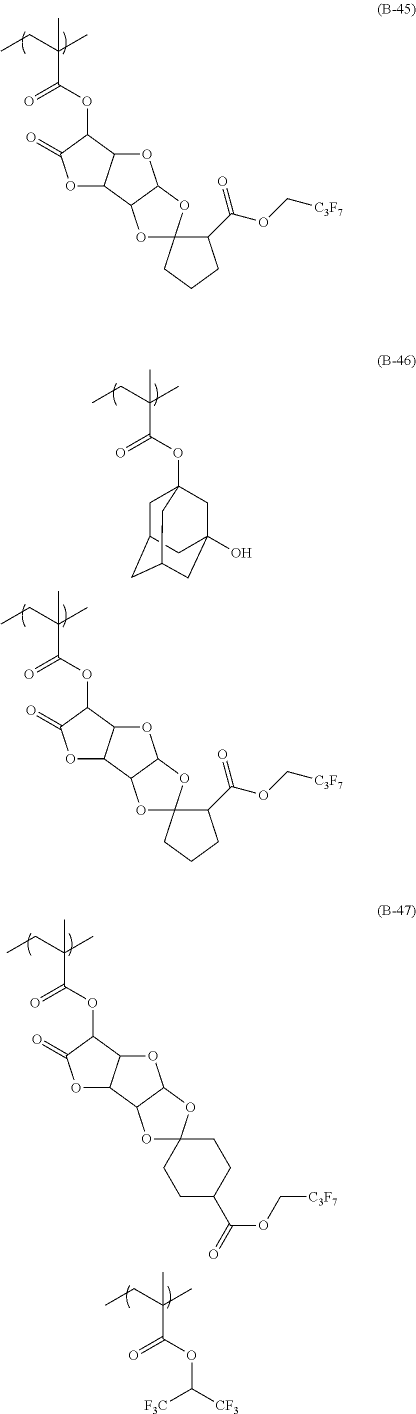

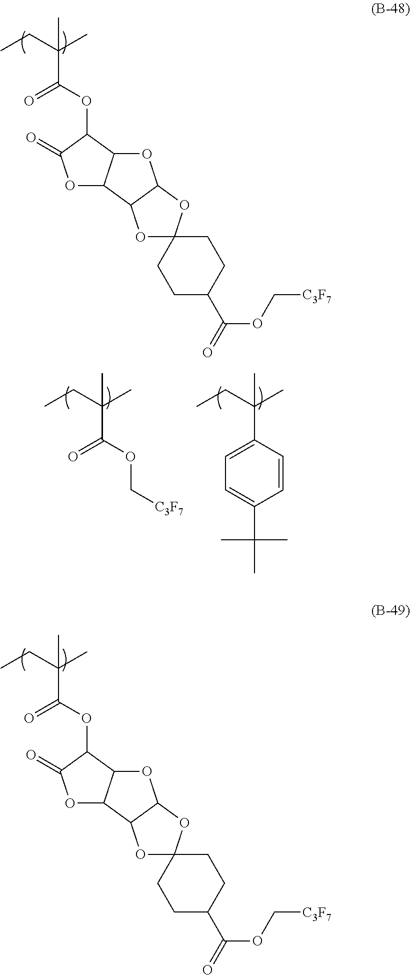

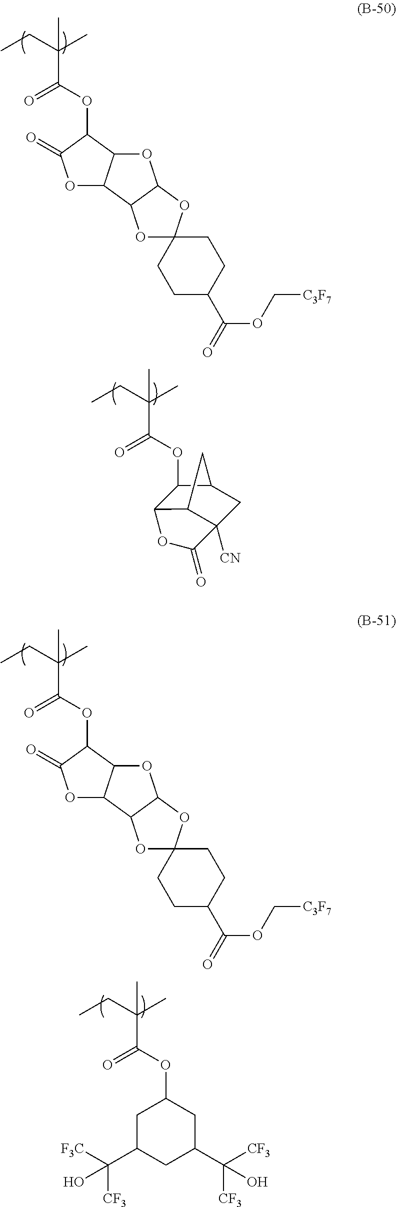

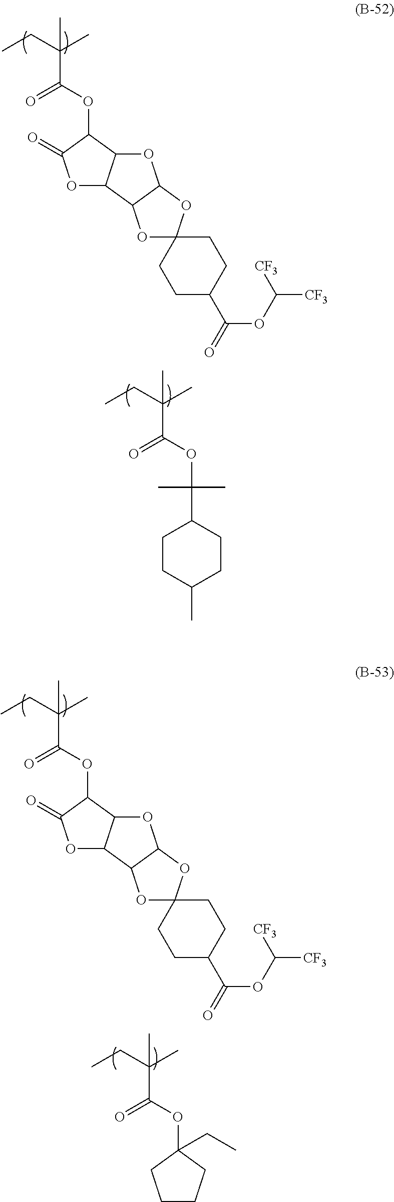

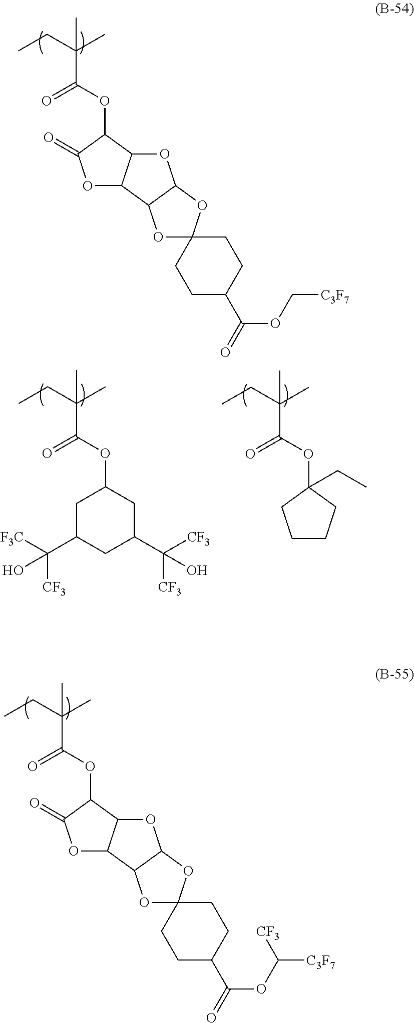

TABLE 1

| | Composition | | Mw/ |
|---|---|---|---|
| Polymer | (mol %) | Mw | Mn |
| B-1 | 50/50 | 6000 | 1.5 |
| B-2 | 30/70 | 6500 | 1.4 |
| B-3 | 45/55 | 8000 | 1.4 |
| B-4 | 100 | 15000 | 1.7 |
| B-5 | 60/40 | 6000 | 1.4 |
| B-6 | 40/60 | 8000 | 1.4 |
| B-7 | 30/40/30 | 8000 | 1.4 |
| B-8 | 60/40 | 8000 | 1.3 |
| B-9 | 50/50 | 6000 | 1.4 |
| B-10 | 40/40/20 | 7000 | 1.4 |
| B-11 | 40/30/30 | 9000 | 1.6 |
| B-12 | 30/30/40 | 6000 | 1.4 |
| B-13 | 60/40 | 9500 | 1.4 |
| B-14 | 60/40 | 8000 | 1.4 |
| B-15 | 35/35/30 | 7000 | 1.4 |
| B-16 | 50/40/5/5 | 6800 | 1.3 |
| B-17 | 20/30/50 | 8000 | 1.4 |
| B-18 | 25/25/50 | 6000 | 1.4 |
| B-19 | 100 | 9500 | 1.5 |
| B-20 | 100 | 7000 | 1.5 |
| B-21 | 50/50 | 6000 | 1.6 |
| B-22 | 40/60 | 9600 | 1.3 |
| B-23 | 100 | 20000 | 1.7 |
| B-24 | 100 | 25000 | 1.4 |
| B-25 | 100 | 15000 | 1.7 |
| B-26 | 100 | 12000 | 1.8 |
| B-27 | 100 | 18000 | 1.3 |
| B-28 | 70/30 | 15000 | 2.0 |
| B-29 | 85/15/5 | 18000 | 1.8 |
| B-30 | 60/40 | 25000 | 1.8 |
| B-31 | 90/10 | 19000 | 1.6 |
| B-32 | 60/40 | 20000 | 1.8 |
| B-33 | 50/30/20 | 11000 | 1.6 |
| B-34 | 60/40 | 12000 | 1.8 |
| B-35 | 60/40 | 15000 | 1.6 |
| B-36 | 100 | 22000 | 1.8 |
| B-37 | 20/80 | 35000 | 1.6 |
| B-38 | 30/70 | 12000 | 1.7 |
| B-39 | 30/70 | 9000 | 1.5 |
| B-40 | 100 | 9000 | 1.5 |
| B-41 | 40/15/45 | 12000 | 1.9 |
| B-42 | 30/30/40 | 13000 | 2.0 |
| B-43 | 40/40/20 | 23000 | 2.1 |
| B-44 | 65/30/5 | 25000 | 1.6 |
| B-45 | 100 | 15000 | 1.7 |
| B-46 | 20/80 | 9000 | 1.7 |
| B-47 | 70/30 | 18000 | 1.5 |
| B-48 | 60/20/20 | 18000 | 1.8 |
| B-49 | 100 | 12000 | 1.4 |
| B-50 | 60/40 | 20000 | 1.6 |
| B-51 | 70/30 | 33000 | 2.0 |
| B-52 | 60/40 | 19000 | 1.8 |
| B-53 | 50/50 | 15000 | 1.5 |
| B-54 | 40/20/40 | 35000 | 1.9 |
| B-55 | 100 | 16000 | 1.4 |

By the actinic ray-sensitive or radiation-sensitive resin composition in the present invention containing a hydrophobic resin which has at least one of a fluorine atom and a silicon atom, the hydrophobic resin can be localized on the surface layer of the film formed from the actinic ray-sensitive or radiation-sensitive resin composition, and may improve the immersion liquid traceability by improving the receding contact angle of the film surface for water after the baking or before the exposure when a liquid immersion medium is water.

The receding contact angle of the film after baking or before exposing the film composed of the actinic ray-sensitive or radiation-sensitive resin composition of the present invention is preferably 60° to 90° at a normal room temperature of 23±3° C. and a humidity of 45±5%, more preferably 65° or more, even more preferably 70° or more, and particularly preferably 75° or more.

The hydrophobic resin is localized on the interface as described above, but, unlike surfactants, necessarily does not need to have a hydrophilic group within the molecule and does not contribute to uniformly mixing the polar/non-polar substances.

In the liquid immersion exposure step, the contact angle of the immersion liquid for the resist film in a dynamic state becomes critical since the immersion liquid needs to move on a wafer following the movement of an exposure head scanning on the wafer at a high speed to form an exposure pattern, therefore, the resist is required to have an ability to follow the high-speed scan of the exposure head without leaving any droplets.

In the hydrophobic resin, a development residue (scum) and BLOB defects are easily deteriorated after alkali development since the hydrophobic resin is hydrophobic, however, a development residue (scum) and BLOB defect performance are improved since the hydrophobic resin has three or more polymer chains through at least one branch portion, therefore, the alkali dissolution rate is improved compared to a linear resin.

When the hydrophobic resin has a fluorine atom, the content of the fluorine atom is preferably 5 to 80% by mass and more preferably 10 to 80% by mass with regard to a molecular weight of the hydrophobic resin. In addition, the repeating unit including a fluorine atom is preferably 10 to 100 mol % and more preferably 30 to 100 mol % with regard to all repeating units in the hydrophobic resin.

When the hydrophobic resin has a silicon atom, the content of the silicon atom is preferably 2 to 50% by mass and more preferably 2 to 30% by mass with regard to a molecular weight of the hydrophobic resin. In addition, the repeating unit including a silicon atom is preferably 10 to 90 mol % and more preferably 20 to 80 mol % with regard to all repeating units in the hydrophobic resin.

The weight-average molecular weight of the hydrophobic resin is preferably 1,000 to 100,000, more preferably 2,000 to 50,000, and even more preferably 3,000 to 35,000. Here, the weight-average molecular weight of the resin represents a polystyrene converted molecular weight measured by GPC (a carrier: tetrahydrofuran (THF)).

The content of the hydrophobic resin in the actinic ray-sensitive or radiation-sensitive resin composition may be appropriately adjusted and used so that the receding contact angle of the actinic ray-sensitive or radiation-sensitive resin film becomes the above range, but is preferably 0.01 to 20% by mass, more preferably 0.1 to 15% by mass, even more preferably 0.1 to 10% by mass, and particularly preferably 0.2 to 8% by mass with regard to total solid contents in the actinic ray-sensitive or radiation-sensitive resin composition.

The hydrophobic resin may be used either alone or as a combination of two types or more.

[4] Basic Compound

The actinic ray-sensitive or radiation-sensitive resin composition of the present invention preferably contains a basic compound in order to reduce performance changes over time from exposure to heating.

The basic compound may preferably include a compound having a structure represented by the following Formulae (A) to (E).

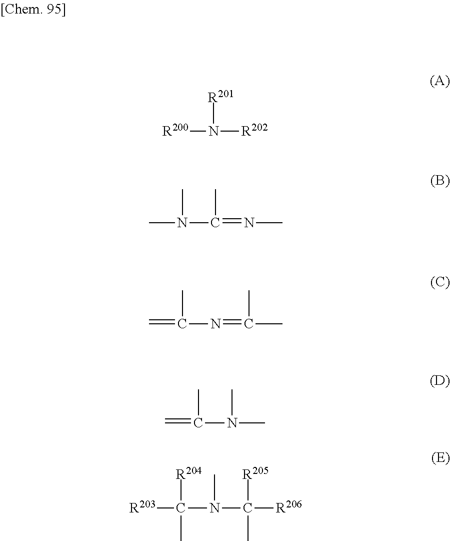

In General formulae (A) and (E), R²⁰⁰, R²⁰¹ and R²⁰² may be the same as or different from each other, and represent a hydrogen atom, an alkyl group (preferably having 1 to 20 carbon atoms), a cycloalkyl group (preferably having 3 to 20 carbon atoms) or an aryl group (preferably having 6 to 20 carbon atoms), and R²⁰¹ and R²⁰² may be bonded to each other to form a ring.

R²⁰³, R²⁰⁴, R²⁰⁵ and R²⁰⁶ may be the same as or different from each other, and represent an alkyl group having 1 to 20 carbon atoms.

For the above alkyl group, an alkyl group having a substituent is preferably an aminoalkyl group having 1 to 20 carbon atoms, a hydroxyalkyl group having 1 to 20 carbon atoms or a cyanoalkyl group having 1 to 20 carbon atoms.

The alkyl group in General Formulae (A) and (E) is more preferably unsubstituted.

The preferable compound may include guanidine, aminopyrrolidine, pyrazole, pyrazoline, piperazine, amino morpholine, aminoalkyl morpholine, piperidine or the like, and the more preferable compound may include a compound having an imidazole structure, a diazabicyclo structure, an onium hydroxide structure, an onium carboxylate structure, a trialkylamine structure, an aniline structure, or a pyridine structure, an alkylamine derivative having a hydroxyl group and/or an ether bond, an aniline derivative having a hydroxyl group and/or an ether bond, or the like.

The compound having an imidazole structure may include imidazole, 2,4,5-triphenyl imidazole, benzimidazole, or the like. The compound having a diazabicyclo structure may include 1,4-diazabicyclo[2,2,2]octane, 1,5-diazabicyclo[4,3,0]nona-5-ene, 1,8-diazabicyclo[5,4,0]undeca-7-ene, or the like. The compound having an onium hydroxide structure may include tetrabutylammonium hydroxide, triarylsulfonium hydroxide, phenacylsulfonium hydroxide, sulfonium hydroxide having an 2-oxoalkyl group, specifically, triphenylsulfonium hydroxide, tris(t-butylphenyl) sulfonium hydroxide, bis(t-butylphenyl)iodonium hydroxide, phenacylthiophenium hydroxide, 2-oxopropylthiophenium hydroxide, or the like. The compound having an onium carboxylate structure is a compound having an onium hydroxide structure of which anion portion is carboxylated, and may include, for example, acetate, adamantane-1-carboxylate, perfluoroalkyl carboxylate, or the like. The compounds having a trialkylamine structure may include tri(n-butyl)amine, tri(n-octyl)amine, or the like. The aniline compound may include 2,6-diisopropylaniline, N,N-dimethylaniline, N,N-dibutylaniline, N,N-dihexylaniline, or the like. The alkylamine derivative having a hydroxyl group and/or an ether bond may include ethanolamine, diethanolamine, triethanolamine, N-phenyldiethanolamine, and tris(methoxyethoxyethyl)amine, or the like. The aniline derivative having a hydroxyl group and/or an ether bond may include N,N-bis(hydroxyethyl)aniline, or the like.

The preferable basic compound may further include an amine compound having a phenoxy group, an ammonium salt compound having a phenoxy group, an amine compound having a sulfonate group, and an ammonium salt compound having a sulfonate group.

As for the amine compound having a phenoxy group, the ammonium salt compound having a phenoxy group, the amine compound having a sulfonate group, and the ammonium salt compound having a sulfonate group, it is preferable that at least one alkyl group be bonded to the nitrogen atom. In addition, it is preferable that the compound have an oxygen atom in the alkyl chain to form an oxyalkylene group. The number of the oxyalkylene groups within the molecule is one or more, preferably 3 to 9, and more preferably 4 to 6. As the oxyalkylene group, the structure of —CH₂CH₂O—, —CH(CH₃)CH₂O—, or —CH₂CH₂CH₂O— is preferable.

Specific examples of the amine compound having a phenoxy group, the ammonium salt compound having a phenoxy group, the amine compound having a sulfonate group, and the ammonium salt compound having a sulfonate group include, but are not limited to, the compounds (C1-1) to (C3-3) exemplified in [0066] of US2007/0224539A.

These basic compounds may be used either alone or as a combination of two types or more.

The composition of the present invention may or may not contain the basic compound, but when the composition does, the content of the basic compound is typically 0.001 to 10% by mass, and preferably 0.01 to 5% by mass with regard to solid contents of the actinic ray-sensitive or radiation-sensitive resin composition.

The ratio between the acid generator and the basic compound used in the composition is preferably a ratio of acid generator/basic compound (molar ratio)=2.5 to 300. In other words, the molar ratio is preferably 2.5 or more from the viewpoint of sensitivity and resolution, and is preferably 300 or less from the viewpoint of suppressing the reduction of the resolution by an enlargement of the resist pattern over time from the exposure to the heat treatment. The acid generator/basic compound (molar ratio) is more preferably 5.0 to 200, and even more preferably 7.0 to 150.

These basic compounds are preferably used in a molar ratio of low molecular compound (D)/basic compound=100/0 to 10/90, more preferably used in 100/0 to 30/70, and particularly preferably used in 100/0 to 50/50 with regard to a low molecular compound (D) described in the following section [5].

Furthermore, the basic compound here does not include (D) a low molecular compound containing a nitrogen atom and a group capable of being detached by the action of an acid which is also a basic compound sometimes.

[5] Low Molecular Compound Having Nitrogen Atom and Group Capable of being Detached by Action of Acid

The composition of the present invention may contain a low molecular compound containing a nitrogen atom and a group capable of being detached by the action of an acid (hereinafter also referred to as “low molecular compound (D)” or “Compound (D)”).

The group capable of being detached by the action of an acid is not particularly limited, but is preferably an acetal group, a carbonate group, a carbamate group, a tertiary ester group, a tertiary hydroxyl group or a hemiaminal ether group, and particularly preferably a carbamate group or a hemiaminal ether group.

The molecular weight of the low molecular compound having a group capable of being detached by the action of an acid (D) is preferably 100 to 1000, more preferably 100 to 700, and particularly preferably 100 to 500.

The compound (D) is preferably an amine derivative having a group capable of being detached by the action of an acid on the nitrogen atom.

The compound (D) may have a carbamate group having a protecting group on the nitrogen atom. The protecting group constituting the carbamate group may be represented by the following General Formula (d-1).

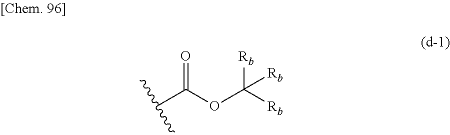

In General Formula (d-1), Rbs each independently represent a hydrogen atom, an alkyl group, a cycloalkyl group, an aryl group, an aralkyl group or an alkoxyalkyl group. Rbs may be bonded to each other to form a ring.

The alkyl group, the cycloalkyl group, the aryl group, the aralkyl group represented by Rbs may be substituted with a functional group such as a hydroxyl group, a cyano group, an amino group, a pyrrolidino group, a piperidino group, a morpholino group or an oxo group, an alkoxy group, or a halogen atom. The same applies to the alkoxyalkyl group represented by Rbs.

Examples of the alkyl group, the cycloalkyl group, the aryl group, the aralkyl group of the above Rb (these alkyl group, cycloalkyl group, aryl group and aralkyl group may be substituted with the functional group described above, an alkoxy group, or a halogen atom) may include a group derived from a linear or branched alkane such as methane, ethane, propane, butane, pentane, hexane, heptane, octane, nonane, decane, undecane or dodecane, a group in which the group derived from alkane is substituted with one type or more, or one or more cycloalkyl groups such as, for example, a cyclobutyl group, cyclopentyl group or cyclohexyl group, a group derived from cycloalkane such as cyclobutane, cyclopentane, cyclohexane, cycloheptane, cyclooctane, norbornane, adamantane or noradamantane, a group in which the group derived from cycloalkane is substituted with one type or more, or one or more linear or branched alkyl groups such as, for example, a methyl group, an ethyl group, an n-propyl group, an i-propyl group, an n-butyl group, a 2-methylpropyl group, a 1-methylpropyl group or a t-butyl group, a group derived from an aromatic compound such as benzene, naphthalene, or anthracene, a group in which the group derived from an aromatic compound is substituted with one type or more, or one or more linear or branched alkyl groups such as, for example, a methyl group, an ethyl group, an n-propyl group, an i-propyl group, an n-butyl group, a 2-methylpropyl group, a 1-methylpropyl group or a t-butyl group, a group derived from a heterocyclic compound such as pyrrolidine, piperidine, morpholine, tetrahydrofuran, tetrahydropyran, indole, indoline, quinoline, perhydroquinoline, indazole or benzimidazole, a group in which the group derived from a heterocyclic compound is substituted with one type or more, or one or more linear or branched alkyl groups or groups derived from an aromatic compound, a group in which the group derived from linear or branched alkane•the group derived from cycloalkane is substituted with one type or more, or one or more groups derived from an aromatic compound such as a phenyl group, a naphthyl group, or an anthracenyl group, or the like, or a group in which the substituents described above are substituted with a functional group such as a hydroxyl group, a cyano group, an amino group, a pyrrolidino group, a piperidino group, a morpholino group or an oxo group, or the like.

Rb is preferably a linear or branched alkyl group, a cycloalkyl group or an aryl group. A linear or branched alkyl group or a cycloalkyl group is more preferable.

The ring formed by two Rbs being bonded to each other may include an alicyclic hydrocarbon group, an aromatic hydrocarbon ring, a heterocyclic hydrocarbon group, or a derivative thereof.

Specific structures of the group represented by General Formula (d-1) are shown below.

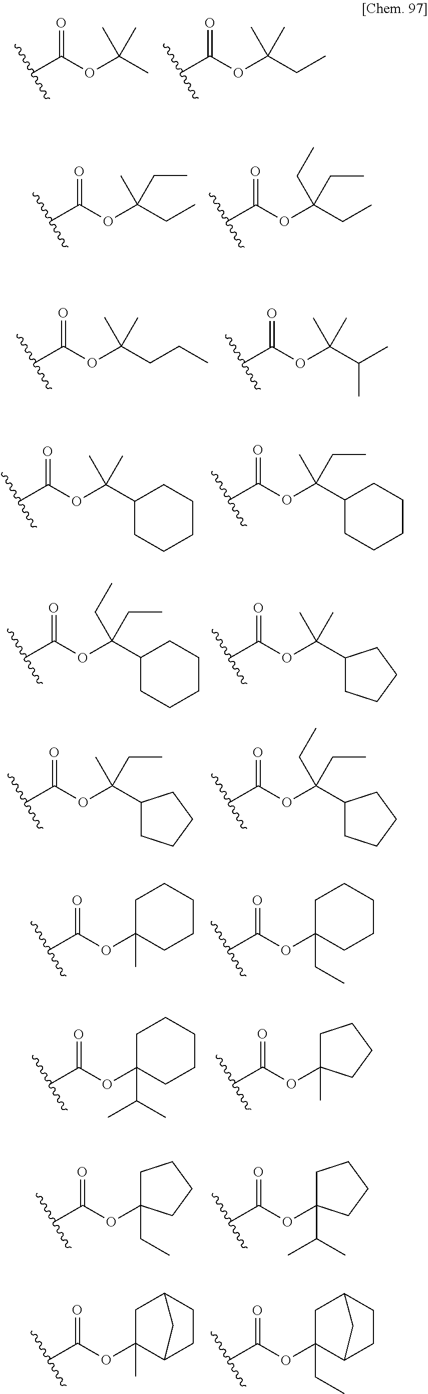

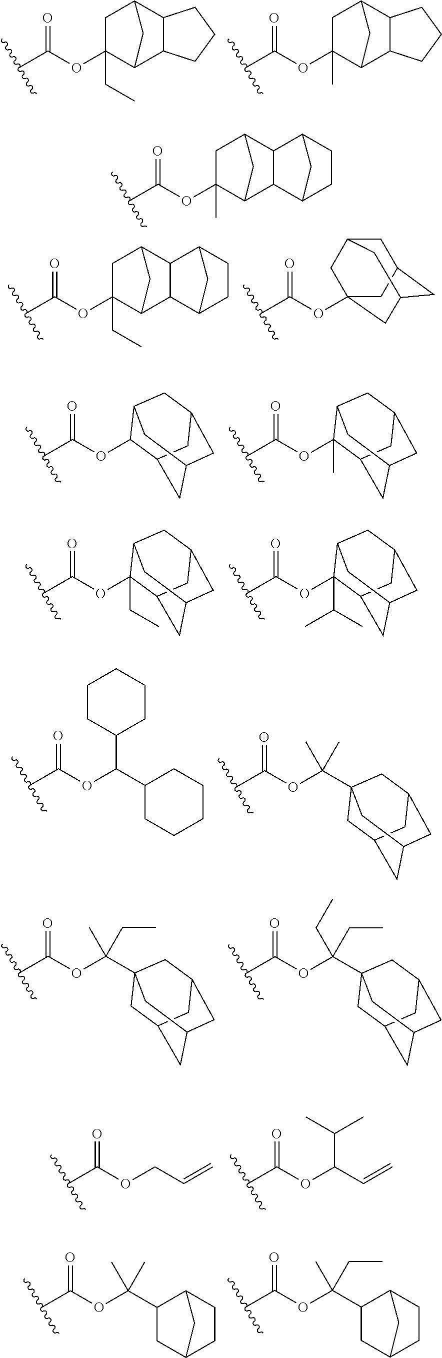

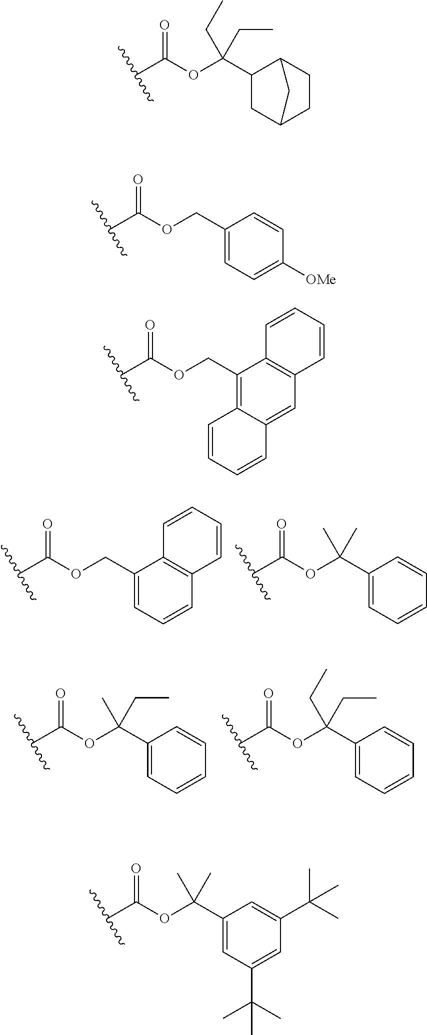

The compound (D) may also be formed by arbitrary combinations of the above basic compound and a structure represented by General Formula (d-1).

The compound (D) particularly preferably has a structure represented by the following General Formula (A).

In addition, the compound (D) may correspond to the above basic compound as long as it is a low molecular compound containing a group capable of being detached by the action of an acid.

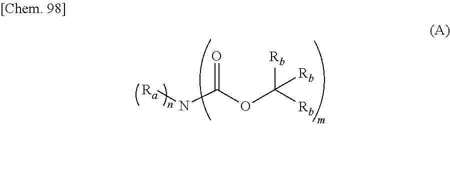

In General Formula (A), Ra represents a hydrogen atom, an alkyl group, a cycloalkyl group, an aryl group or an aralkyl group. In addition, when n=2, the two Ras may be the same as or different from each other, two of Ra may be bonded to each other to form a divalent heterocyclic hydrocarbon group (preferably having 20 or less carbon atoms) or a derivative thereof.

Rbs are synonymous with Rbs in General Formula (d-1) and so are the preferable examples. However, in —C(Rb)(Rb)(Rb), when one or more of Rbs are hydrogen atoms, at least one of the remaining Rbs is a cyclopropyl group, an 1-alkoxyalkyl group or an aryl group.

n represents an integer of 0 to 2, m represents an integer of 1 to 3, respectively, and n+m=3.

In General Formula (A), the alkyl group, the cycloalkyl group, the aryl group and the aralkyl group represented by Ra may be substituted with the same group described above as the group in which the alkyl group, the cycloalkyl group, the aryl group and the aralkyl group represented by R_{b} may be substituted.

Specific examples of the alkyl group, the cycloalkyl group, the aryl group, and the aralkyl group of the above Ra (these alkyl group, cycloalkyl group, aryl group and aralkyl group may be substituted with the above groups) include the same specific examples for Rb described above.

In addition, examples of the divalent heterocyclic hydrocarbon group (preferably having 1 to 20 carbon atoms) formed by the above Ras being bonded to each other or a derivative thereof include a group derived from a heterocyclic compound such as pyrrolidine, piperidine, morpholine, 1,4,5,6-tetrahydropyrimidine, 1,2,3,4-tetrahydroquinoline, 1,2,3,6-tetrahydropyridine, homopiperazine, 4-azabenzimidazole, benzotriazole, 5-azabenzotriazole, 1H-1,2,3-triazole, 1,4,7-triazacyclononane, tetrazole, 7-azaindole, indazole, benzimidazole, imidazo[1,2-a]pyridine, (1S,4S)-(+)-2,5-diazabicyclo[2.2.1]heptane, 1,5,7-triazabicyclo[4.4.0]dec-5-ene, indole, indoline, 1,2,3,4-tetrahydroquinoxaline, perhydroquinoline, 1,5,9-triazacyclododecane, or a group in which the group derived from these heterocyclic compounds is substituted with one type or more, or one or more groups derived from linear or branched alkanes, groups derived from cycloalkane, groups derived from an aromatic compound, groups derived from a heterocyclic compound, functional groups such as a hydroxyl group, a cyano group, an amino group, a pyrrolidino group, a piperidino group, a morpholino group or an oxo group, or the like.

Specific examples of the particularly preferable compound (D) of the present invention are shown below, however, the present invention is not limited to these.

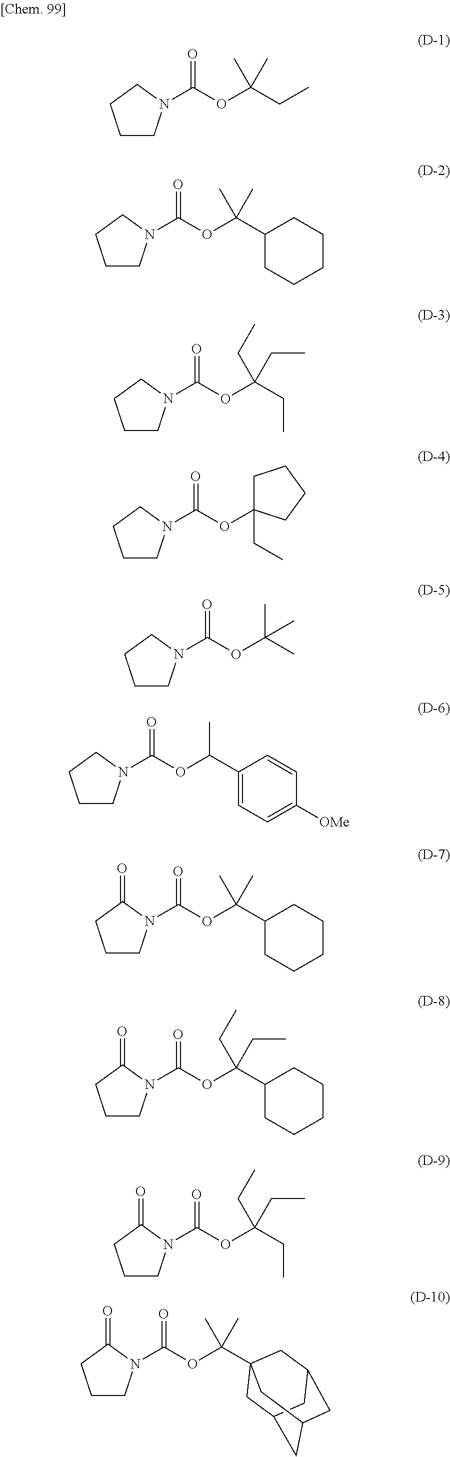

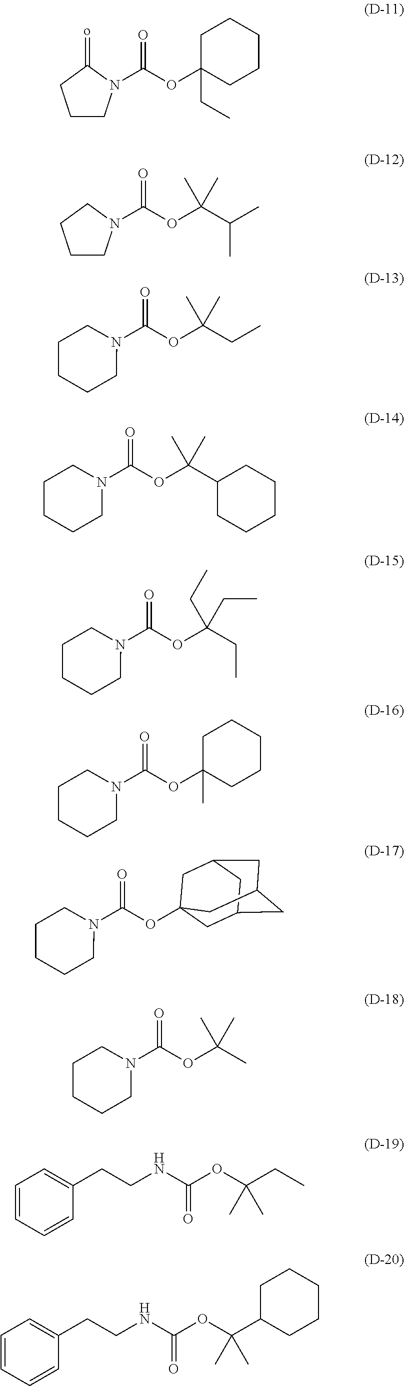

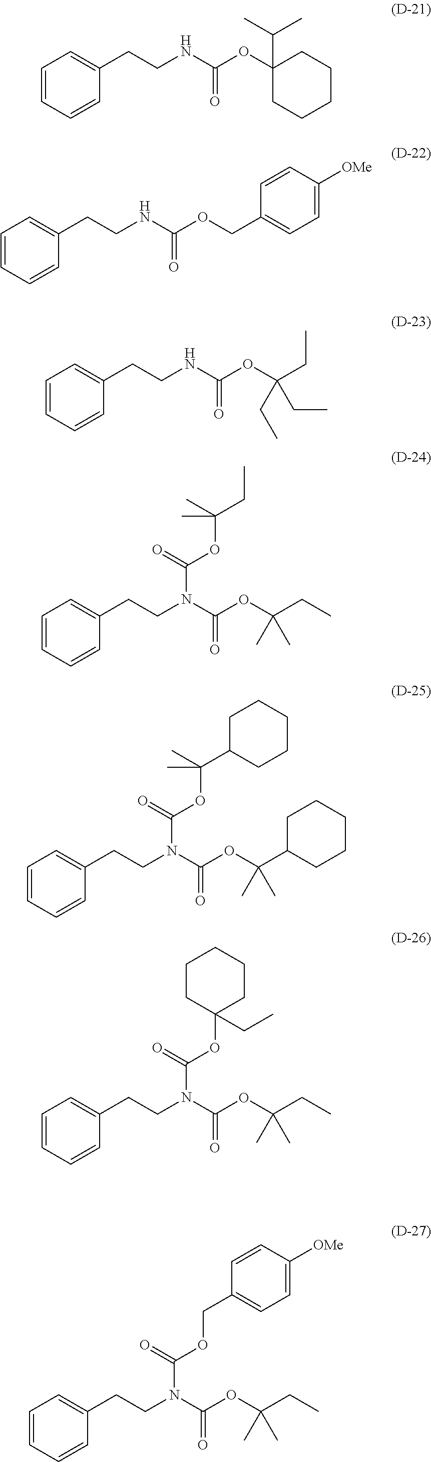

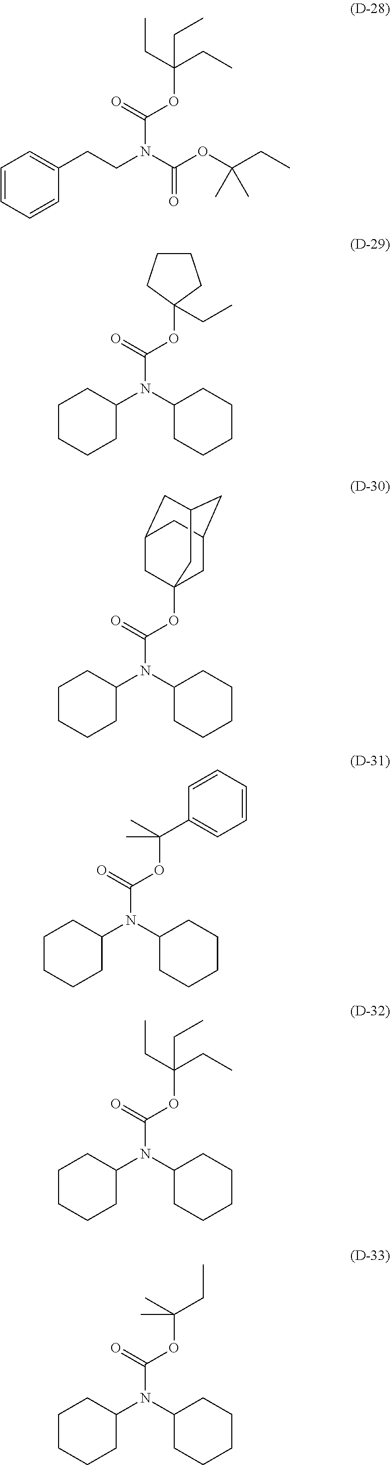

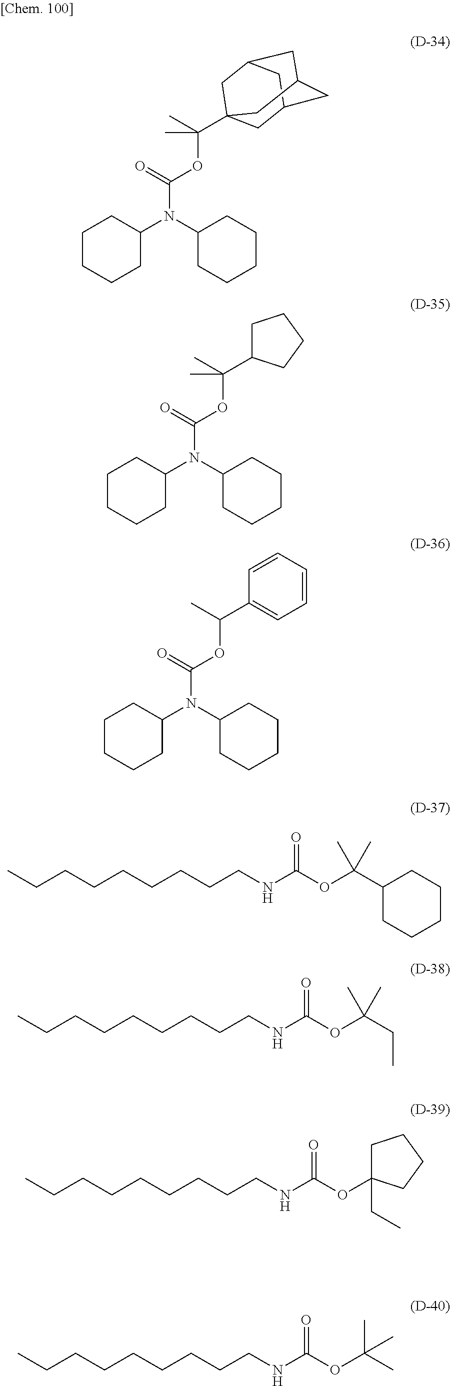

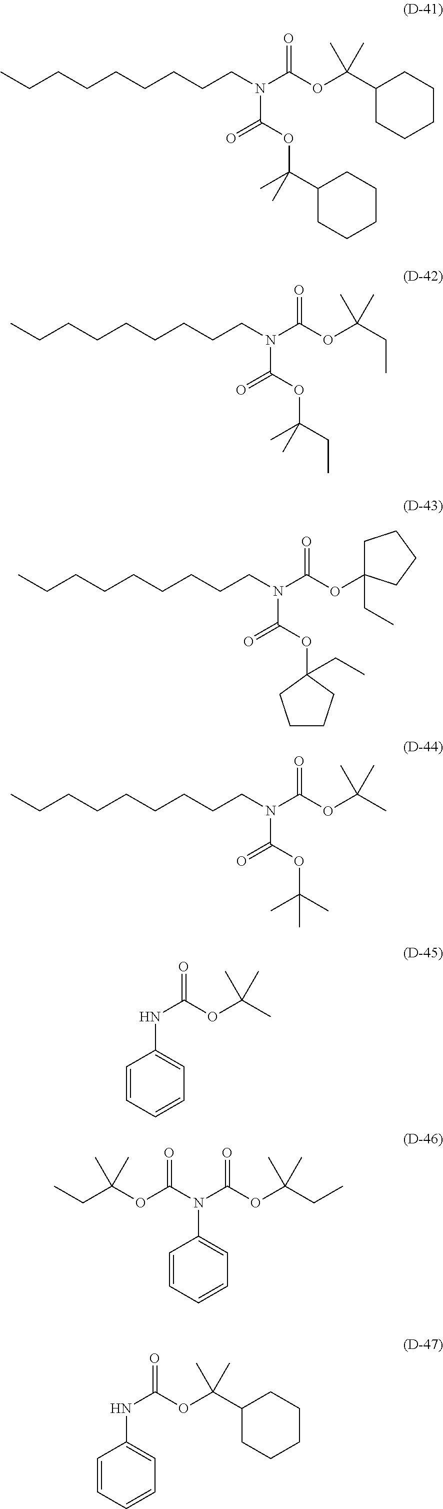

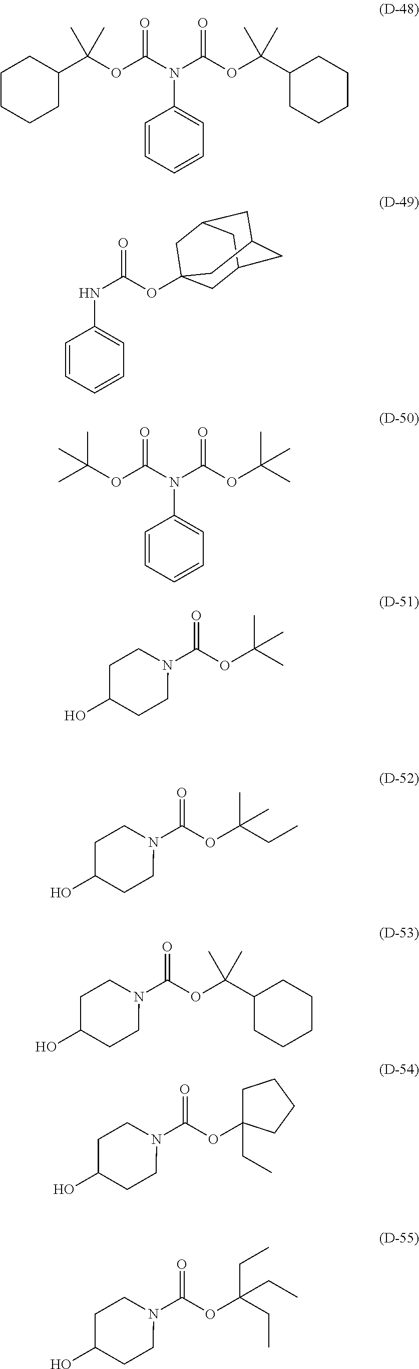

The compound represented by General Formula (A) can be synthesized based on JP2007-298569A, JP2009-199021A, and the like.

In the present invention, (D) the low molecular compound containing a nitrogen atom and a group capable of being detached by the action of an acid may be used either alone or as a combination of two types or more.

The actinic ray-sensitive or radiation-sensitive resin composition of the present invention may or may not contain (D) the low molecular compound containing a nitrogen atom and a group capable of being detached by the action of an acid, but when the composition does, the content of the compound (D) is typically 0.001 to 20% by mass, preferably 0.001 to 10% by mass, and more preferably 0.01 to 5% by mass with regard to total solid contents of the composition combined with the above basic compound.

[6] Surfactant

The composition in the present invention may further or may not contain a surfactant. The surfactant is preferably a fluorine- and/or silicon-based surfactant.

The surfactant corresponding to these may include Megaface F176 and Megaface R08 manufactured by DIC Corporation, PF656 and PF6320 manufactured by OMNOVA Solutions Inc., Troysol S-366 manufactured by Troy Chemical Co., Ltd., Fluorad FC430 manufactured by Sumitomo 3M Limited, a polysiloxane polymer KP-341 manufactured by Shin-Etsu Chemical Co., Ltd. or the like.

Other surfactants besides the fluorine-based and/or silicon-based surfactants may also be used. More specifically, polyoxyethylene alkyl ethers, polyoxyethylene alkyl aryl ethers or the like may be included.

In addition to these, well-known surfactants may be used as appropriate. Examples of the surfactant which can be used include surfactants disclosed after [0273] of US2008/0248425A1.

These surfactants may be used either alone or as a combination of two types or more.

The actinic ray-sensitive or radiation-sensitive resin composition of the present invention may or may not contain the surfactant, but when the composition does, the amount of the surfactant used is preferably 0 to 2% by mass, more preferably 0.0001 to 2% by mass, and particularly preferably 0.0005 to 1% by mass with regard to total solid contents of the composition.

Meanwhile, keeping the addition amount of the surfactant to be 10 ppm or less or containing no surfactants is also preferable. As a result, surface localization of the hydrophobic resin is enhanced, thereby traceability of water may be improved when liquid immersion exposure is carried out since the surface of the resist film is made to be more hydrophobic.

[7] Solvent

The actinic ray-sensitive or radiation-sensitive resin composition according to the present invention typically further contains a solvent.

Examples of the solvent include an organic solvent such as alkylene glycol monoalkyl ether carboxylate, alkylene glycol monoalkyl ether, alkyl lactate, alkyl alkoxy propionate, cyclic lactone (preferably having 4 to 10 carbon atoms), a monoketone compound which may have a ring (preferably having 4 to 10 carbon atoms), alkylene carbonate, alkyl alkoxy acetate, or alkyl pyruvate.

Examples of the alkylene glycol monoalkyl ether carboxylate preferably include propylene glycol monomethyl ether acetate (PGMEA, alias 1-methoxy-2-acetoxypropane), propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate or ethylene glycol monoethyl ether acetate.

Examples of the alkylene glycol monoalkyl ether preferably include propylene glycol monomethyl ether (PGME, alias 1-methoxy-2-propanol), propylene glycol monoethyl ether, propylene glycol monopropyl ether, propylene glycol monobutyl ether, ethylene glycol monomethyl ether or ethylene glycol monoethyl ether.

Examples of the alkyl lactate preferably include methyl lactate, ethyl lactate, propyl lactate or butyl lactate.

Examples of the alkyl alkoxy propionate preferably include 3-ethoxyethyl propionate, 3-methoxymethyl propionate, 3-ethoxymethyl propionate or 3-methoxyethyl propionate.

Examples of the cyclic lactone preferably include β-propiolactone, β-butyrolactone, γ-butyrolactone, α-methyl-γ-butyrolactone, β-methyl-γ-butyrolactone, γ-valerolactone, γ-caprolactone, γ-octanoiclactone or α-hydroxy-γ-butyrolactone.

Examples of the monoketone compound which may have a ring preferably include 2-butanone, 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexen-2-one, 3-penten-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone or 3-methylcycloheptanone.

Examples of the alkylene carbonate preferably include propylene carbonate, vinylene carbonate, ethylene carbonate or butylene carbonate.

Examples of the alkyl alkoxy acetate preferably include 2-methoxyethyl acetate, 2-ethoxyethyl acetate, 2-(2-ethoxyethoxy)ethyl acetate, 3-methoxy-3-methylbutyl acetate or 1-methoxy-2-propyl acetate.

Examples of the alkyl pyruvate preferably include methyl pyruvate, ethyl pyruvate or propyl pyruvate.

The solvent which may be preferably used may include a solvent having a boiling point or 130° C. or higher. Specifically, cyclopentanone, γ-butyrolactone, cyclohexanone, ethyl lactate, ethylene glycol monoethyl ether acetate, propylene glycol monomethyl ether acetate, 3-ethoxyethyl propionate, ethyl pyruvate, 2-ethoxyethyl acetate, 2-(2-ethoxyethoxy)ethyl acetate or propylene carbonate.

In the present invention, the solvent may be used either alone or as a combination of two types or more.

In the present invention, a mixed solvent prepared by mixing a solvent containing a hydroxyl group in the structure and a solvent not containing a hydroxyl group may be used as the organic solvent.

The solvent containing a hydroxyl group and the solvent not containing a hydroxyl group may be appropriately selected from the compounds exemplified above, however, alkylene glycol monoalkyl ether, alkyl lactate or the like is preferable, and propylene glycol monomethyl ether or ethyl lactate is more preferable as the solvent containing a hydroxyl group. In addition, alkylene glycol monoalkyl ether acetate or alkyl alkoxy propionate, a monoketone compound which may have a ring, cyclic lactone, alkyl acetate or the like is preferable, propylene glycol monomethyl ether acetate, ethoxyethyl propionate, 2-heptanone, γ-butyrolactone, cyclohexanone or butyl acetate is particularly preferable, propylene glycol monomethyl ether acetate, ethoxyethyl propionate or 2-heptanone is most preferable as the solvent not containing a hydroxyl group.

The mixing ratio (mass) of the solvent containing a hydroxyl group and the solvent not containing a hydroxyl group is 1/99 to 99/1, preferably 10/90 to 90/10, more preferably is 20/80 to 60/40. A mixed solvent containing 50% by mass or more of the solvent not containing a hydroxyl group is particularly preferable in terms of coating uniformity.

The solvent may preferably contain propylene glycol monomethyl ether acetate, and is preferably a single solvent of propylene glycol monomethyl ether acetate or is a mixed solvent of two types or more containing propylene glycol monomethyl ether acetate.

[8] Other Components

In addition to the components described above, the composition of the present invention may appropriately contain an onium carboxylate salt, a dissolution inhibiting compound with a molecular weight of 3,000 or less described in Proceedings of SPIE, 2724, 355 (1996), a dye, a plasticizer, a photosensitizer, a light absorbing agent or the like.

[9] Pattern Forming Method

A pattern forming method of the present invention includes a step of exposing and a step of developing the resist film.

The resist film of the present invention is formed from the actinic ray-sensitive or radiation-sensitive resin composition of the present invention described above, and more specifically, is preferably formed on a substrate. In the pattern forming method of the present invention, the step of forming a film using a resist composition on a substrate, the step of exposing the film and the step of developing may be performed using generally known methods.

The actinic ray-sensitive or radiation-sensitive resin composition of the present invention is preferably used in a film thickness of 30 to 250 nm and more preferably used in a film thickness of 30 to 200 nm from the viewpoint of improving resolution. Such film thicknesses may be obtained by setting the solid content concentration in the actinic ray-sensitive or radiation-sensitive resin composition in an appropriate range, therefore, giving appropriate viscosity, and as a result, improving coating properties and film-forming properties.

The solid content concentration in the actinic ray-sensitive or radiation-sensitive resin composition is generally 1 to 10% by mass, more preferably from 1 to 8.0% by mass, and even more preferably 1.0 to 6.0% by mass.

The actinic ray-sensitive or radiation-sensitive resin composition in the present invention is used by dissolving the above component in a solvent, filtering using a filter, and then coating on a support. The filter is preferably made of polytetrafluoroethylene, polyethylene, or nylon with a pore size of preferably 0.1 μm or less, more preferably 0.05 μm or less, and more preferably 0.03 μm or less. In addition, a plurality of types of filters may be used by being connected in series or in parallel. The composition may also be filtered a plurality of times. Furthermore, the composition may be subjected to a deaeration treatment or the like before and after filtration.

The composition is applied by a suitable coating method such as a spinner on the substrate used in the manufacture of integrated circuit elements (for example: silicon/silicon dioxide coating). After that and being dried, a photosensitive resist film may be formed.

The film is irradiated with actinic rays or radiation through a predetermined mask, and is preferably baking (heated), developed, and rinsed. As a result, a favorable pattern may be obtained. In addition, a drawing which is not through a mask (a direct drawing) is common in the irradiation of an electron beam.

It is preferable that a pre-heating step (PB: Prebaking) be included after the film formation and prior to the exposure step.

It is also preferable that, a heating step after exposure (PEB: Post Exposure Baking) be included after the exposure step and prior to the development step.

The heating temperature for both PB and PEB is preferably 70 to 120° C., and more preferably 80 to 110° C.

The heating time is preferably 30 to 300 seconds, more preferably 30 to 180 seconds, and even more preferably 30 to 90 seconds.

Heating may be carried out using means included in normal exposure and development apparatus, and may also be carried out using a hot plate or the like.

The reaction of the exposed portion is accelerated due to the baking, and therefore, sensitivity or pattern profile is improved.

Actinic rays or radiation is not particularly limited, but is, for example, a KrF excimer laser, an ArF excimer laser, EUV light, an electron beam or the like, and is preferably an ArF excimer laser, EUV light or an electron beam.

As the alkali developer in the development step, quaternary ammonium salts represented by tetramethylammonium hydroxide are typically used, however, in addition to these, an alkaline aqueous solution such as inorganic alkalis, primary to tertiary amines, alcoholamines or cyclic amines may also be used.

In addition, an appropriate amount of alcohols or surfactants may be added to the above alkali developer.

The alkali concentration of the alkali developer is typically 0.1 to 20% by mass.

The pH of the alkali developer is typically 10.0 to 15.0.

As the rinsing liquid, pure water may be used with an appropriate amount of surfactants being added.

As the development method, for example, a method in which a substrate is immersed in a tank filled with a developer for a certain period of time (a dipping method), a method in which a developer is heaped up on the surface of a substrate by surface tension and developed by resting for a certain period of time (a paddle method), a method in which a developer is sprayed on the substrate surface (a spraying method), a method in which a developer is continuously discharged on a substrate rotated at a constant rate while scanning a developer discharging nozzle at a constant rate (a dynamic dispense method), or the like, may be applied.

In a rinsing step, the wafer developed is cleaned using a rinsing liquid. The cleaning method is not particularly limited, however, a method in which a rinsing liquid is continuously discharged on a substrate rotating at a constant rate (a spin coating method), a method in which a substrate is immersed in a tank filled with a rinsing liquid for a certain period of time (a dipping method), a method in which a rinsing liquid is sprayed on a substrate surface (a spraying method), or the like, may be applied, and among these, it is preferable that cleaning be carried out using a spin coating method, the substrate be rotated at a rotational speed of 2,000 rpm to 4,000 rpm after the cleaning, and the rinsing liquid be removed from the substrate. It is also preferable that a heating step (Post Baking) be included after the rinsing step. The residual developer and the rinsing liquid between and inside the patterns are removed by the baking. The heating step after the rinsing step is typically performed at 40 to 160° C. and preferably at 70 to 95° C., and typically for 10 seconds to 3 minutes and preferably for 30 seconds to 90 seconds.

Furthermore, a treatment for removing the developer or the rinsing liquid deposited on the pattern may be carried out using supercritical fluid after the development step or the rinsing step.

In addition, an antireflection film may be provided by coating on the substrate in advance before forming a photosensitive film (resist film).

As the antireflection film, both an inorganic film type such as titanium, titanium dioxide, titanium nitride, chromium oxide, carbon or amorphous silicon, or an organic film type made of a light absorber and a polymeric material may be used. Furthermore, as the organic antireflection film, commercially available organic antireflection films such as DUV30 series or DUV-40 series manufactured by Brewer Science, Inc., AR-2, AR-3 or AR-5 manufactured by Shipley Company L.L.C., or the like may be used.

An exposure (immersion exposure) may be carried out by filling the area between the film and the lens with liquid (immersion medium) having a higher refractive index than air upon irradiation with actinic rays or radiation. As a result, resolution can be enhanced. The immersion medium used is preferably water. Water is also suitable in terms that it has a small temperature coefficient of refractive index, is readily available, and easy to handle.

In addition, a medium having a refractive index of 1.5 or more may be used in terms of improving the refractive index. This medium may be either an aqueous solution or an organic solvent.

When water is used as the immersion liquid, an additive may be added in a small percentage for the purpose of improving the refractive index, and the like. Examples of the additive are described in detail in Chapter 12 of “Process and Material of Liquid Immersion Lithography” published by CMC Publishing. Meanwhile, if materials opaque to light of 193 nm or impurities whose refractive index is significantly different from water are incorporated, they cause a distortion of the optical image projected on the film, therefore, distilled water is preferable as the water used. Pure water filtered through an ion exchange filter or the like may also be used. Electrical resistance of the pure water is preferably 18.3 MQcm or more, TOC (Total Organic Carbon) is preferably 20 ppb or less, and it is preferable that a deaeration treatment be carried out.

A film sparingly soluble in the immersion liquid (hereinafter, also referred to as “top coat”) may be provided between the resist film and the immersion liquid so that the resist film is not in direct contact with the immersion liquid. As a function required for the top coat, coating suitability on the resist film, transparency to radiation, particularly, radiation with a wavelength of 193 nm, and sparing solubility in the immersion liquid may be included. As the top coat, a top coat which does not mix with the resist film, and can be coated uniformly on the resist film is preferable.

The top coat is preferably a polymer which does not contain an aromatic group from the viewpoint of transparency in 193 nm. Examples of the polymer such as this include a hydrocarbon polymer, an acrylate polymer, polymethacrylate, polyacrylate, polyvinyl ether, a silicon-containing polymer and a fluorine-containing polymer. The hydrophobic resin described above is also very suitable as a top coat. The residual monomer component of the polymer included in the top coat is preferably smaller since an optical lens is contaminated when impurities are eluted to the immersion liquid from the top coat.

When stripping the top coat, a developer may be used or a separate stripping agent may be used. As the stripping agent, a solvent with small penetration to the resist film is preferable. Stripping by an alkali developer is preferable in terms that the stripping step may be performed simultaneously with the developing treatment step of the resist. The top coat is preferably an acid from the viewpoint of stripping with the alkali developer, however, from the viewpoint of a non-intermixing property with the resist, the top coat may be either neutral or alkaline.

The refractive index difference between the top coat and the immersion liquid is preferably none or small. In this case, improving the resolution is possible. When the exposure light source is an ArF excimer laser (wavelength: 193 nm), the use of water is preferable as the immersion liquid, therefore, the top coat for ArF liquid immersion exposure preferably has a refractive index closer to that of water (1.44).

In addition, the top coat is preferably a thin film from the viewpoint of transparency and refractive index. The top coat preferably does not mix either with the resist film or with the immersion liquid. From this point of view, when the immersion liquid is water, it is preferable that the solvent used for the top coat be sparingly soluble in the solvent used in the actinic ray-sensitive or radiation-sensitive resin composition of the present invention, and be a non-water-soluble medium. In addition, when the immersion liquid is an organic solvent, the top coat may be either water-soluble or non-water-soluble.

In addition, the present invention also relates to an electronic devices manufacturing method including the pattern forming method of the present invention described above, and an electronic device manufactured by this manufacturing method.

The electronic device of the present invention is suitably installed in electrical and electronic devices (home appliances, OA and media-related devices, optical devices, communication devices, and the like).

### Example

### Synthesis Example 1

### Synthesis of Acid Generator

The compounds listed in the acid generator (1) column of the following Table 2 (the compounds represented by General Formula (I) or (IV)) were synthesized in accordance with synthesis methods disclosed in WO2011/093139A1, and the like, and the compounds listed in the acid generator (2) column of the following Table 2 (the compounds represented by General Formula (II), (III) or (V)) were synthesized in accordance with synthesis methods disclosed in JP2005-266766A, and the like.

### Synthesis Example 2

### Synthesis of Resin C

11.5 g of cyclohexanone was placed in a three-neck flask and was heated to 85° C. under a stream of nitrogen. A solution in which 1.98 g, 3.05 g, 0.95 g, 2.19 g and 2.76 g of the following compounds (monomers) from left to right, and a polymerization initiator V-601 (manufactured by Wako Pure Chemical Industries, Ltd., 0.562 g) were dissolved in 21.0 g of cyclohexanone was added dropwise to cyclohexanone in the flask over 6 hours. After completion of the dropwise addition, the mixture was further reacted for 2 hours at 85° C. After cooling the reaction solution, the reaction solution was added dropwise to a mixed solution of 420 g of hexane/180 g of ethyl acetate over 20 minutes, the precipitate was collected by filtration and dried, and 9.1 g of a resin C was obtained. The polymer composition ratio calculated from NMR was 20/25/10/30/15. The weight-average molecular weight (Mw) of the resin C obtained which is determined from a GPC method was 9,200 using polystyrene conversion, and the degree of dispersion (Mw/Mn) was 1.55.

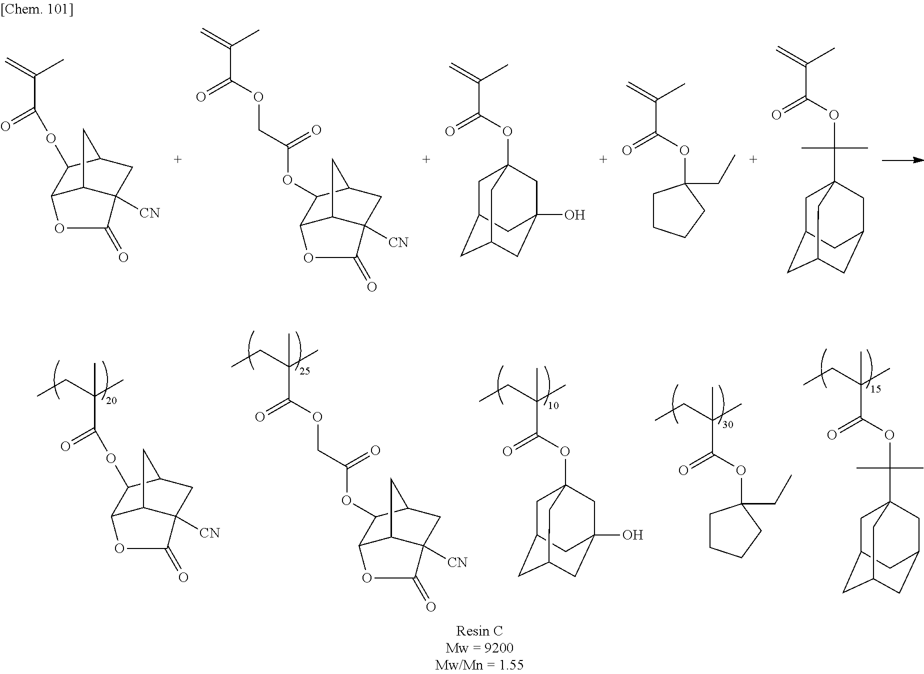

The resins A, B, D to G were synthesized in the same manner as that of Synthesis Example 2. The polymer structure, the weight-average molecular weight (Mw), and the degree of dispersion (Mw/Mn) of the resins A, B, D to G are shown below. In addition, the composition ratios of each repeating unit of the following polymer structures are shown in molar ratios.

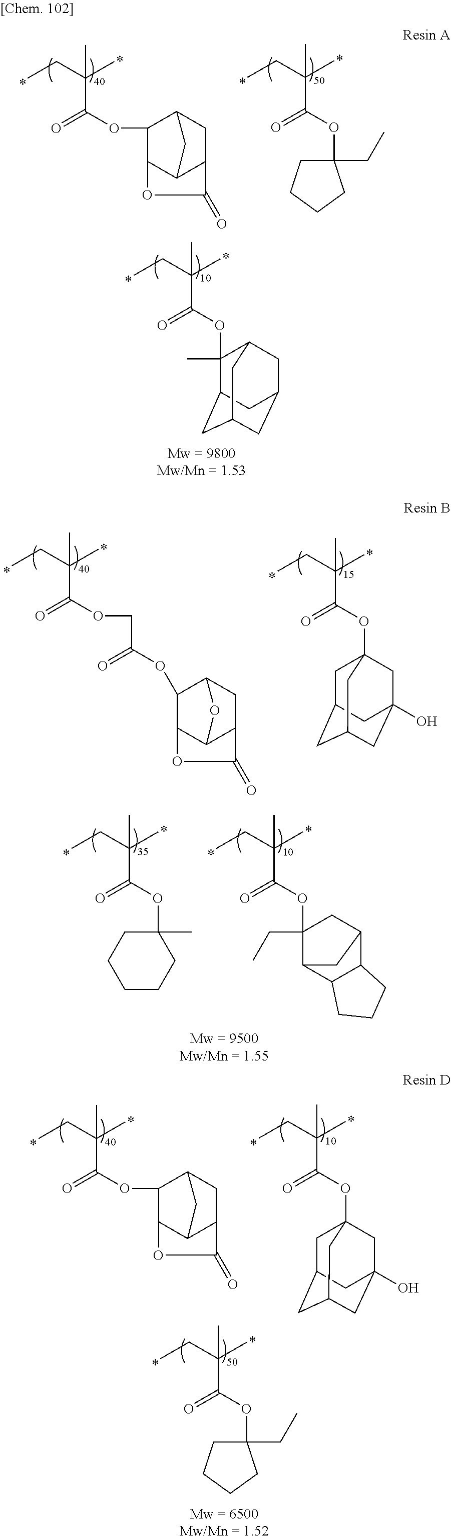

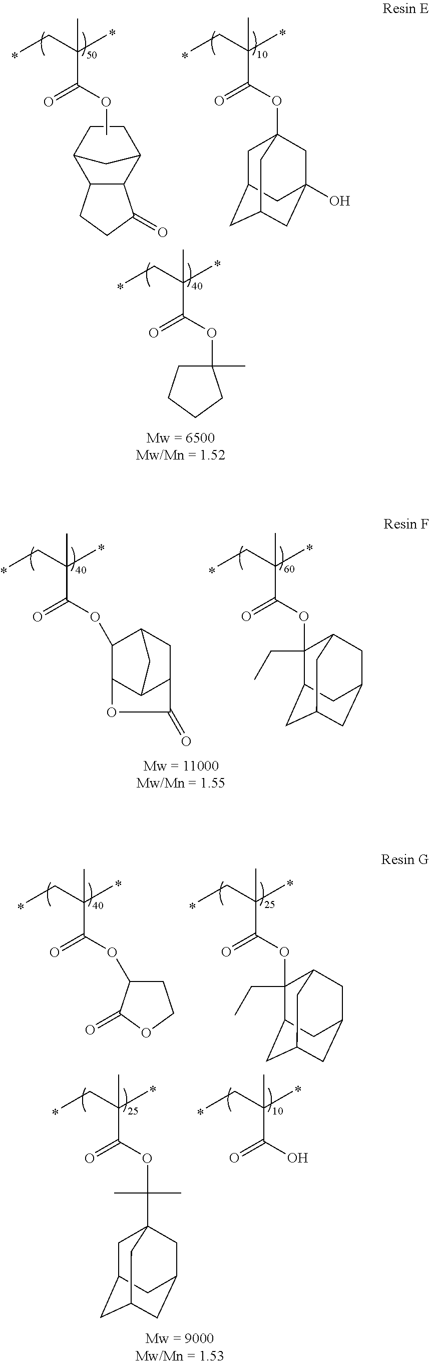

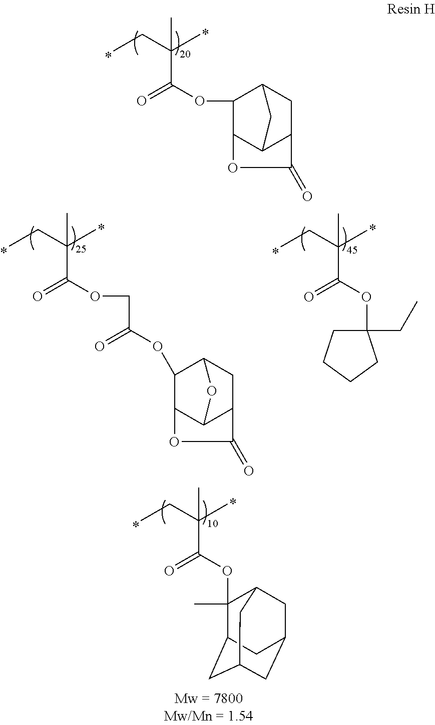

[Preparation of Resist Composition]

The components shown in the following Table 2 were dissolved in the solvents shown in the following Table 2, and a solution with a solid content concentration of 4% by mass was prepared, respectively. This solution was filtered using a polyethylene filter with a pore size of 0.05 μm, and the actinic ray-sensitive or radiation-sensitive resin composition (a positive-tone resist solution) was prepared. The actinic ray-sensitive or radiation-sensitive resin composition was evaluated using the following methods, and the results are shown in Table 2.

In addition, in Table 2, when the actinic ray-sensitive or radiation-sensitive resin composition contains a hydrophobic resin (HR), the form of use was labeled as “addition”. When the actinic ray-sensitive or radiation-sensitive resin composition does not contain a hydrophobic resin (HR), and the topcoat protective film containing a hydrophobic resin (HR) is formed on the upper layer after the film is formed, the form of use was labeled as “TC”.

<Resist Evaluation>

(Exposure Conditions: ArF Liquid Immersion Exposure)

ARC29SR (manufactured by Nissan Chemical Industries, Ltd.) for forming an organic anti-reflective film was coated on a silicon wafer, baking was carried out for 60 seconds at 205° C., and the anti-reflective film with a film thickness of 98 nm was formed. The actinic ray-sensitive or radiation-sensitive resin composition prepared was coated thereon, baking was carried out for 60 seconds at 130° C., and the film with a film thickness of 120 nm was formed. When a top coat was used, a solution of 3% by mass in which the resin for a top coat (the hydrophobic resin (HR)) was dissolved in decane/octanol (mass ratio 9/1) was coated on the film obtained as described above, baking was carried out for 60 seconds at 85° C., and the top coat layer with a film thickness of 50 nm was formed. An exposure was carried out thereon through a 6% half-tone mask of 1:1 line and space pattern with a line width of 48 nm using an ArF excimer laser liquid immersion scanner (manufactured by ASML; XT1700i, NA1.2). Ultra-pure water was used as an immersion liquid. After that, heating was carried out for 60 seconds at 130°, then, development was carried out for 30 seconds using an aqueous solution of tetramethylammonium hydroxide (2.38% by mass), and the pattern was formed after rinsing with pure water and spin drying.

(Depth of Focus Latitude (DOF) Evaluation)

The amount of exposure and depth of focus reproducing a resist pattern of 1:1 line and space pattern with a line width of 48 nm were made to be an optimum exposure amount and an optimum depth of focus, respectively, and, when the depth of focus was changed (defocused) from an optimum depth of focus, the width of the depth of focus which allowed ±10% (that is, 48 nm±10%) of the above line width was observed, while the exposure amount was kept at an optimum exposure amount. When this value is large, defocus tolerance is large, and therefore, is preferable.

[Particle Evaluation]

For the positive-tone resist solution prepared, the number of particles immediately after the preparation (particles initial value) in solution, and the number of particles allowed to stand for 1 week at 4° C. (the number of particles after the passage of time) in solution were counted using a particle counter KS-41 manufactured by Rion Co. Ltd., and the increase in the number of particles calculated using (the number of particles after the passage of time)-(particle initial value). Here, the particles with a particle diameter of 0.25 μm or more included in 1 mL of solution were counted.

In the particle evaluation, the amount of increases being 0.2 pieces/ml or less was determined as A, greater than 0.2 pieces/ml and less than or equal to 1 pieces/ml as B, greater than 1 pieces/ml and less than or equal to 5 pieces/ml as C, and greater than 5 pieces/ml as D.

TABLE 2

| | | | | | | | | Evaluation | |
|---|---|---|---|---|---|---|---|---|---|
| | Acid | Acid | | Basic Compound | Hydrophobic | Solvent | | Results | |
| | Generator (1) | Generator (2) | Resin (B) | or Compound (D) | Resin (HR) | (Mass | Surfactant | DOF | |
| | (g) | (g) | (10 g) | (g) | (35 mg) | Ratio) | (10 mg) | (μm) | Particle |
| Example 1 | A-1 | A-13 | A | DIA | Addition | A1 | W-1 | 0.18 | A |
| | (1.0) | (1.2) | | (0.3) | B-10 | (100) | | | |
| Example 2 | A-2 | A-9 | C | D-52 | Addition | A1/B1 | W-2 | 0.17 | A |
| | (1.2) | (0.5) | | (0.33) | B-2 | (60/40) | | | |
| Example 3 | A-3 | A-22 | B | DBA | Addition | A1/A2/A3 | W-1 | 0.19 | A |
| | (1.8) | (0.3) | | (0.35) | B-12 | (90/7/3) | | | |
| Example 4 | A-4 | A-8 | A | D-13 | Addition | A1/A3 | W-3 | 0.17 | A |
| | (1.0) | (0.6) | | (0.28) | B-52 | (95/5) | | | |
| Example 5 | A-14 | A-38 | E | PBI | TC | A1/B2 | — | 0.16 | B |
| | (1.2) | (0.7) | | (0.38) | B-41 | (90/10) | | | |
| Example 6 | A-15 | A-35 | D | TEA | TC | A1 | W-4 | 0.15 | B |
| | (1.6) | (0.2) | | (0.36) | B-41 | (100) | | | |
| Example 7 | A-18 | A-21 | A/D | D-13 | Addition | A1/A3 | W-1 | 0.17 | A |
| | (0.9) | (1.5) | (5 g/5 g) | (0.33) | B-52 | (97/3) | | | |
| Example 8 | A-24 | A-25 | A | PBI | Addition | A1 | — | 0.16 | B |
| | (0.8) | (1.3) | | (0.38) | B-30 | (100) | | | |
| Example 9 | A-29 | A-34 | B | DIA/D-13 | Addition | A1/A2 | W-1 | 0.18 | A |
| | (1.1) | (0.5) | | (0.1/0.2) | B-16 | (90/10) | | | |
| Example | A-1 | A-30 | A/D | D-13 | TC | A1/A3 | W-1 | 0.17 | A |
| 10 | (2.1) | (2.1) | (5 g/5 g) | (0.33) | B-8 | (97/3) | | | |
| Example 11 | A-1 | A-13 | F | DIA | Addition | A1 | W-1 | 0.14 | A |
| | (1.0) | (1.2) | | (0.3) | B-2 | (100) | | | |
| Example 12 | A-2 | A-9 | G | D-52 | Addition | A1/B1 | W-2 | 0.14 | A |
| | (1.2) | (0.5) | | (0.33) | B-10 | (60/40) | | | |
| Example 13 | A-45 | A-13 | F | DIA | Addition | A1 | W-1 | 0.14 | A |
| | (1.0) | (1.2) | | (0.3) | B-2 | (100) | | | |
| Example 14 | A-46 | A-38 | C | PBI | TC | A1/B2 | — | 0.16 | B |
| | (1.2) | (0.7) | | (0.38) | B-41 | (90/10) | | | |
| Example 15 | A-2 | A-16 | C | D-52 | Addition | A1/B1 | W-2 | 0.18 | A |
| | (1.2) | (0.5) | | (0.33) | B-2 | (60/40) | | | |
| Example 16 | A-2 | A-9 | H | D-52 | Addition | A1/B1 | W-2 | 0.18 | A |
| | (1.2) | (0.5) | | (0.33) | B-2 | (60/40) | | | |
| Example 17 | A-2 | A-9 | H | D-52 | Addition | A1/B1 | W-2 | 0.18 | A |
| | (1.0) | (0.3) | | (0.33) | B-2 | (60/40) | | | |
| | | A-11 | | | | | | | |
| | | (0.2) | | | | | | | |
| Comparative | A-1 | — | A | PEA | Addition | A1 | W-1 | 0.11 | D |
| Example 1 | (1.0) | | | (0.42) | B-12 | (100) | | | |
| Comparative | A-35 | A-9 | A | DIA | Addition | A1 | W-1 | 0.07 | C |
| Example 2 | (1.2) | (0.5) | | (0.3) | B-10 | (100) | | | |
| Comparative | A-1 | A-35 | A | DIA | Addition | A1 | W-1 | 0.04 | B |
| Example 3 | (1.2) | (0.5) | | (0.3) | B-10 | (100) | | | |
| Comparative | A-14 | A-8 | A | DIA | Addition | A1 | W-1 | 0.04 | B |
| Example 4 | (0.5) | (1.2) | | (0.3) | B-10 | (100) | | | |

Abbreviations in the tables are shown in the above specific examples, or shown below.

[Acid Generator (Compound (A))

Abbreviations in the tables are shown in the above specific examples.

[Basic Compound]
DIA: 2,6-diisopropyl aniline
TEA: triethanolamine
DBA: N,N-dibutylaniline
PBI: 2-phenylbenzimidazole
PEA: N-phenyldiethanolamine

[Hydrophobic Resin (HR)]

Abbreviations in the tables are shown in the above specific examples.

[Low Molecular Compound Having Group Capable of being Detached by the Action of Acid (Compound (D))]

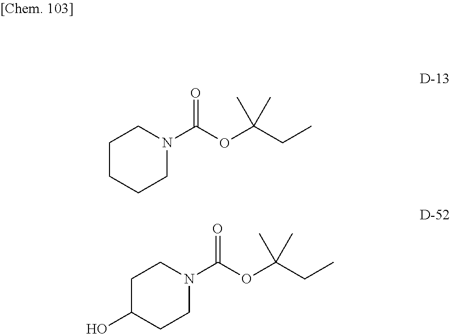

[Surfactant]
W-1: Megaface F176 (manufactured by DIC Corporation) (fluorine-based)
W-2: Megaface R08 (manufactured by DIC Corporation) (fluorine- and silicon-based)
W-3: PF6320 (manufactured by OMNOVA Solutions Inc.) (fluorine-based)
W-4: Troysol S-366 (manufactured by Troy Chemical Co., Ltd.)

[Solvent]
A1: propylene glycol monomethyl ether acetate (PGMEA)
A2: cyclohexanone
A3: γ-butyrolactone
B1: propylene glycol monomethyl ether (PGME)
B2: ethyl lactate

As is seen from Table 2, the compositions of the examples have liquid properties of large depth of focus latitude (Depth Of Focus), and small particle occurrences over time. Meanwhile, in the acid generator, the effects of the above examples were not obtained in the compositions of the comparative examples which did not have the combination of the above compound (A-1) and the combination of the above compound of (A-2).

Furthermore, in Examples 1 to 10 and 14 to 17 which use the resin having a repeating unit represented by the above general formula (AIII), more excellent effects were obtained regarding DOF.

This application claims priority under 35 U.S.C. §119 of Japanese Patent application JP 2011-260909, filed on Nov. 29, 2011, the entire contents of which are hereby incorporated by reference.

What is claimed is:

1. An actinic ray-sensitive or radiation-sensitive resin composition comprising:
(A) a compound capable of generating an acid by irradiation of actinic rays or radiation; and
(B) a resin of which solubility in an alkali developer is increased by being decomposed by the action of an acid,
wherein the actinic ray-sensitive or radiation-sensitive resin composition contains a combination of the following compounds of (A-1) or a combination of the following compounds of (A-2) as the compound (A),
(A-1) A combination of a compound represented by the following General Formula (I) and a compound represented by the following General Formulae (II) or (III)
(A-2) A combination of a compound represented by the following General Formula (IV) and a compound represented by the following General Formula (V) 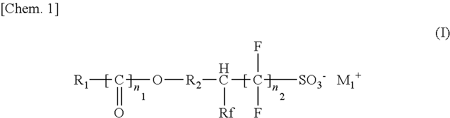
in General Formula (I), R₁ is a group having “a monovalent alicyclic hydrocarbon group having 5 or more carbon atoms” or a group having “an aryl group having 6 or more carbon atoms”, R₂ is a divalent linking group, Rf is a fluorine atom, or an alkyl group substituted with at least one fluorine atom, M₁⁺ is a monovalent cation, and n₁ and n₂ each independently are 0 or 1, 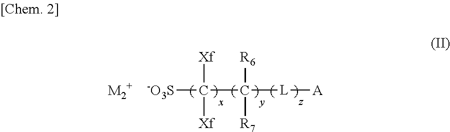
in General Formula (II), Xf and A each independently represent an alkyl group having 1 to 5 carbon atoms or a fluorine atom, and Xfs may be bonded to each other to form a ring, Xfs which are present in plural number may be the same as or different from each other, R₆ and R₇ each independently represent a hydrogen atom, a fluorine atom or an alkyl group, and R₆ and R₇ may be the same as or different from each other when present in plural number, L represents a divalent linking group and Ls may be the same as or different from each other when present in plural number, x represents an integer of 1 to 20, y represents an integer of 0 to 10, and z represents an integer of 0 to 10, and M₂⁺ represents a monovalent cation, 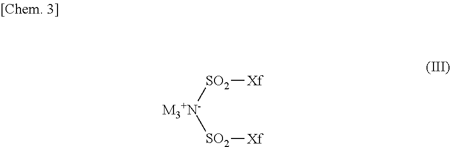
in General Formula (III), Xfs each independently are synonymous with Xfs in General Formula (II), Xfs may be the same as or different from each other, and may be bonded to each other to form a ring, and M₃⁺ represents a monovalent cation, 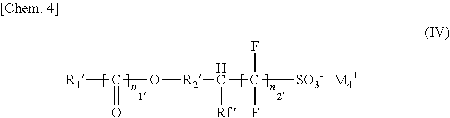
in General Formula (IV), R₁′ is an alkyl group having 1 to 5 carbon atoms, R₂′ is a divalent linking group, Rf′ is a fluorine atom, or an alkyl group substituted with at least one fluorine atom, M₄⁺ is a monovalent cation, and n₁′ and n₂′ each independently are 0 or 1, 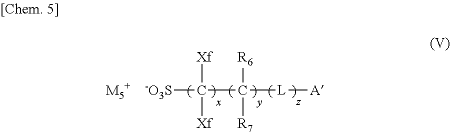
in General Formula (V), Xf, R₆, R₇, L, x, y, and z are synonymous with Xf, R₆, R₇, L, x, y, and z in General Formula (II), A′ represents a monovalent alicyclic hydrocarbon group having 5 or more carbon atoms or an aryl group having 6 or more carbon atoms, and M₅⁺ represents a monovalent cation.

2. The actinic ray-sensitive or radiation-sensitive resin composition according to claim 1,
wherein the resin (B) is a resin having a repeating unit represented by the following General Formula (AIII), 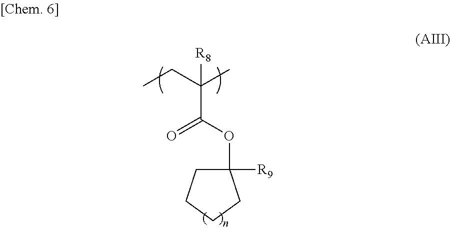
R₈ represents a hydrogen atom or an alkyl group, R₉ represents an alkyl group, and n represents an integer of 1 to 6.

3. The actinic ray-sensitive or radiation-sensitive resin composition according to claim 1, further comprising:
a low molecular compound containing a nitrogen atom and a group capable of being detached by the action of an acid.

4. The actinic ray-sensitive or radiation-sensitive resin composition according to claim 2, further comprising:
a low molecular compound containing a nitrogen atom and a group capable of being detached by the action of an acid.

5. The actinic ray-sensitive or radiation-sensitive resin composition according to claim 1,
wherein the resin (B) is a resin containing a repeating unit having a lactone structure or a sultone structure represented by the following General Formula (VI), 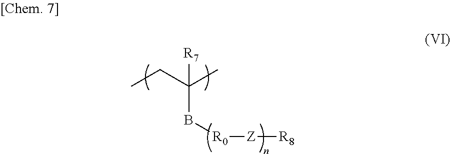
in General Formula (VI), B represents an ester bond or an amide bond, R₀ represents an alkylene group, a cycloalkylene group or a combination thereof, and when R₀ is present in plural number, the plural R₀s may be the same as or different from each other, Z represents a single bond, an ether bond, an ester bond, an amide bond, a urethane bond or a urea bond, and when Z is present in plural number, the plural Zs may be the same as or different from each other, R₈ represents a monovalent organic group having a lactone structure or a sultone structure, n is the number of repetitions of the structure represented by —R₀—Z— and represents an integer of 0 to 2, and R₇ represents a hydrogen atom, a halogen atom or an alkyl group.

6. The actinic ray-sensitive or radiation-sensitive resin composition according to claim 2,
wherein the resin (B) is a resin containing a repeating unit having a lactone structure or a sultone structure represented by the following General Formula (VI), 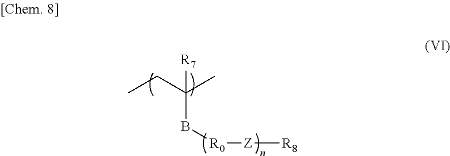
wherein, in General Formula (VI), B represents an ester bond or an amide bond, R₀ represents an alkylene group, a cycloalkylene group or a combination thereof, and when R₀ is present in plural number, the plural R₀s may be the same as or different from each other, Z represents a single bond, an ether bond, an ester bond, an amide bond, a urethane bond or a urea bond, and when Z is present in plural number, the plural Zs may be the same as or different from each other, R₈ represents a monovalent organic group having a lactone structure or a sultone structure, n is the number of repetitions of the structure represented by —R₀—Z— and represents an integer of 0 to 2, and R₇ represents a hydrogen atom, a halogen atom or an alkyl group.

7. The actinic ray-sensitive or radiation-sensitive resin composition according to claim 5,
wherein n is 1 or 2 in General Formula (VI).

8. A resist film which is formed using the actinic ray-sensitive or radiation-sensitive resin composition according to claim 1.

9. A pattern forming method including exposing and developing the resist film according to claim 8.

10. The pattern forming method according to claim 9,
wherein the exposure is an immersion exposure.

11. An electronic device manufacturing method including the pattern forming method according to claim 9.

12. An electronic device which is manufactured using the electronic device manufacturing method according to claim 11.
